(19) United States
(12) Patent Application Publication
(10) Pub. No.: US 2025/0247072 A1
(43) Pub. Date: Jul. 31, 2025

(54) PIEZOELECTRIC RESONATOR

(71) Applicant: Murata Manufacturing Co., Ltd., Nagaokakyo-shi (JP)

(72) Inventor: Toshio NISHIMURA, Nagaokakyo-shi (JP)

(21) Appl. No.: 19/184,081

(22) Filed: Apr. 21, 2025

Related U.S. Application Data
(63) Continuation of application No. PCT/JP2024/025226, filed on Jul. 12, 2024.

(30) Foreign Application Priority Data
Dec. 26, 2023 (JP) 2023-219822

(51) Int. Cl. H03H 9/13; H03H 9/02; H03H 9/19

(52) U.S. Cl. CPC H03H 9/132; H03H 9/02244; H03H 9/19; H03H 2009/02322; H03H 2009/02511

(57) ABSTRACT

A piezoelectric resonator is provided that includes a piezoelectric element having first and second main surfaces; a first electrode including a first excitation electrode on the first main surface and a first extended electrode coupled to a first outer peripheral portion of the first excitation electrode; and a second excitation electrode provided on the second main surface. At least one cavity is in at least one of the first electrode and the second excitation electrode in the region where the first electrode overlaps the second excitation electrode and is within a range of a distance of four times or less a thickness of the piezoelectric element from a boundary between the first excitation electrode and the first extended electrode.

### CROSS REFERENCE TO RELATED APPLICATIONS

This application is a continuation of International Application No. PCT/JP2024/025226, filed Jul. 12, 2024, which claims priority to Japanese Patent Application No. 2023-219822, filed Dec. 26, 2023, the contents of each of which are hereby incorporated by reference in their entirety.

### TECHNICAL FIELD

The present disclosure relates to a piezoelectric resonator.

### BACKGROUND

In various electronic devices, such as mobile communication terminals, communication base stations, and home appliances, piezoelectric resonators are currently used for applications of timing devices, sensors, oscillators, and the like. An example piezoelectric resonator includes a piezoelectric element having a pair of main surfaces, and a pair of excitation electrodes provided on the pair of main surfaces of the piezoelectric element.

Japanese Unexamined Patent Application Publication No. 2014-158149 (hereinafter “Patent Document 1”) discloses a vibration element including a substrate that vibrates by thickness shear vibration, a first excitation electrode that is provided on one main surface of the substrate and has a shape in which four corners of a quadrangular shape are cut out, and a second excitation electrode that is provided on the other main surface of the substrate. In this example, a ratio (S2/S1) of an area S2 of the first excitation electrode to an area S1 of the quadrangular shape is 87.7%≤(S2/S1)<95.0%.

According to the exemplary vibration element described in Patent Document 1, the excitation degree of the spurious of the inharmonic mode can be reduced, but with the improvement of the performance of the electronic device, further improvement of the vibration characteristics is required for the piezoelectric resonator.

### SUMMARY OF THE INVENTION

Thus, it is an object of the exemplary embodiment of the present disclosure to provide a piezoelectric resonator with improved vibration characteristics.

According to an exemplary aspect, a piezoelectric resonator is provided that includes a piezoelectric element having a first main surface and a second main surface that face each other; a first electrode including a first excitation electrode provided on the first main surface and a first extended electrode coupled to the first excitation electrode; and a second excitation electrode provided on the second main surface. In a plan view of the first or second main surface, a high acoustic velocity region is positioned at a center portion in a region where the first excitation electrode overlaps the second excitation electrode, and a low acoustic velocity region is positioned at a peripheral portion in the region where the first excitation electrode overlaps the second excitation electrode. The low acoustic velocity region has an acoustic velocity less than an acoustic velocity in the high acoustic velocity region. Moreover, a first outer peripheral portion of the first excitation electrode is inside a second outer peripheral portion of the second excitation electrode, and an acoustic velocity in the region where the first extended electrode and the second excitation electrode overlap with each other is less than the acoustic velocity in the high acoustic velocity region and is equal to or greater than the acoustic velocity in the low acoustic velocity region. In addition, at least one cavity is in at least one of the first electrode and the second excitation electrode in the region where the first electrode overlaps the second excitation electrode overlap. The at least one cavity is within a range of a distance of four times or less a thickness of the piezoelectric element from a boundary between the first excitation electrode and the first extended electrode.

According to another exemplary aspect of the present disclosure, a piezoelectric resonator is provided that includes a piezoelectric element having a first main surface and a second main surface that face each other; a first electrode including a first excitation electrode provided on the first main surface and a first extended electrode coupled to the first excitation electrode; and a second excitation electrode provided on the second main surface. In a plan view of the first or second main surface, a high acoustic velocity region is positioned at a center portion in a region where the first excitation electrode overlaps the second excitation electrode, and a low acoustic velocity region is positioned at a peripheral portion in the region where the first excitation electrode overlaps the second excitation electrode overlap. The low acoustic velocity region has an acoustic velocity less than an acoustic velocity in the high acoustic velocity region are provided. Moreover, a first outer peripheral portion of the first excitation electrode is inside a second outer peripheral portion of the second excitation electrode, and an acoustic velocity in a region where the first extended electrode and the second excitation electrode overlap with each other is less than the acoustic velocity in the high acoustic velocity region and is equal to or greater than the acoustic velocity in the low acoustic velocity region. In addition, at least one first cavity is in at least one of the first excitation electrode and the second excitation electrode in a region on a first extended electrode side with respect to the high acoustic velocity region, in the low acoustic velocity region, and at least one second cavity is in at least one of the first excitation electrode and the second excitation electrode in a region on a side opposite to the first extended electrode with the high acoustic velocity region interposed therebetween, in the low acoustic velocity region.

According to the exemplary embodiments of the present disclosure, a piezoelectric resonator is provided with improved vibration characteristics.

### BRIEF DESCRIPTION OF DRAWINGS

FIG. 1 is an exploded perspective view of a quartz crystal resonator unit according to a first exemplary embodiment.

FIG. 2 is a cross-sectional view of a quartz crystal resonator unit according to the first exemplary embodiment.

FIG. 3 is a plan view of a quartz crystal resonator according to the first exemplary embodiment.

FIG. 4 is a cross-sectional view of the quartz crystal resonator according to the first exemplary embodiment.

FIG. 5 is a diagram showing a vibration distribution of the quartz crystal resonator according to the first exemplary embodiment.

FIG. 6 is a diagram showing a vibration distribution of the quartz crystal resonator according to the first exemplary embodiment.

FIG. 7 is a diagram showing a vibration distribution of the quartz crystal resonator according to the first exemplary embodiment.

FIG. 8 is a plan view of a quartz crystal resonator according to a comparative example.

FIG. 9 is a diagram showing a vibration distribution of the quartz crystal resonator according to the comparative example.

FIG. 10 is a diagram showing a vibration distribution of the quartz crystal resonator according to the comparative example.

FIG. 11 is a diagram showing a vibration distribution of the quartz crystal resonator according to the comparative example.

FIG. 12 is a graph showing a simulation result based on the first exemplary embodiment.

FIG. 13 is a graph showing a simulation result based on the first exemplary embodiment.

FIG. 14 is a plan view of a quartz crystal resonator according to a second exemplary embodiment.

FIG. 15 is a graph showing a simulation result based on the second exemplary embodiment.

FIG. 16 is a graph showing a simulation result based on the second exemplary embodiment.

FIG. 17 is a graph showing a simulation result based on the second exemplary embodiment.

FIG. 18 is a graph showing a simulation result based on the second exemplary embodiment.

FIG. 19 is a graph showing a simulation result based on the second exemplary embodiment.

FIG. 20 is a plan view of a quartz crystal resonator according to a third exemplary embodiment.

FIG. 21 is a diagram showing a vibration distribution of the quartz crystal resonator according to the third exemplary embodiment.

FIG. 22 is a diagram showing a vibration distribution of the quartz crystal resonator according to the third exemplary embodiment.

FIG. 23 is a diagram showing a vibration distribution of the quartz crystal resonator according to the third exemplary embodiment.

FIG. 24 is a plan view of a quartz crystal resonator according to a fourth exemplary embodiment.

FIG. 25 is a diagram showing a vibration distribution of the quartz crystal resonator according to the fourth exemplary embodiment.

FIG. 26 is a diagram showing a vibration distribution of the quartz crystal resonator according to the fourth exemplary embodiment.

FIG. 27 is a diagram showing a vibration distribution of the quartz crystal resonator according to the fourth exemplary embodiment.

FIG. 28 is a plan view of a quartz crystal resonator according to a fifth exemplary embodiment.

FIG. 29 is a graph showing a simulation result based on the fifth exemplary embodiment.

FIG. 30 is a plan view of a quartz crystal resonator according to a sixth exemplary embodiment.

FIG. 31 is a graph showing a simulation result based on the sixth exemplary embodiment.

FIG. 32 is a graph showing a simulation result based on the sixth exemplary embodiment.

FIG. 33 is a plan view of a quartz crystal resonator according to a seventh exemplary embodiment.

FIG. 34 is an enlarged plan view of a coupling portion in the seventh exemplary embodiment.

FIG. 35 is a diagram showing a vibration distribution of the quartz crystal resonator according to the seventh exemplary embodiment.

FIG. 36 is a diagram showing a vibration distribution of the quartz crystal resonator according to the seventh exemplary embodiment.

FIG. 37 is a diagram showing a vibration distribution of the quartz crystal resonator according to the seventh exemplary embodiment.

FIG. 38 is a graph showing a simulation result based on the seventh exemplary embodiment.

FIG. 39 is a graph showing a simulation result based on the seventh exemplary embodiment.

FIG. 40 is a plan view of a quartz crystal resonator according to an eighth exemplary embodiment.

FIG. 41 is a graph showing a simulation result based on the eighth exemplary embodiment.

FIG. 42 is a diagram showing a vibration distribution of the quartz crystal resonator according to the eighth exemplary embodiment.

FIG. 43 is a diagram showing a vibration distribution of the quartz crystal resonator according to the eighth exemplary embodiment.

FIG. 44 is a diagram showing a vibration distribution of the quartz crystal resonator according to the eighth exemplary embodiment.

FIG. 45 is a plan view of a quartz crystal resonator according to a ninth exemplary embodiment.

FIG. 46 is a diagram showing a vibration distribution of the quartz crystal resonator according to the ninth exemplary embodiment.

FIG. 47 is a diagram showing a vibration distribution of the quartz crystal resonator according to the ninth exemplary embodiment.

FIG. 48 is a diagram showing a vibration distribution of the quartz crystal resonator according to the ninth exemplary embodiment.

FIG. 49 is a plan view of a quartz crystal resonator according to a tenth exemplary embodiment.

FIG. 50 is a diagram showing a vibration distribution of the quartz crystal resonator according to the tenth exemplary embodiment.

FIG. 51 is a diagram showing a vibration distribution of the quartz crystal resonator according to the tenth exemplary embodiment.

FIG. 52 is a diagram showing a vibration distribution of the quartz crystal resonator according to the tenth exemplary embodiment.

FIG. 53 is a plan view of a quartz crystal resonator according to an eleventh exemplary embodiment.

FIG. 54 is a graph showing a simulation result based on the eleventh exemplary embodiment.

FIG. 55 is a diagram showing a vibration distribution of the quartz crystal resonator according to the eleventh exemplary embodiment.

FIG. 56 is a diagram showing a vibration distribution of the quartz crystal resonator according to the eleventh embodiment.

FIG. 57 is a diagram showing a vibration distribution of the quartz crystal resonator according to the eleventh exemplary embodiment.

FIG. 58 is a plan view of a quartz crystal resonator according to a twelfth exemplary embodiment.

FIG. 59 is a diagram showing a vibration distribution of the quartz crystal resonator according to the twelfth exemplary embodiment.

FIG. 60 is a diagram showing a vibration distribution of the quartz crystal resonator according to the twelfth exemplary embodiment.

FIG. 61 is a diagram showing a vibration distribution of the quartz crystal resonator according to the twelfth exemplary embodiment.

FIG. 62 is a plan view of a quartz crystal resonator according to a thirteenth exemplary embodiment.

FIG. 63 is a diagram showing a vibration distribution of the quartz crystal resonator according to the thirteenth exemplary embodiment.

FIG. 64 is a diagram showing a vibration distribution of the quartz crystal resonator according to the thirteenth exemplary embodiment.

FIG. 65 is a diagram showing a vibration distribution of the quartz crystal resonator according to the thirteenth exemplary embodiment.

FIG. 66 is a plan view of a quartz crystal resonator according to a fourteenth exemplary embodiment.

FIG. 67 is a plan view of a quartz crystal resonator according to a fifteenth exemplary embodiment.

FIG. 68 is a graph showing simulation results based on the fourteenth embodiment and the fifteenth exemplary embodiment.

FIG. 69 is a graph showing a simulation result based on the fifteenth exemplary embodiment.

FIG. 70 is a graph showing a simulation result based on the fourteenth exemplary embodiment.

FIG. 71 is a graph showing a simulation result based on the fourteenth exemplary embodiment.

FIG. 72 is a plan view of a quartz crystal resonator according to a sixteenth exemplary embodiment.

FIG. 73 is a diagram showing a vibration distribution of the quartz crystal resonator according to the sixteenth exemplary embodiment.

FIG. 74 is a diagram showing a vibration distribution of the quartz crystal resonator according to the sixteenth exemplary embodiment.

FIG. 75 is a diagram showing a vibration distribution of the quartz crystal resonator according to the sixteenth exemplary embodiment.

FIG. 76 is a plan view of a quartz crystal resonator according to a seventeenth exemplary embodiment.

FIG. 77 is a diagram showing a vibration distribution of the quartz crystal resonator according to the seventeenth exemplary embodiment.

FIG. 78 is a diagram showing a vibration distribution of the quartz crystal resonator according to the seventeenth exemplary embodiment.

FIG. 79 is a diagram showing a vibration distribution of the quartz crystal resonator according to the seventeenth exemplary embodiment.

FIG. 80 is a plan view of a quartz crystal resonator according to an eighteenth exemplary embodiment.

FIG. 81 is a diagram showing a vibration distribution of the quartz crystal resonator according to the eighteenth exemplary embodiment.

FIG. 82 is a diagram showing a vibration distribution of the quartz crystal resonator according to the eighteenth exemplary embodiment.

FIG. 83 is a diagram showing a vibration distribution of the quartz crystal resonator according to the eighteenth exemplary embodiment.

FIG. 84 is a plan view of a quartz crystal resonator according to a nineteenth exemplary embodiment.

FIG. 85 is a diagram showing a vibration distribution of the quartz crystal resonator according to the nineteenth exemplary embodiment.

FIG. 86 is a diagram showing a vibration distribution of the quartz crystal resonator according to the nineteenth exemplary embodiment.

FIG. 87 is a diagram showing a vibration distribution of the quartz crystal resonator according to the nineteenth exemplary embodiment.

FIG. 88 is a plan view of a quartz crystal resonator according to a twentieth exemplary embodiment.

FIG. 89 is a diagram showing a vibration distribution of the quartz crystal resonator according to the twentieth exemplary embodiment.

FIG. 90 is a diagram showing a vibration distribution of the quartz crystal resonator according to the twentieth exemplary embodiment.

FIG. 91 is a diagram showing a vibration distribution of the quartz crystal resonator according to the twentieth exemplary embodiment.

FIG. 92 is a plan view of a quartz crystal resonator according to a twenty-first exemplary embodiment.

FIG. 93 is a diagram showing a vibration distribution of the quartz crystal resonator according to the twenty-first exemplary embodiment.

FIG. 94 is a diagram showing a vibration distribution of the quartz crystal resonator according to the twenty-first exemplary embodiment.

FIG. 95 is a diagram showing a vibration distribution of the quartz crystal resonator according to the twenty-first exemplary embodiment.

FIG. 96 is a plan view of a quartz crystal resonator according to a twenty-second exemplary embodiment.

FIG. 97 is a diagram showing a vibration distribution of the quartz crystal resonator according to the twenty-second exemplary embodiment.

FIG. 98 is a diagram showing a vibration distribution of the quartz crystal resonator according to the twenty-second exemplary embodiment.

FIG. 99 is a diagram showing a vibration distribution of the quartz crystal resonator according to the twenty-second exemplary embodiment.

### DETAILED DESCRIPTION OF EMBODIMENTS

Hereinafter, exemplary embodiments of the present disclosure will be described. In the following description of the drawings, the same or similar components are defined as the same or similar reference numerals. The drawings are examples, and a dimension and a shape of each portion are schematic. The technical scope of the present disclosure should not be interpreted as being limited to the embodiments.

For purposes of this disclosure, each drawing is attached with an orthogonal coordinate system including an X axis, a Y′ axis, and a Z′ axis for convenience, in order to clarify a mutual relationship between the respective drawings and to help understanding of a positional relationship between respective members. The X axis, the Y′ axis, and the Z′ axis correspond to each other in each drawing. The X axis, the Y′ axis, and the Z′ axis correspond to crystallographic axes of a quartz crystal element 11, which will be described later. The X axis corresponds to an electric axis (polar axis) of the quartz crystal, the Y axis corresponds to a mechanical axis of the quartz crystal, and the Z axis corresponds to an optical axis of the quartz crystal. The Y′ axis and the Z′ axis are axes obtained by rotating the Y axis and the Z axis, respectively, counterclockwise around the X axis by θ degrees as viewed in the positive direction of the X axis direction.

In the following description, a direction parallel to the X axis is referred to as an “X axis direction”, a direction parallel to the Y′ axis is referred to as a “Y′ axis direction”, and a direction parallel to the Z′ axis is referred to as a “Z′ axis direction”. In addition, a distal end direction of an arrow on the X axis, the Y′ axis, and the Z′ axis is referred to as “positive” or “+ (plus)”, and a direction opposite to the arrow is referred to as “negative” or “− (minus)”. It should be noted that, for convenience, the +Y′ axis direction is referred to as an upward direction and the −Y′ axis direction is referred to as a downward direction, but the up-down orientation of the quartz crystal resonator 10 and the quartz crystal resonator unit 1 is not limited. In addition, a plane specified by the X axis and the Z′ axis is defined as a Z′X plane, and the same applies to a plane specified by other axes.

### First Exemplary Embodiment

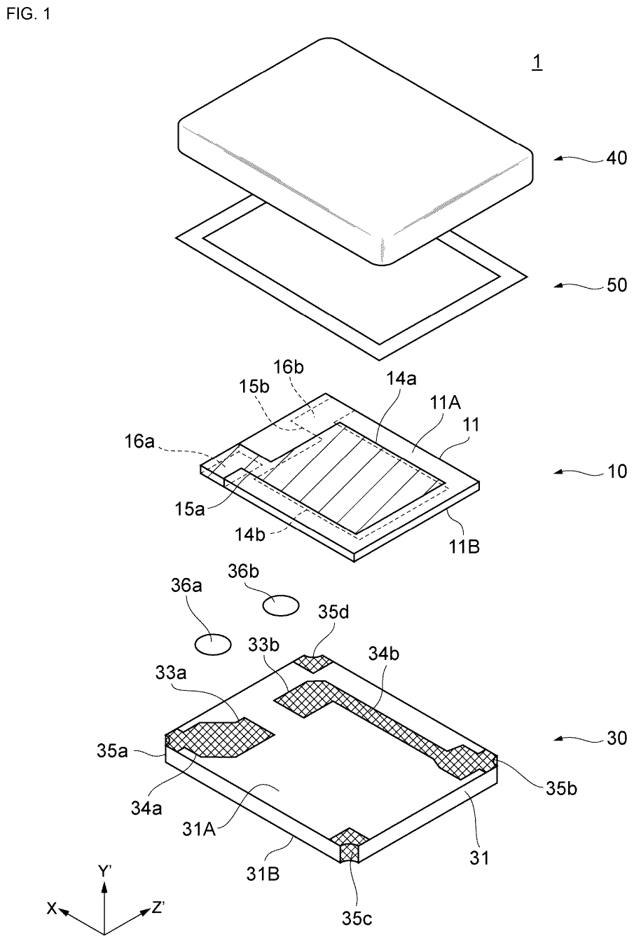

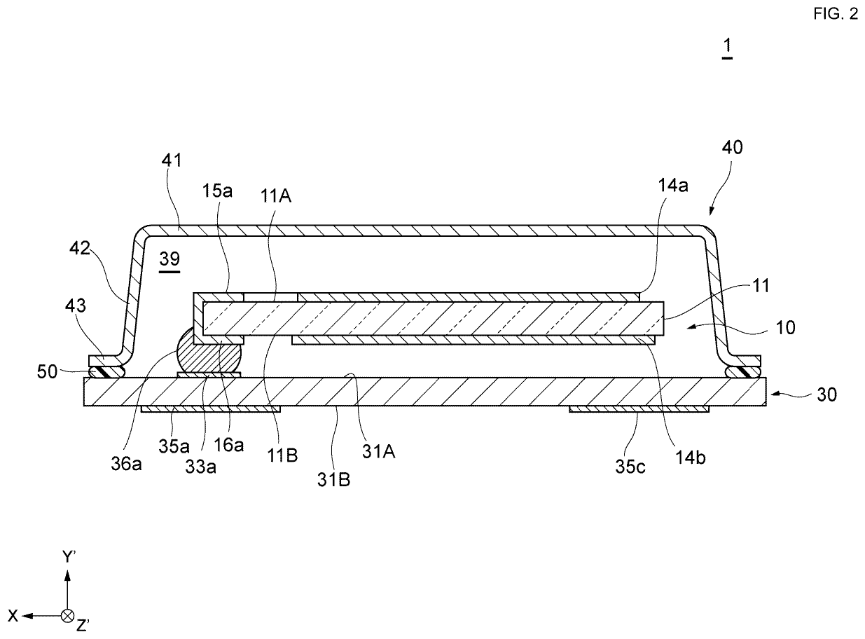

First, a configuration of a quartz crystal resonator unit according to a first embodiment will be described with reference to FIGS. 1 and 2. FIG. 1 is an exploded perspective view of the quartz crystal resonator unit according to the first embodiment. FIG. 2 is a cross-sectional view of the quartz crystal resonator unit according to the first embodiment.

The quartz crystal resonator unit 1 includes a quartz crystal resonator 10, a base member 30, a lid member 40, and a bonding portion 50. Hereinafter, the Y′ axis direction will be referred to as a “thickness direction” of the quartz crystal resonator 10.

The quartz crystal resonator unit 1 is used as a component of, for example, a temperature compensated crystal oscillator (TCXO), a voltage controlled crystal oscillator (VCXO), or an oven-controlled crystal oscillator (OCXO).

The quartz crystal resonator 10 is an electromechanical energy conversion element that mutually converts electric energy and mechanical energy by a piezoelectric effect. The frequency of the main mode of the quartz crystal resonator 10 is, for example, about 0.8 GHz or more and 2.0 GHz or less, and is, for example, about 0.95 GHz. A frequency of an inharmonic mode of the quartz crystal resonator 10 is, for example, within a range of approximately 1% of the frequency of the main mode.

In the exemplary aspect, the quartz crystal resonator 10 is excited at a predetermined frequency based on the applied alternating voltage. Moreover, the quartz crystal resonator 10 is held, such that it is configured to vibrate in a vibration space provided between the base member 30 and the lid member 40. The main vibration of the quartz crystal resonator 10 is a thickness shear vibration mode in an exemplary aspect.

It is noted that the main vibration of the quartz crystal resonator is not limited to the thickness shear vibration mode, and may be, for example, a thickness longitudinal vibration mode, a spreading vibration mode, a length vibration mode, or a bending vibration mode in alternative exemplary aspects.

As shown in FIG. 1, the quartz crystal resonator 10 includes the quartz crystal element 11 having a flake shape, a first excitation electrode 14a and a second excitation electrode 14b forming a pair of excitation electrodes, a first extended electrode 15a and a second extended electrode 15b forming a pair of extended electrodes, and a first coupling electrode 16a and a second coupling electrode 16b forming a pair of coupling electrodes.

The quartz crystal element 11 has an upper surface 11A and a lower surface 11B that face each other. The upper surface 11A is positioned on a side that faces a top wall portion 41 of the lid member 40. The lower surface 11B is positioned on a side that faces the base member 30. The upper surface 11A and the lower surface 11B correspond to a pair of main surfaces of the quartz crystal element 11. The upper surface 11A corresponds to an example of a first main surface, and the lower surface 11B corresponds to an example of a second main surface.

The quartz crystal element 11 is, for example, an AT cut quartz crystal. The AT cut quartz crystal is formed such that the XZ′ plane is the main surface, and the direction parallel to the Y′ axis is the thickness. As an example, when the upper surface 11A is viewed in a plan view in the thickness direction (hereinafter simply referred to as a “plan view”), a shape of the quartz crystal element 11 (hereinafter referred to as a “planar shape”) is a rectangular shape having a pair of short sides extending in the Z′ axis direction and a pair of long sides extending in the X axis direction. As an example, the shape of the quartz crystal element 11 is a flat plate shape having a uniform thickness.

It is noted that the planar shape of the quartz crystal element is not limited to the shape described above. For example, the planar shape of the quartz crystal element may be a rectangular shape having a long side extending in the Z′ axis direction and a short side extending in the X axis direction, and may be a square shape having a side extending in the Z′ axis direction and a side extending in the X axis direction. The planar shape of the quartz crystal element may be a rectangular shape having a side extending along a direction intersecting the Z axis direction and the Z′ axis direction. The planar shape of the quartz crystal element may be a polygonal shape, a circular shape, an elliptical shape, or a shape obtained by combining these shapes. Further, the quartz crystal element is not limited to a flat plate shape. Instead, the quartz crystal element may have a mesa type structure or an inverted mesa type structure having unevenness on at least one of the upper surface and the lower surface. The quartz crystal element may have a convex structure in which an amount of change in the thickness changes continuously or may have a bevel structure in which an amount of change in the thickness changes discontinuously.

The axes obtained by rotating the Y axis and the Z axis among the X axis, the Y axis, and the Z axis, which are crystallographic axes of a synthetic quartz crystal, by 35 degrees 15 minutes±1 minute 30 seconds in the direction from the Y axis to the Z axis around the X axis are defined as the Y′ axis and the Z′ axis, respectively, and the AT cut quartz crystal element 11 of is obtained by cutting out the XZ′ plane as a main surface.

The quartz crystal resonator 10 using the AT cut quartz crystal element 11 has high frequency stability in a wide temperature range. Further, the AT cut quartz crystal resonator also has excellent aging characteristics and can be manufactured at low cost. Further, the AT cut quartz crystal resonator uses a thickness shear vibration mode as a main vibration.

It is noted that the cut-angles of the quartz crystal element are not limited to the angles described above. The rotation angles of the Y′ axis and the Z′ axis in the AT cut quartz crystal element 11 may be tilted in a range of −5 degrees or more and +15 degrees or less from 35 degrees 15 minutes. In addition, as the cut-angles of the quartz crystal element, a different cut other than the AT cut, for example, a BT cut, a GT cut, an SC cut, or the like may be applied. Further, the main vibration mode of the quartz crystal resonator is not limited to the thickness shear vibration mode, and may be, for example, a thickness longitudinal vibration, a spreading vibration, a length vibration, or a bending vibration in alternative exemplary aspects.

The first excitation electrode 14a and the second excitation electrode 14b are configured to apply an alternating voltage to the quartz crystal element 11 to excite the quartz crystal element 11. The first excitation electrode 14a and the second excitation electrode 14b are provided at the center portion of the quartz crystal element 11 in plan view. The first excitation electrode 14a is provided on the upper surface 11A, and the second excitation electrode 14b is provided on the lower surface 11B. The first excitation electrode 14a and the second excitation electrode 14b face each other in the Y′ axis direction with the quartz crystal element 11 interposed therebetween.

The planar shape of the first excitation electrode 14a is a rectangular shape having a short side extending in the Z′ axis direction and a long side extending in the X axis direction. Further, the first excitation electrode 14a has a thickness in the Y′ axis direction. The second excitation electrode 14b also has the same shape.

It is noted that the planar shapes of the first excitation electrode and the second excitation electrode are not limited to the shape described above. The planar shape of the first excitation electrode and the second excitation electrode may be a rectangular shape having a short side extending in the X axis direction, or may be a square shape having a side extending in the X axis direction and a side extending in the Z′ axis direction. The planar shape of the first excitation electrode and the second excitation electrode may be a rectangular shape having sides extending along directions intersecting the Z axis direction and the Z′ axis direction. The planar shape of the first excitation electrode and the second excitation electrode may be a polygonal shape, a circular shape, an elliptical shape, or a combination thereof.

The first extended electrode 15a electrically couples the first excitation electrode 14a and the first coupling electrode 16a, and the second extended electrode 15b electrically couples the second excitation electrode 14b and the second coupling electrode 16b. The first extended electrode 15a is provided from the upper surface 11A to the lower surface 11B of the quartz crystal element 11, and the second extended electrode 15b is provided on the lower surface 11B of the quartz crystal element 11.

The first coupling electrode 16a and the second coupling electrode 16b electrically couple the quartz crystal resonator 10 to the base member 30. The first coupling electrode 16a and the second coupling electrode 16b are provided on the lower surface 11B of the quartz crystal element 11.

The first excitation electrode 14a, the first extended electrode 15a, and the first coupling electrode 16a are integrally provided. The same applies to the second excitation electrode 14b, the second extended electrode 15b, and the second coupling electrode 16b. A group of electrodes consisting of the first excitation electrode 14a, the first extended electrode 15a, and the first coupling electrode 16a is referred to as a first electrode, and a group of electrodes consisting of the second excitation electrode 14b, the second extended electrode 15b, and the second coupling electrode 16b is referred to as a second electrode.

The first electrode and the second electrode have, for example, a multilayer structure in which an underlying layer and a surface layer are provided in this order to be laminated. For example, the underlying layer is a chromium (Cr) layer having good adhesion to the quartz crystal element 11, and the surface layer is a gold (Au) layer having good chemical stability. The first electrode and the second electrode may contain titanium (Ti), aluminum (Al), molybdenum (Mo), or an aluminum copper alloy (AlCu) containing aluminum (Al) as a main component. The first electrode and the second electrode may have a monolayer structure.

The base member 30 is configured to hold the quartz crystal resonator 10, such that the quartz crystal resonator 10 can be excited. The base member 30 includes a base 31, coupling electrodes 33a and 33b, extended electrodes 34a and 34b, outer electrodes 35a, 35b, 35c, and 35d, and conductive holding members 36a and 36b.

The base 31 is a plate-shaped insulator having an upper surface 31A and a lower surface 31B that face each other in the thickness direction. The upper surface 31A and the lower surface 31B correspond to a pair of main surfaces of the base 31. The upper surface 31A is positioned on a side that faces the quartz crystal resonator 10 and the lid member 40 and corresponds to a mounting surface on which the quartz crystal resonator 10 is mounted. From the viewpoint of suppressing a thermal stress acting on the quartz crystal resonator 10 from the base 31 due to thermal history such as reflow, the base 31 is preferably formed of a heat-resistant material. From the same viewpoint, the base 31 may be formed of a material having a thermal expansion coefficient close to that of the quartz crystal element 11. The base 31 is formed of, for example, a ceramic substrate, a glass substrate, or a quartz crystal substrate.

A corner portion of the base 31 has a notched side surface of which a part is formed in a cylindrically curved surface shape (also referred to as a castellation shape). It is noted that the shape of the corner portion of the base 31 is not limited thereto. For example, the corner portion of the base may have a notched side surface formed in a prism shape or may be a substantially right-angled corner portion without a notch.

The coupling electrodes 33a and 33b are electrically coupled to the quartz crystal resonator 10. The coupling electrode 33a is electrically coupled to the coupling electrode 16a of the quartz crystal resonator 10, and the coupling electrode 33b is electrically coupled to the coupling electrode 16b of the quartz crystal resonator 10.

The extended electrode 34a electrically couples the coupling electrode 33a and the outer electrode 35a, and the extended electrode 34b electrically couples the coupling electrode 33b and the outer electrode 35b. The extended electrodes 34a and 34b are provided on the upper surface 31A of the base 31.

The outer electrodes 35a and 35b are external terminals for electrically coupling the quartz crystal resonator 10 to an external substrate (not shown). The outer electrode 35a electrically couples the first excitation electrode 14a of the quartz crystal resonator 10 to the external substrate, and the outer electrode 35b electrically couples the second excitation electrode 14b of the quartz crystal resonator 10 to the external substrate. One electrode of the outer electrodes 35c and 35d is a ground electrode that grounds the lid member 40, and the other is a dummy electrode that is not electrically coupled to the quartz crystal resonator 10 or the lid member 40. Each of the outer electrodes 35a, 35b, 35c, and 35d is continuously provided from the notched side surfaces provided at the four corner portions of the base 31 to the lower surface 31B. In the example illustrated in FIG. 1, the outer electrode 35a and the outer electrode 35b are positioned diagonally opposite to each other on the upper surface 31A of the base 31, and the outer electrode 35c and the outer electrode 35d are positioned diagonally opposite to each other on the upper surface 31A of the base 31.

It should be appreciated that the functions and positions of the outer electrodes 35a, 35b, 35c, and 35d are not limited to the above. Both the outer electrodes 35c and 35d may be ground electrodes or may be dummy electrodes. Moreover, the outer electrodes 35c and 35d may be omitted. The outer electrode 35c may be electrically coupled to one of the outer electrodes 35a and 35b, and the outer electrode 35d may be electrically coupled to the other of the outer electrodes 35a and 35b. In plan view, the outer electrodes 35a and 35b may be positioned on the same short side of the upper surface 31A of the base 31 or may be positioned on the same long side.

The conductive holding members 36a and 36b electrically couple the base member 30 and the quartz crystal resonator 10, and mechanically hold the quartz crystal resonator 10. The conductive holding member 36a electrically couples the first coupling electrode 16a of the quartz crystal resonator 10 to the coupling electrode 33a of the base member 30. The conductive holding member 36b electrically couples the second coupling electrode 16b of the quartz crystal resonator 10 to the coupling electrode 33b of the base member 30. The conductive holding members 36a and 36b are solidified products of a conductive adhesive including a thermosetting resin, a photocurable resin, or the like. The main component of the conductive holding members 36a and 36b is, for example, a silicone resin. The conductive holding members 36a and 36b include conductive particles, and as the conductive particles, for example, metal particles including silver (Ag) are used.

It is noted that the main component of the conductive holding members 36a and 36b is not limited to a silicone resin, and may be, for example, an epoxy resin or an acrylic resin. In addition, the conductive particles included in the conductive holding members 36a and 36b are not limited to silver particles, and may be formed of other metals, conductive ceramics, conductive organic materials, and the like. The conductive holding members 36a and 36b may include a conductive polymer.

The lid member 40 forms an internal space 39 in which the quartz crystal resonator 10 is accommodated between the lid member 40 and the base member 30. The lid member 40 has the top wall portion 41, a side wall portion 42 extending from an outer peripheral portion of the top wall portion 41 toward the base member 30, and a flange portion 43 extending from a distal end of the side wall portion 42 toward the outer side portion. The top wall portion 41 faces the base member 30 with the quartz crystal resonator 10 interposed therebetween in the Y′ axis direction. The side wall portions 42 surround the quartz crystal resonator 10 at an interval in the XZ′ plane direction. The flange portion 43 is provided in a frame shape in plan view and is provided to be closest to the base member 30 on the lid member 40. A material of the lid member 40 is desirably a conductive material, and more desirably a metal material having high airtightness. Since the lid member 40 is formed of a conductive material, the lid member 40 has an electromagnetic shield function of reducing electromagnetic waves entering and leaving the internal space 39. From the viewpoint of suppressing generation of a thermal stress, desirably, the material of the lid member 40 is a material having a thermal expansion coefficient close to that of the base member 30, and is, for example, an Fe—Ni—Co alloy of which the thermal expansion coefficient near room temperature matches that of glass or ceramic over a wide temperature range. The lid member 40 is electrically coupled to at least one of the outer electrodes 35c and 35d by a ground member (not shown).

The bonding portion 50 bonds the base member 30 and the lid member 40 to seal the internal space 39. The bonding portion 50 is provided in a frame shape along the entire periphery of the flange portion 43 on the base member 30, and is interposed between the lower surface of the flange portion 43 of the lid member 40 and the upper surface 31A of the base member 30. The bonding portion 50 is formed of an insulating material. The bonding portion 50 is formed of, for example, an organic adhesive including an epoxy-based resin, a vinyl-based resin, an acrylic-based resin, an urethane-based resin, or a silicone resin. It is noted that the material of the bonding portion 50 is not limited to an organic adhesive, and may be an inorganic adhesive such as a silicon-based adhesive containing water glass or a calcium-based adhesive containing cement. Moreover, the material of the bonding portion 50 may be glass having a low melting point (for example, a lead borate-based or tin phosphate-based glass).

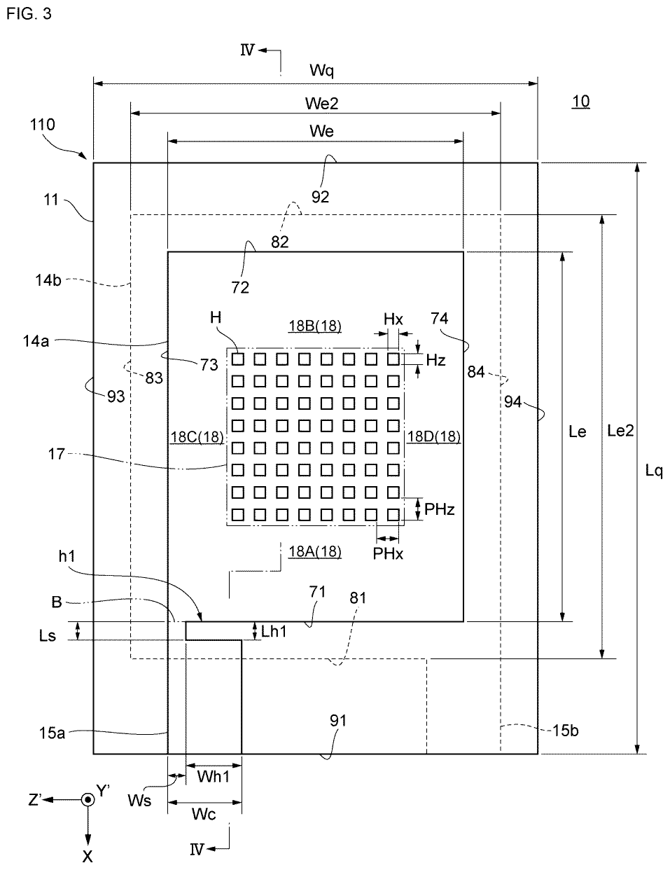

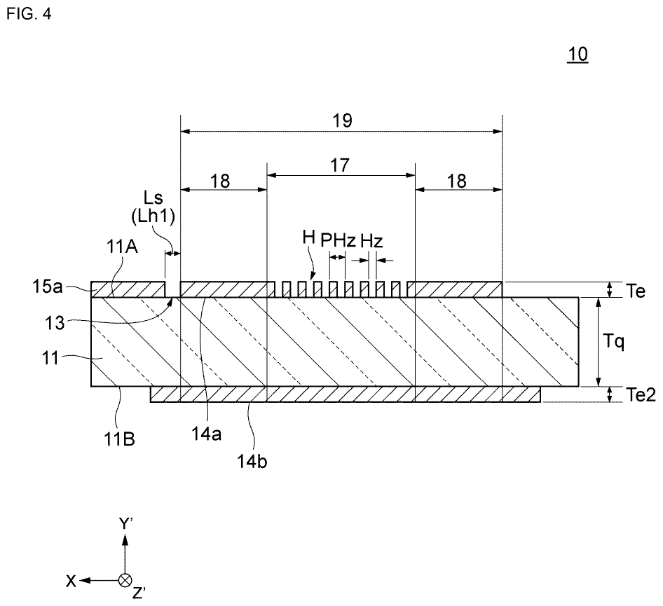

Next, a configuration of the quartz crystal resonator 10 according to the first embodiment will be described with reference to FIG. 3 and FIG. 4. FIG. 3 is a plan view of the quartz crystal resonator according to the first embodiment. FIG. 4 is a cross-sectional view of the quartz crystal resonator according to the first embodiment. FIG. 4 is a cross-sectional view taken along line IV-IV of the quartz crystal resonator shown in FIG. 3. In FIG. 3, the IV-IV line crosses a second low acoustic velocity region 18B and a high acoustic velocity region 17 from the negative X axis direction side of the quartz crystal resonator 10 in the X axis direction, bends in a first low acoustic velocity region 18A, extends in the X axis direction, bends again, and crosses a cavity h1 and the first extended electrode 15a to the positive X axis direction side of the quartz crystal resonator 10 in the X axis direction. In addition, in order to simplify the description, the first coupling electrode 16a and the second coupling electrode 16b are not shown in FIG. 3 or 4.

The quartz crystal resonator 10 has an excitation region 19, the high acoustic velocity region 17, and the low acoustic velocity region 18. The excitation region 19 is a region where the first excitation electrode 14a and the second excitation electrode 14b overlap with each other, and is a region where the quartz crystal element 11 is excited when a voltage is applied thereto. The high acoustic velocity region 17 is a region in the excitation region 19 where the acoustic velocity is greater than the average acoustic velocity in the entire excitation region 19. The low acoustic velocity region 18 is a region in the excitation region 19 where the acoustic velocity is less than the average acoustic velocity in the entire excitation region 19. The acoustic velocity in the low acoustic velocity region 18 is less than the acoustic velocity in the high acoustic velocity region 17. The acoustic velocity in the region where the first extended electrode 15a and the second excitation electrode 14b overlap with each other is less than the acoustic velocity in the high acoustic velocity region 17 and is equal to or greater than the acoustic velocity in the low acoustic velocity region 18.

As shown in FIG. 3, the planar shape of the excitation region 19 is a rectangular shape having a pair of sides extending along the X axis direction and a pair of sides extending along the Z′ axis direction. The planar shape of the excitation region 19 is determined by the planar shape of the first excitation electrode 14a, the planar shape of the second excitation electrode 14b, and the positional relationship between the first excitation electrode 14a and the second excitation electrode 14b.

As shown in FIG. 3, in plan view, the high acoustic velocity region 17 is positioned at a center portion in the excitation region 19. The planar shape of the high acoustic velocity region 17 is a rectangular shape having a pair of sides extending along the X axis direction and a pair of sides extending along the Z′ axis direction.

It is noted that the planar shape of the high acoustic velocity region is not limited to the shape described above. The planar shape of the high acoustic velocity region may have a rectangular shape having a side extending along a direction intersecting the Z axis direction and the Z′ axis direction. The planar shape of the high acoustic velocity region may be a rectangular shape or a square shape. The planar shape of the high acoustic velocity region may be a polygonal shape, a circular shape, an elliptical shape, or a combination thereof.

In addition, in plan view, the high acoustic velocity region may be provided from an end portion of the excitation region on the positive Z′ axis direction side to an end portion on the negative Z′ axis direction side, or may be provided from an end portion of the excitation region on the positive X axis direction side to an end portion on the negative X axis direction side.

As shown in FIG. 3, in plan view, the low acoustic velocity region 18 is positioned at the peripheral portion in the excitation region 19. The low acoustic velocity region 18 is provided in a rectangular frame shape surrounding the high acoustic velocity region 17. The low acoustic velocity region 18 includes the first low acoustic velocity region 18A, the second low acoustic velocity region 18B, a third low acoustic velocity region 18C, and a fourth low acoustic velocity region 18D.

The first low acoustic velocity region 18A is adjacent to the high acoustic velocity region 17 on the positive X axis direction side, and extends along the Z′ axis direction. The second low acoustic velocity region 18B is adjacent to the high acoustic velocity region 17 on the negative X axis direction side and extends along the Z′ axis direction. The third low acoustic velocity region 18C is adjacent to the high acoustic velocity region 17 on the positive Z′ axis direction side and extends along the X axis direction. The fourth low acoustic velocity region 18D is adjacent to the high acoustic velocity region 17 on the negative Z′ axis direction side and extends along the X axis direction. An end portion of the first low acoustic velocity region 18A on the positive Z′ axis direction side is coupled to an end portion of the third low acoustic velocity region 18C on the positive X axis direction side, and an end portion of the first low acoustic velocity region 18A on the negative Z′ axis direction side is coupled to an end portion of the fourth low acoustic velocity region 18D on the positive X axis direction side. An end portion of the second low acoustic velocity region 18B on the positive Z′ axis direction side is coupled to an end portion of the third low acoustic velocity region 18C on the negative X axis direction side, and an end portion of the second low acoustic velocity region 18B on the negative Z′ axis direction side is coupled to an end portion of the fourth low acoustic velocity region 18D on the negative X axis direction side.

In plan view, the end portion of the first low acoustic velocity region 18A on the positive Z′ axis direction side overlaps with the end portion of the third low acoustic velocity region 18C on the positive X axis direction side, and the end portion of the first low acoustic velocity region 18A on the negative Z′ axis direction side overlaps with the end portion of the fourth low acoustic velocity region 18D on the positive X axis direction side. The end portion of the second low acoustic velocity region 18B on the positive Z′ axis direction side overlaps with the end portion of the third low acoustic velocity region 18C on the negative X axis direction side, and the end portion of the second low acoustic velocity region 18B on the negative Z′ axis direction side overlaps with the end portion of the fourth low acoustic velocity region 18D on the negative X axis direction side.

The planar shape of the low acoustic velocity region is determined by the planar shape of the excitation region and the planar shape of the high acoustic velocity region and is not limited to the above. The planar shape of the low acoustic velocity region may be a polygonal shape, a circular shape, an elliptical shape, or a frame shape which is a combination of these shapes. Further, the third low acoustic velocity region and the fourth low acoustic velocity region may be omitted. That is, the high acoustic velocity region, the first low acoustic velocity region, and the second low acoustic velocity region may be provided in a strip shape extending in parallel with each other along the Z′ axis direction. In addition, the first low acoustic velocity region and the second low acoustic velocity region may be omitted, and the high acoustic velocity region, the third low acoustic velocity region, and the fourth low acoustic velocity region may be provided in a strip shape extending in parallel with each other along the X axis direction. Further, the end portion of the first low acoustic velocity region on the positive Z′ axis direction side may be separated from the third low acoustic velocity region, and the end portion of the first low acoustic velocity region on the negative Z′ axis direction side may be separated from the fourth low acoustic velocity region. The end portion of the second low acoustic velocity region on the positive Z′ axis direction side may be separated from the third low acoustic velocity region, and the end portion of the second low acoustic velocity region on the negative Z′ axis direction side may be separated from the fourth low acoustic velocity region.

As shown in FIG. 3, in plan view, the quartz crystal element 11 has outer peripheral portions 91, 92, 93, and 94. The outer peripheral portion 91 is an outer peripheral portion of one side among the four sides of the quartz crystal element 11 in plan view, the one side extending along the Z′ axis direction on the positive X axis direction side. The outer peripheral portion 92 is an outer peripheral portion of one side of the four sides of the quartz crystal element 11 in plan view, the one side extending along the Z′ axis direction on the negative X axis direction side. The outer peripheral portion 93 is an outer peripheral portion of one side of the four sides of the quartz crystal element 11 in plan view, the one side extending along the X axis direction on the positive Z′ axis direction side. The outer peripheral portion 94 is an outer peripheral portion of one side of the four sides of the quartz crystal element 11 in plan view, the one side extending along the X axis direction on the negative Z′ axis direction side.

As shown in FIG. 3, in plan view, the first excitation electrode 14a has outer peripheral portions 71, 72, 73, and 74. The outer peripheral portion 71 is an outer peripheral portion of one side of the four sides of the first excitation electrode 14a in plan view, the one side extending along the Z′ axis direction on the positive X axis direction side. The outer peripheral portion 72 is an outer peripheral portion of one side of the four sides of the first excitation electrode 14a in plan view, the one side extending along the Z′ axis direction on the negative X axis direction side. The outer peripheral portion 73 is an outer peripheral portion of one side of the four sides of the first excitation electrode 14a in plan view, the one side extending along the X axis direction on the positive Z′ axis direction side. The outer peripheral portion 74 is an outer peripheral portion of one side of the four sides of the first excitation electrode 14a in plan view, the one side extending along the X axis direction on the negative Z′ axis direction side. The outer peripheral portions 71, 72, 73, and 74 correspond to an example of a first outer peripheral portion.

As shown in FIG. 3, in plan view, the second excitation electrode 14b has outer peripheral portions 81, 82, 83, and 84. The outer peripheral portion 81 is an outer peripheral portion of one side of the four sides of the second excitation electrode 14b in plan view, the one side extending along the Z′ axis direction on the positive X axis direction side. The outer peripheral portion 82 is an outer peripheral portion of one side of the four sides of the second excitation electrode 14b in plan view, the one side extending along the Z′ axis direction on the negative X axis direction side. The outer peripheral portion 83 is an outer peripheral portion of one side of the four sides of the second excitation electrode 14b in plan view, the one side extending along the X axis direction on the positive Z′ axis direction side. The outer peripheral portion 84 is an outer peripheral portion of one side of the four sides of the second excitation electrode 14b in plan view, the one side extending along the X axis direction on the negative Z′ axis direction side. The outer peripheral portions 81, 82, 83, and 84 correspond to an example of a first outer peripheral portion.

In plan view, the second excitation electrode 14b is smaller than the quartz crystal element 11, and the outer peripheral portions 81, 82, 83, and 84 of the second excitation electrodes 14b are provided inside the outer peripheral portions 91, 92, 93, and 94 of the quartz crystal element 11. The first excitation electrode 14a is smaller than the second excitation electrode 14b, and the outer peripheral portions 71, 72, 73, and 74 of the first excitation electrode 14a are provided inside the outer peripheral portions 81, 82, 83, and 84 of the second excitation electrode 14b. In plan view, the outer peripheral portion 71, the outer peripheral portion 81, and the outer peripheral portion 91 are provided in parallel, the outer peripheral portion 72, the outer peripheral portion 82, and the outer peripheral portion 92 are provided in parallel, the outer peripheral portion 73, the outer peripheral portion 83, and the outer peripheral portion 93 are provided in parallel, and the outer peripheral portion 74, the outer peripheral portion 84, and the outer peripheral portion 94 are provided in parallel.

As shown in FIG. 3, in plan view, a dimension of the quartz crystal element 11 along the X axis direction is defined as a length Lq, and a dimension of the quartz crystal element 11 in the Z′ axis direction is defined as a length Wq. A dimension of the first excitation electrode 14a along the X axis direction is defined as a length Le, and a dimension of the first excitation electrode 14a along the Z′ axis direction is defined as a length We. A dimension of the second excitation electrode 14b along the X axis direction is defined as a length Le2, and a dimension of the second excitation electrode 14b along the Z′ axis direction is defined as a length We2.

The length Lq is a distance between the outer peripheral portion 91 and the outer peripheral portion 92 along the X axis direction at a predetermined position, and is specified, for example, as a distance between the outer peripheral portion 91 and the outer peripheral portion 92 in the X axis direction. The predetermined position is, for example, on a straight line that passes through the center of the quartz crystal element 11 in plan view and extends in the X axis direction. The length Lq may be specified as an average value or a maximum value of distances between the outer peripheral portion 91 and the outer peripheral portion 92 in the X axis direction. The length Wq is a distance along the Z′ axis direction between the outer peripheral portion 93 and the outer peripheral portion 94 at a predetermined position, and is specified as, for example, a distance between the outer peripheral portion 93 and the outer peripheral portion 94 in the Z′ axis direction. The predetermined position is, for example, on a straight line that passes through the center of the quartz crystal element 11 in plan view and extends in the Z′ axis direction. The length Wq may be specified as an average value or a maximum value of the distances between the outer peripheral portion 93 and the outer peripheral portion 94 in the Z′ axis direction.

Similarly, the length Le is a distance between the outer peripheral portion 71 and the outer peripheral portion 72 along the X axis direction at a predetermined position (for example, on a straight line passing through the center of the first excitation electrode 14a and extending in the X axis direction), and is specified as, for example, a distance between the outer peripheral portion 71 and the outer peripheral portion 72 in the X axis direction. The length Le may be specified as an average value or a maximum value of distances between the outer peripheral portion 71 and the outer peripheral portion 72 in the X axis direction. The length We is a distance between the outer peripheral portion 73 and the outer peripheral portion 74 along the Z′ axis direction at a predetermined position (for example, on a straight line passing through the center of the first excitation electrode 14a and extending in the Z′ axis direction), and is specified as, for example, a distance between the outer peripheral portion 73 and the outer peripheral portion 74 in the Z′ axis direction. The length We may be specified as an average value or a maximum value of the distances between the outer peripheral portion 73 and the outer peripheral portion 74 in the Z′ axis direction. The length Le2 is a distance between the outer peripheral portion 81 and the outer peripheral portion 82 along the X axis direction at a predetermined position (for example, on a straight line passing through the center of the second excitation electrode 14b and extending in the X axis direction), and is specified as, for example, a distance between the outer peripheral portion 81 and the outer peripheral portion 82 in the X axis direction. The length Le2 may be specified as an average value or a maximum value of distances between the outer peripheral portion 81 and the outer peripheral portion 82 in the X axis direction. The length We2 is a distance between the outer peripheral portion 83 and the outer peripheral portion 84 along the Z′ axis direction at a predetermined position (for example, on a straight line passing through the center of the second excitation electrode 14b and extending in the Z′ axis direction), and is specified as, for example, a distance between the outer peripheral portion 83 and the outer peripheral portion 84 in the Z′ axis direction. The length We2 may be specified as an average value or a maximum value of the distances between the outer peripheral portion 83 and the outer peripheral portion 84 in the Z′ axis direction.

Since the planar shape of the quartz crystal element 11 is a rectangular shape in which the X axis direction is the longitudinal direction, the length Lq is greater than the length Wq (Wq<Lq). Since the planar shapes of the first excitation electrode 14a and the second excitation electrode 14b are also the same rectangular shape, the length Le is greater than the length We (We<Le), and the length Le2 is greater than the length We2 (We2<Le2). Since all of the outer peripheral portions 81, 82, 83, and 84 of the second excitation electrode 14b are positioned inside the outer peripheral portions 91, 92, 93, and 94 of the quartz crystal element 11, the length Lq is greater than the length Le2 (Le2<Lq), and the length Wq is greater than the length We2 (We2<Wq). Since all the outer peripheral portions 71, 72, 73, and 74 of the first excitation electrode 14a are positioned inside the outer peripheral portions 81, 82, 83, and 84 of the second excitation electrode 14b, the length Le2 is greater than the length Le (Le<Le2), and the length We2 is greater than the length We (We<We2). In summary, the relationship of Le<Le2<Lq and We<We2<Wq is established.

As shown in FIG. 4, a thickness of the quartz crystal element 11 is defined as Tq, a thickness of the first excitation electrode 14a is defined as Te, and a thickness of the second excitation electrode 14b is defined as Te2.

The thickness Tq is a distance between the upper surface 11A and the lower surface 11B along the Y′ axis direction at a predetermined position, and is specified as, for example, a distance between the upper surface 11A and the lower surface 11B in the Y′ axis direction. The predetermined position is, for example, a straight line that passes through the center of the excitation region 19 and extends in the Y′ axis direction. The thickness Tq may be specified as an average value or a maximum value of the distance between the upper surface 11A and the lower surface 11B in the Y′ axis direction in the excitation region 19.

Similarly, the thickness Te is a distance between the upper surface and the lower surface of the first excitation electrode 14a along the Y′ axis direction at a predetermined position (for example, on a straight line passing through the center of the excitation region 19 and extending in the Y′ axis direction), and is specified as, for example, a distance between the upper surface and the lower surface of the first excitation electrode 14a in the Y′ axis direction. The thickness Te may be specified as an average value or a maximum value of the distance between the upper surface and the lower surface of the first excitation electrode 14a in the Y′ axis direction in the excitation region 19. The thickness Te2 is a distance between the upper surface and the lower surface of the second excitation electrode 14b along the Y′ axis direction at a predetermined position (for example, on a straight line passing through the center of the excitation region 19 and extending in the Y′ axis direction), and is specified as, for example, a distance between the upper surface and the lower surface of the second excitation electrode 14b in the Y′ axis direction. The thickness Te2 may be specified as an average value or a maximum value of the distance between the upper surface and the lower surface of the second excitation electrode 14b in the Y′ axis direction in the excitation region 19.

The thickness Tq and the thickness Te2 are substantially constant across the high acoustic velocity region 17 and the low acoustic velocity region 18. The thickness Te is substantially constant over the high acoustic velocity region 17 and the low acoustic velocity region 18, except for a part in which a plurality of hole portions H and the cavities h1, which will be described later, are formed.

The thickness Tq is greater than the thickness Te and the thickness Te2, and the thickness Te is equal to the thickness Te2 (Te=Te2<Tq). In addition, the thickness Tq is greater than the total of the thickness Te and the thickness Te2 (Te+Te2<Tq). However, it is noted that the magnitude relationship between the thickness Te and the thickness Te2 is not limited to the above, and a relationship of Te<Te2 may be established, or a relationship of Te2<Te may be established.

The thickness of the first extended electrode 15a is equal to the thickness Te of the first excitation electrode 14a. That is, the first electrode has a uniform thickness Te. In addition, the thickness of the second extended electrode 15b is equal to the thickness Te2 of the second excitation electrode 14b. That is, the second electrode has a uniform thickness Te2.

As shown in FIGS. 3 and 4, a plurality of hole portions H (simply referred to as “holes”) are provided in the first excitation electrode 14a of the high acoustic velocity region 17. Therefore, the average mass of the quartz crystal resonator 10 in the high acoustic velocity region 17 is smaller than the average mass of the quartz crystal resonator 10 in the low acoustic velocity region 18. Due to the effect of the decrease in the average mass, the acoustic velocity in the high acoustic velocity region 17 is greater than the acoustic velocity in the low acoustic velocity region 18. By providing the high acoustic velocity region 17 and the low acoustic velocity region 18 in the excitation region 19, the electromechanical coupling coefficient k(%) of the spurious mode is suppressed, and the electromechanical coupling coefficient k(%) of the main mode is improved.

As shown in FIG. 4, the hole portion H is a through-hole that passes through the first excitation electrode 14a in the Y′ axis direction. Here, the hole portion is not limited to the through-hole, and the hole portion may have a groove shape with a bottom that is open in the Y′ axis direction. In addition, the hole portion may be provided in the second excitation electrode or may be provided in both the first excitation electrode and the second excitation electrode.

As shown in FIG. 3, the planar shape of the hole portion His a square shape having a pair of sides extending along the Z′ axis direction and a pair of sides extending along the X axis direction. Therefore, when a dimension of the hole portion H in the X axis direction is defined as Hx and a dimension in the Z′ axis direction is defined as Hz, Hx=Hz.

It is noted that the planar shape of the hole portion is not limited to a square shape having sides extending along the X axis direction and the Z′ axis direction. For example, the planar shape of the hole portion may be a rectangular shape of Hx<Hz or Hz<Hx, or may be a rectangular shape having a side extending along a direction intersecting the X axis direction and the Z′ axis direction. The planar shape of the hole portion may be a polygonal shape, a circular shape, an elliptical shape, or a combination thereof.

As shown in FIG. 3, the plurality of hole portions H are arranged in a matrix along the X axis direction and the Z′ axis direction. An array period of the plurality of hole portions H in the Z′ axis direction, that is, a distance between the end portions of two hole portions H, which are adjacent to each other in the Z′ axis direction and are on the negative Z′ axis direction side, is defined as PHz. An array period of the hole portions H in the X axis direction, that is, a distance between the end portions of two hole portions H, which are adjacent to each other in the X axis direction and are on the negative X axis direction side, is defined as PHx. The plurality of hole portions H are arranged at equal intervals in each of the Z′ axis direction and the X axis direction. That is, PHz=PHx.

It is noted that the array period of the plurality of hole portions H is not limited to the array period described above, and may be PHz<PHx or may be PHx<PHz. Further, the form in which the plurality of hole portions H are arranged is not limited to the form described above. The plurality of hole portions H may be arranged along a direction intersecting the Z′ axis direction and the X axis direction. The plurality of hole portions H may be arranged in a staggered manner or may be arranged in an irregular manner.

In an exemplary aspect case where the hole portion His a through-hole, in order to make the inside of the hole portion H in the high acoustic velocity region 17 function as a part of the first excitation electrode 14a, desirably, a relationship of 0<Hr/Tq≤2.0 is established when the thickness of the quartz crystal element 11 is defined as Tq and the inner diameter of the hole portion H is defined as Hr. In this case, since the decrease rate of the electrostatic capacity due to the hole portion His suppressed to 1% or less, the inside of the hole portion H can also sufficiently function as an excitation electrode. In addition, further desirably, the relationship of 0<Hr/Tq≤1.5 is established, and still further desirably, the relationship of 0<Hr/Tq≤1.0 is established. When 0<Hr/Tq≤1.5, the decrease rate of the electrostatic capacity is suppressed to 0.5% or less, and when 0<Hr/Tq≤1.0, the decrease rate of the electrostatic capacity is suppressed to 0.1% or less. In order to form the hole portion H with a sufficient processing accuracy, desirably, 0.1≤Hr/Tq, and further desirably, 0.5≤Hr/Tq.

The inner diameter Hr of the hole portion His defined as the length of one side in a case where the hole portion H has a square shape (Hr=Hx=Hz), and is defined as the length of one side when the shape of the hole portion H is converted into a square shape while keeping the area constant in a case where the hole portion H has a shape other than a square shape.

As shown in FIG. 3, the first extended electrode 15a is coupled to a corner formed by the outer peripheral portion 71 and the outer peripheral portion 73 of the first excitation electrode 14a. In addition, the first extended electrode 15a is coupled only to the outer peripheral portion 71 among the outer peripheral portions 71, 72, 73, and 74 of the first excitation electrode 14a. Therefore, a boundary B between the first excitation electrode 14a and the first extended electrode 15a is positioned on the extension line of the outer peripheral portion 71. A coupling portion between the first excitation electrode 14a and the first extended electrode 15a overlaps with the second excitation electrode 14b.

It is noted that the coupling position of the first extended electrode with respect to the first excitation electrode is not limited to the above described above. For example, the first extended electrode may be coupled to both the outer peripheral portion 71 and the outer peripheral portion 73 at the corner of the first excitation electrode. The first extended electrode may be coupled to a center portion of the outer peripheral portion 71 of the first excitation electrode in the Z′ axis direction.

As shown in FIG. 3, the second extended electrode 15b is coupled to a corner formed by the outer peripheral portion 81 and the outer peripheral portion 84 of the second excitation electrode 14b. In addition, the second extended electrode 15b is coupled only to the outer peripheral portion 81 among the outer peripheral portions 81, 82, 83, and 84 of the second excitation electrode 14b.

It is noted that the coupling position of the second extended electrode with respect to the second excitation electrode is not limited to the configuration described above. For example, the second extended electrode may be coupled to both the outer peripheral portion 81 and the outer peripheral portion 84 at the corner of the second excitation electrode. The second extended electrode may be coupled to a center portion of the outer peripheral portion 81 of the second excitation electrode in the Z′ axis direction. However, from the viewpoint of suppressing the occurrence of spurious vibration between the first extended electrode and the second extended electrode, desirably, the first extended electrode does not overlap with the second extended electrode in plan view, and more desirably, the first extended electrode is as far as possible from the second extended electrode.

As shown in FIG. 3, the cavity h1 is provided in the first electrode in a region overlapping with the coupling portion between the first excitation electrode 14a and the first extended electrode 15a. That is, the plurality of hole portions H and the cavity h1 are provided on the first electrode on the same side of the quartz crystal resonator 10. The cavity h1 overlaps with the second electrode. The cavity h1 is provided on the first extended electrode 15a side of the boundary B between the first excitation electrode 14a and the first extended electrode 15a. The cavity h1 is provided within a range of a distance of four times or less the thickness Tq of the quartz crystal element 11 from the boundary B. The cavity h1 is a through-hole that passes through the first excitation electrode 14a in the Y′ axis direction. The cavity h1 is provided in a slit shape having a longitudinal shape extending in a direction parallel to the boundary B. The planar shape of the cavity h1 is a rectangular shape having a pair of long sides extending along the Z′ axis direction and a pair of short sides extending along the X axis direction. In addition, the cavity h1 is provided in a notch shape that is open on the negative Z′ axis direction side of the first extended electrode 15a.

The position where the cavity is provided is not particularly limited as long as the position is within a region overlapping with the coupling portion between the first excitation electrode 14a and the first extended electrode 15a, that is, substantially, within a range of a distance of four times or less the thickness Tq of the quartz crystal element 11 from the boundary B between the first excitation electrode 14a and the first extended electrode 15a. For example, the cavity may be provided on the side of the first excitation electrode 14a of the boundary B, or may be provided on both the first extended electrode 15a and the first excitation electrode 14a across the boundary B. In an exemplary aspect where the cavity is provided in the first extended electrode 15a, the cavity may be provided in a notch shape that is open on the positive Z′ axis direction side of the first extended electrode 15a. The cavity may be provided in the first electrode in an island shape surrounded by the first electrode. The cavity may be provided in the second electrode or may be provided in both the first electrode and the second electrode. The longitudinal direction of the slit-shaped cavity is, for example, a direction parallel to the boundary B, but may be a direction intersecting the boundary B as long as the direction is a direction along the boundary B. Here, the direction along the boundary B is a direction in which the absolute value of the angle formed with the boundary B is 45° or less, and for example, a direction in which the absolute value of the angle formed with the boundary B is 30° or less may be used, or a direction in which the absolute value of the angle formed with the boundary B is 20° or less may be used. In an exemplary aspect where the longitudinal direction of the slit-shaped cavity is the direction along the boundary B, the angle formed with the longitudinal direction of the slit-shaped cavity and the boundary B is, for example, −45° or more and 45° or less.

For purposes of this disclosure, the expression “the cavity is provided substantially within a range of a distance of four times or less the thickness Tq of the quartz crystal element 11 from the boundary B between the first excitation electrode 14a and the first extended electrode 15a” indicates that 90% or more of the cavity is positioned within a range of a distance of four times or less the thickness Tq of the quartz crystal element 11 from the boundary B between the first excitation electrode 14a and the first extended electrode 15a. Furthermore, desirably, the cavity is provided substantially in a range of a distance of three and a half times or less the thickness Tq of the quartz crystal element 11 from the boundary B, and more desirably, the cavity is provided substantially in a range of a distance three times or less the thickness Tq of the quartz crystal element 11 from the boundary B. In addition, desirably, all of the cavities are provided in a range of a distance of four times or less the thickness Tq of the quartz crystal element 11 from the boundary B, more desirably, all of the cavities are provided in a range of a distance of three and a half times or less the thickness Tq of the quartz crystal element 11 from the boundary B, and even more desirably, all of the cavities are provided in a range of a distance of three times or less the thickness the thickness Tq of the quartz crystal element 11 from the boundary B.

It is noted that the number of cavities is not limited to one. For example, when the cavity has a slit shape having a longitudinal shape extending in a direction along the boundary B, a plurality of slit-shaped cavities may be provided to be arranged in a direction intersecting the boundary B. In addition, the cavities may be a plurality of cavities arranged in a row, with the cavities arranged in a direction along the boundary B. Further, the plurality of cavities arranged in a row may be provided in a direction intersecting the boundary B in a case where the direction is along the boundary B. In this case, the angle formed with the direction, in which the cavities are arranged in a row, and the boundary B is, for example, −45° or more and 45° or less.

The longitudinal direction of the slit-shaped cavity and the direction in which the cavities are arranged in a row may be a direction along a direction orthogonal to the boundary B (hereinafter referred to as a “direction orthogonal to the boundary B”). Here, the direction along the direction orthogonal to the boundary B is a direction in which the absolute value of the angle formed with the boundary B is greater than 45° and less than 135°, and for example, the direction may be a direction in which the absolute value of the angle formed with the boundary B is greater than 60° and less than 120°, or may be a direction in which the absolute value of the angle formed with the boundary B is greater than 70° and less than 110°.

As shown in FIG. 3, a dimension of the cavity h1 along the X axis direction is defined as a length Lh1, and a dimension of the cavity h1 along the Z′ axis direction is defined as a length Wh1. In the first extended electrode 15a, a dimension of a part (hereinafter referred to as a “narrow passage portion”) narrowed by the cavity h1 along the X axis direction is referred to as a length Ls, and a dimension of the narrow passage portion along the Z′ axis direction is referred to as a length Ws.

The length Lh1 is a distance between the long sides of the cavities h1 at a predetermined position along the X axis direction, and is specified as, for example, a distance between the long sides of the cavities h1 in the X axis direction. The predetermined position is, for example, on a straight line that passes through the center of the cavity h1 in plan view and extends in the X axis direction. The length Lh1 may be specified as an average value or a maximum value of distance between the long sides of the cavities h1 in the X axis direction. The length Wh1 is a distance between the short sides of the cavities h1 along the Z′ axis direction at a predetermined position, and is specified as, for example, a distance between the short sides of the cavities h1 in the Z′ axis direction. The predetermined position is, for example, on a straight line that passes through the center of the cavity h1 in plan view and extends in the Z′ axis direction. The length Wh1 may be specified as an average value or a maximum value of distance between the short sides of the cavities h1 in the Z′ axis direction.

The length Ls is specified in the same manner as the length Lh1. The length Ws is a distance along the Z′ axis direction between an end portion of the narrow passage portion on the positive Z′ axis direction side and an end portion of the narrow passage portion on the negative Z′ axis direction side at a predetermined position, and is specified, for example, as a distance in the Z′ axis direction between the end portion of the narrow passage portion on the positive Z′ axis direction side and the end portion of the narrow passage portion on the negative Z′ axis direction side. The predetermined position is, for example, on a straight line that passes through the center of the narrow passage portion in plan view and extends in the Z′ axis direction. The length Ws may be specified as an average value or a minimum value of the distances in the Z′ axis direction between the end portion of the narrow passage portion on the positive Z′ axis direction side and the end portion of the narrow passage portion on the negative Z′ axis direction side. The length Ws may be calculated by subtracting the length Wh1 from the length Wc. In an exemplary aspect where the cavity is provided at the center portion of the first extended electrode 15a in the Z′ axis direction and the narrow passage portions are formed on both the positive Z′ axis direction side and the negative Z′ axis direction side with respect to the cavity, the length Ws is specified as a total of a dimension of the narrow passage portion on the positive Z′ axis direction side in the Z′ axis direction and a dimension of the narrow passage portion on the negative Z′ axis direction side in the Z′ axis direction.

The length Wc is a distance along the Z′ axis direction between the end portion of the first extended electrode 15a on the positive Z′ axis direction side and the end portion of the first extended electrode 15a on the negative Z′ axis direction side at a predetermined position, and is specified, for example, as a distance in the Z′ axis direction between the end portion of the first extended electrode 15a on the positive Z′ axis direction side and the end portion of the first extended electrode 15a on the negative Z′ axis direction side. The predetermined position is, for example, a straight line that is at equal intervals from the second excitation electrode 14b and the first coupling electrode 16a in the X axis direction in plan view and extends in the Z′ axis direction. The length Wc may be specified as an average value or a maximum value of distances in the Z′ axis direction between the end portion of the first extended electrode 15a on the positive Z′ axis direction side and the end portion of the first extended electrode 15a on the negative Z′ axis direction side. The length Wc corresponds to the length of the first extended electrode 15a in the direction parallel to the boundary B.

The length Wh1 is greater than the length Lh1 (Lh1<Wh1). The length Lh1 is equal to the length Ls (Lh1=Ls). Desirably, the length Wh1 is equal to or greater than the length Ws (Ws≤Wh1). Desirably, the length Wh1 is 50% or more and 90% or less of the length Wc (Wc×0.50≤Wh1≤Wc×0.90). In an exemplary aspect where a plurality of cavities are provided along the boundary B, desirably, the total length of the plurality of cavities in a direction along the boundary B is 50% or more and 90% or less of the length Wc.

Desirably, a relationship of 2<Lh1/Tq≤Wh1/Tq is established, more desirably, a relationship of 2.5≤Lh1/Tq≤Wh1/Tq is established, even more desirably, a relationship of 3≤Lh1/Tq≤Wh1/Tq is established, still more desirably, a relationship of 3.5≤Lh1/Tq≤Wh1/Tq is established, and still more desirably, a relationship of 4≤Lh1/Tq≤Wh1/Tq is established.

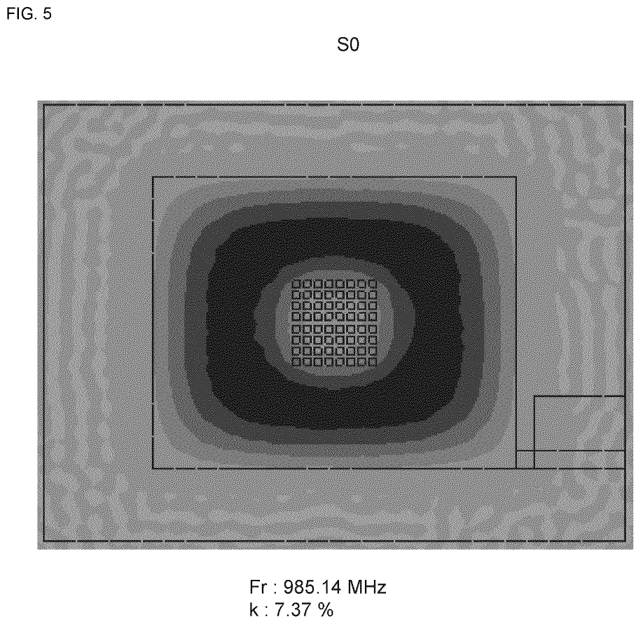

Next, simulation results based on the first embodiment will be described with reference to FIGS. 5 to 13.

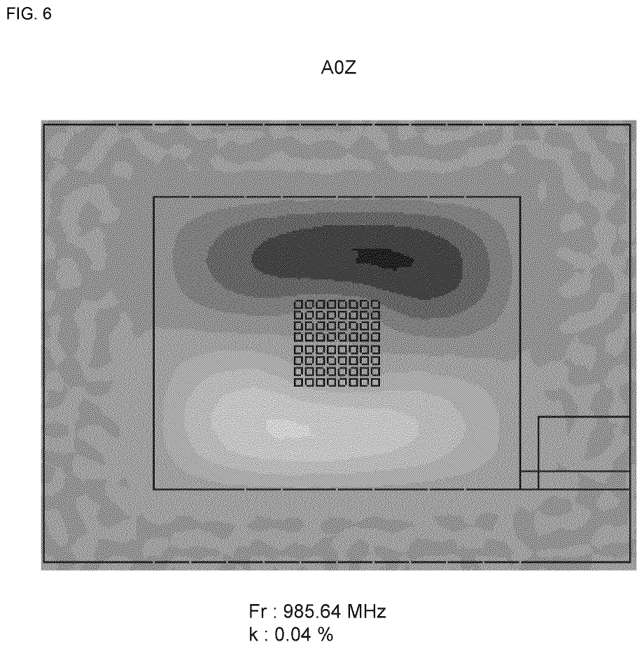

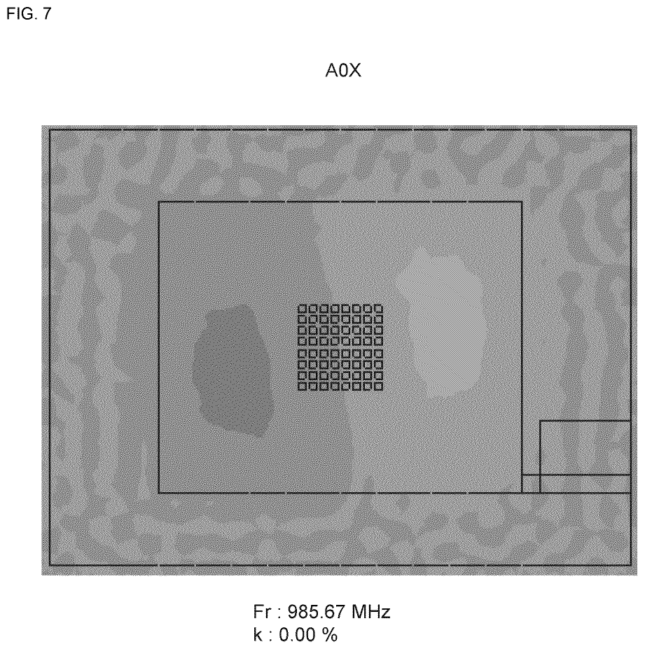

FIGS. 5 to 7 are diagrams showing the vibration distributions of the quartz crystal resonator according to the first embodiment. FIG. 5 shows a vibration distribution in an S0 mode, which is a main mode, as a simulation result based on the first embodiment. FIG. 6 shows a vibration distribution of a mode v (hereinafter referred to as an “A0Z mode”) in which vibrations in opposite phases are arranged in the Z′ axis direction in the A0 mode, which is a spurious mode, as a simulation result based on the first embodiment. FIG. 7 shows a vibration distribution of a mode (hereinafter referred to as an “A0X mode”) in which vibrations in opposite phases are arranged in the X axis direction in the A0 mode, which is a spurious mode, as a simulation result based on the first embodiment. In FIGS. 5 to 7, the first excitation electrode 14a and the first extended electrode 15a are shown, and the second excitation electrode 14b and the second extended electrode 15b are not shown.

The simulation conditions for the vibration distribution based on the first embodiment are as follows. In the simulation conditions, the center of the first excitation electrode 14a and the center of the second excitation electrode 14b overlap with each other in plan view.

$$Tq = 1.52 μm$$

$$Te = Te 2 = 0.08 μm$$

$$Lq = 160 μm$$

$$Wq = 120 μm$$

$$Le = 100 μm$$

$$We = 80 μm$$

$$Le 2 = 120 μm$$

$$We 2 = 100 μm$$

$$Wc = 20 μm$$

$$Hx = Hz = 1.5 μm$$

$$PHx = PHz = 3 μm$$

$$Number of H = 8 \times 8$$

$$Ls = 5 μm$$

$$Ws = 5 μm$$

As shown in FIG. 5, in the first embodiment, the electromechanical coupling coefficient k in the S0 mode (hereinafter referred to as “k_{S0}”) is 7.37%, and the frequency Fr in the S0 mode (hereinafter referred to as “Fr_{S0}”) is 985.14 MHz. As shown in FIG. 6, in the first embodiment, the electromechanical coupling coefficient k in the A0Z mode (hereinafter referred to as “k_{A0Z}”) is 0.04%, and the frequency Fr in the A0Z mode (hereinafter referred to as “Fr_{A0Z}”) is 985.64 MHz. As shown in FIG. 7, in the first embodiment, the electromechanical coupling coefficient k in the A0X mode (hereinafter referred to as “k_{A0X}”) is 0.00%, and the frequency Fr in the A0X mode (hereinafter referred to as “Fr_{A0X}”) is 985.67 MHz.

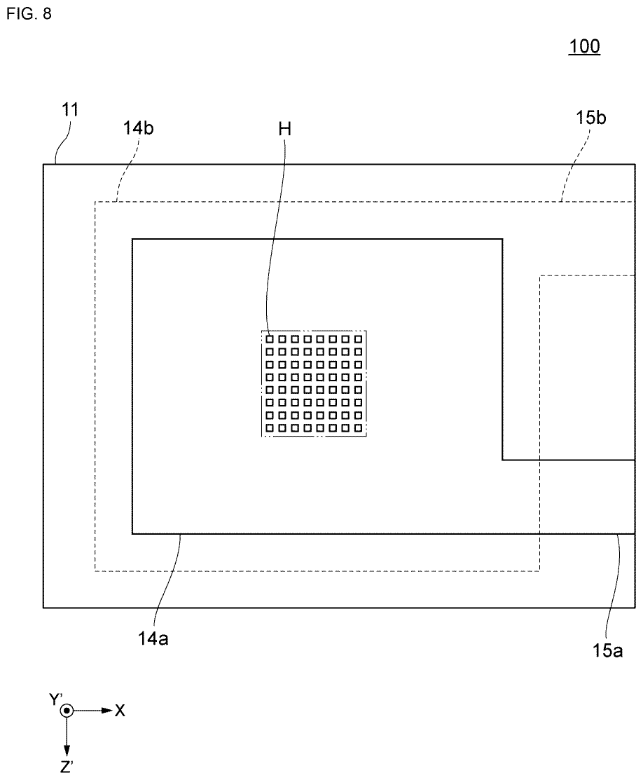

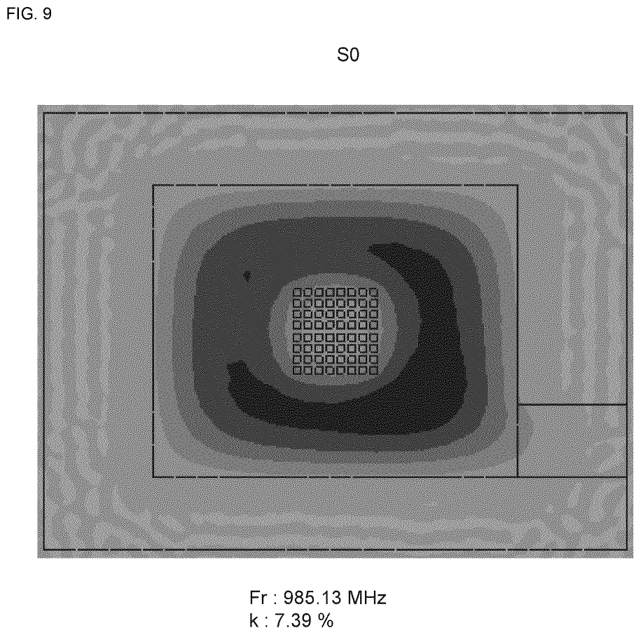

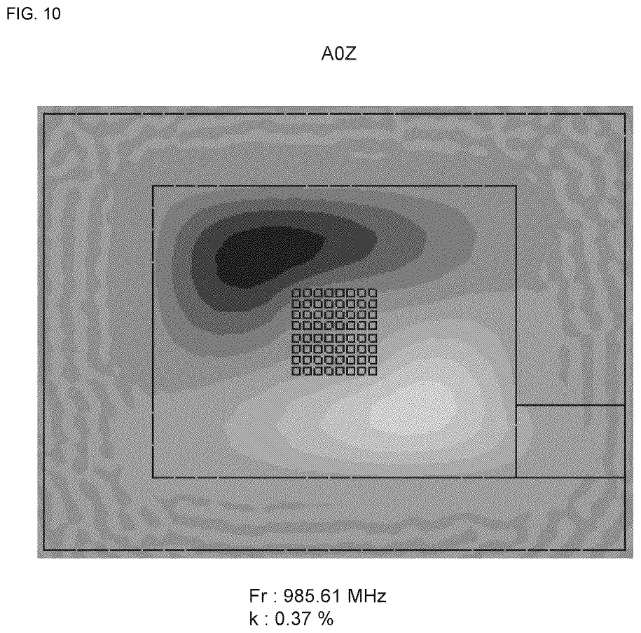

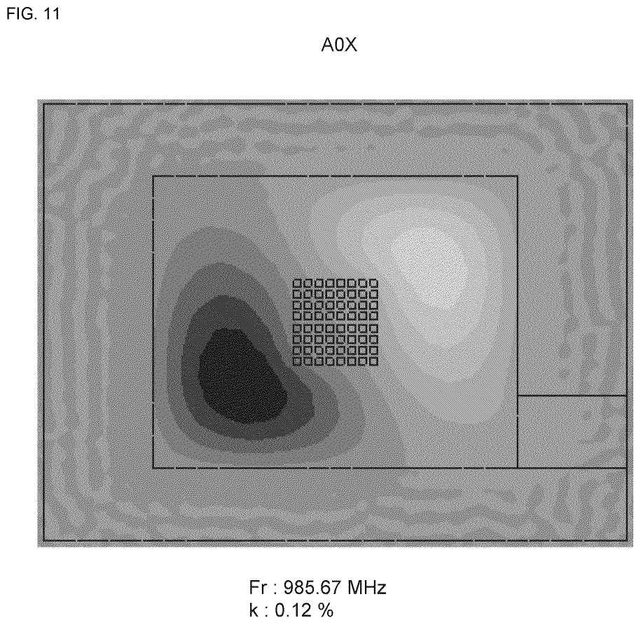

FIG. 8 is a plan view of a quartz crystal resonator according to a comparative example. FIGS. 9 to 11 are diagrams showing vibration distributions of the quartz crystal resonator according to the comparative example. FIG. 9 shows a vibration distribution in the S0 mode as a simulation result based on the comparative example. FIG. 10 shows a vibration distribution in the A0Z mode as a simulation result based on the comparative example. FIG. 11 shows the vibration distribution in the A0X mode. In FIGS. 9 to 11, the first excitation electrode 14a and the first extended electrode 15a are shown, and the second excitation electrode 14b and the second extended electrode 15b are not shown.

The quartz crystal resonator 100 according to the comparative example is the same as the quartz crystal resonator 10 according to the first embodiment except that the cavity h1 is omitted as shown in FIG. 8. The simulation conditions based on the comparative example are the same as the simulation conditions based on the first embodiment except that Ls=0 and Ws=Wc.

As shown in FIG. 9, in the comparative example, k_{S0} is 7.39% and Fr_{S0} is 985.13 MHz. As shown in FIG. 10, in the comparative example, k_{A0Z} is 0.37% and Fr_{S0} is 985.61 MHz. As shown in FIG. 11, in the comparative example, k_{A0X} is 0.12% and Fr_{S0} is 985.67 MHz.

Comparing FIG. 9 with FIG. 5, k_{S0} in a case where the cavity h1 is not provided is 7.39%, and k_{S0} in a case where the cavity h1 is provided is 7.37%. Therefore, the presence or absence of the cavity h1 has a small effect on k_{S0}. Comparing FIG. 10 with FIG. 6, k_{A0Z} is reduced from 0.37% to 0.04% by providing the cavity h1. Comparing FIG. 11 with FIG. 7, k_{A0X} is reduced from 0.12% to 0.00% by providing the cavity h1.

As shown in FIGS. 10 and 11, in the comparative example, the vibration is distributed to leak from the excitation region to the first extended electrode. As a result, the vibration intensity on the first extended electrode side in the excitation region is stronger than the vibration intensity on the side opposite to the first extended electrode, and the balance of the vibration distribution is broken. On the other hand, as shown in FIGS. 6 to 8, in the first embodiment, there is no leakage of vibration to the first extended electrode, and the balance of vibration distribution within the excitation region is improved.

It is considered that the reason why the vibration leaks from the excitation region to the first extended electrode in the comparative example is that the vibration excited between the first extended electrode and the second excitation electrode is coupled to the vibration excited between the first excitation electrode and the second excitation electrode. In particular, the antisymmetric A0 mode does not excite in the ideal state, as the positive and negative charges cancel each other out. However, when the balance of the vibration distribution is disturbed, as in the comparative example, the part that is not canceled is emphasized. In the first embodiment, the cavity h1 suppresses the coupling between the A0 mode of the excitation region and the vibration excited by the first extended electrode. Therefore, the balance of the vibration distribution in the A0 mode in the excitation region is improved, and the vibration distribution in the A0 mode approaches the ideal state. Therefore, the positive and negative charges in the A0 mode cancel each other out, and the increase in k_{A0Z} and k_{A0X} due to the first extended electrode is suppressed.

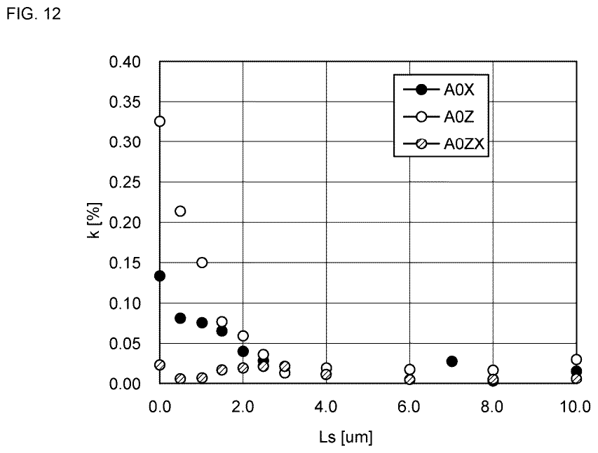

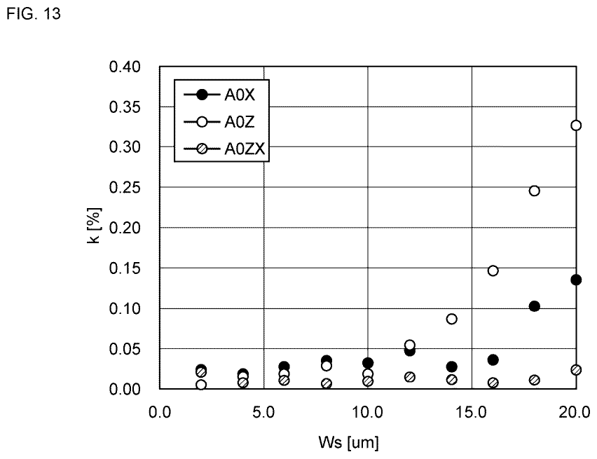

FIGS. 12 and 13 are graphs showing simulation results based on the first embodiment. In the graph shown in FIG. 12, the horizontal axis indicates the length Ls [μm] of the narrow passage portion along the X axis direction, and the vertical axis indicates the electromechanical coupling coefficient k [%]. In the graph shown in FIG. 13, the horizontal axis indicates the length Ws [μm] of the narrow passage portion along the Z′ axis direction, and the vertical axis indicates the electromechanical coupling coefficient k [%]. The simulation conditions in this case are the same as the simulation conditions for the vibration distribution based on the first embodiment, except that Ls and Ws are variables.

In the graph, not only k_{A0X} and k_{A0Z} are plotted, but also k_{A0Zx}. k_{A0Zx} is an electromechanical coupling coefficient k in a mode in which vibrations in opposite phases are arranged in the Z′ axis direction and the Z axis direction in the A0 mode which is a spurious mode. Since k_{A0Zx} is small in the entire range of the horizontal axis of the graphs shown in FIGS. 12 and 13, the description of k_{A0Zx} will be omitted.

As shown in FIG. 12, in a case where the length Ls is 3 μm or more, that is, in a case where Tq×2≤Ls, both k_{A0X} and k_{A0Z} become sufficiently small. From the viewpoint of suppressing an increase in the wiring resistance of the narrow passage portion and suppressing a decrease in the Q factor due to an increase in the resonance resistance, desirably, a relationship of Ls≤Ws/Rs is established. Rs is a sheet resistance of the first extended electrode. From the above, desirably, a relationship of Tq×2≤Ls≤Ws/Rs is established. More desirably, a relationship of Tq×3≤Ls≤Ws/Rs is established.

As shown in FIG. 13, as the length Ws decreases, both k_{A0X} and k_{A0Z} decrease. In a case where the length Ws is 16 μm or less, that is, in a case where Ws/We≤0.20, k_{A0X} becomes sufficiently small. In a case where the length Ws is 12 μm or less, that is, in a case where Ws/We≤0.15, both k_{A0X} and k_{A0Z} become sufficiently small. From the viewpoint of suppressing an increase in wiring resistance of the narrow passage portion, desirably, a relationship of 0.05≤Ws/We is established. From the above, desirably, a relationship of 0.05≤Ws/We≤0.20 is established, and more desirably, a relationship of 0.05≤Ws/We≤0.15 is established. More desirably, a relationship of 0.075≤Ws/We is established, and still more desirably, a relationship of 0.10≤Ws/We is established.

As described above, according to the present embodiment, the quartz crystal resonator 10 includes the quartz crystal element 11, the first electrode including the first excitation electrode 14a and the first extended electrode 15a provided on the first main surface 11A of the quartz crystal element 11, and the second electrode including the second excitation electrode 14b and the second extended electrode 15b provided on the second main surface 11B of the quartz crystal element 11. In plan view, the high acoustic velocity region 17 positioned at a center portion in the excitation region 19 where the first excitation electrode 14a and the second excitation electrode 14b overlap with each other, and the low acoustic velocity region 18 positioned at a peripheral portion in the excitation region 19 are provided, and the plurality of hole portions H for increasing the acoustic velocity are provided in the first excitation electrode 14a of the high acoustic velocity region 17. The outer peripheral portions 71 to 74 of the first excitation electrode 14a are provided inside the outer peripheral portions 81 to 84 of the second excitation electrode 14b, and the coupling portion between the first excitation electrode 14a and the first extended electrode 15a overlaps with the second excitation electrode 14b. The cavity h1 is provided at the coupling portion between the first excitation electrode 14a and the first extended electrode 15a, and the cavity h1 is provided substantially in a range of a distance of four times or less the thickness Tq of the quartz crystal element 11 from the boundary B between the first excitation electrode 14a and the first extended electrode 15a.

Accordingly, the coupling of the vibration excited between the first extended electrode 15a and the second excitation electrode 14b and the vibration excited in the excitation region 19 is suppressed, and the deterioration of the balance of the vibration distribution in the excitation region 19 due to the first extended electrode 15a is suppressed. As a result, k_{S0} is increased, and k_{A0Z} and k_{A0X} are decreased. Therefore, the vibration characteristics are improved.

As one aspect of the present embodiment, the length Wh1 of the cavity h1 in the Z′ axis direction along the boundary B is 50% or more and 90% or less of the length Wc of the first extended electrode 15a in the Z′ axis direction along the boundary B (0.50≤Wh1/Wc≤0.90).

Accordingly, by setting 0.50≤Wh1/Wc, the coupling of the vibration excited between the first extended electrode 15a and the second excitation electrode 14b and the vibration excited in the excitation region 19 can effectively be suppressed. Moreover, by setting Wh1/Wc≤0.90, a decrease in Q factor due to an increase in resonance resistance caused by an increase in wiring resistance can also be suppressed.

As one aspect of the present embodiment, a relationship of 2<Lh1/Tq≤Wh1/Tq is established for the thickness Tq of the quartz crystal element 11, the length Wh1 of the cavity h1 in the Z′ axis direction along the boundary B, and the length Lh1 of the cavity h1 in the X axis direction intersecting the boundary B.

Accordingly, the electric field generated in the region overlapping with the cavity h1 can be sufficiently suppressed. Therefore, the cavity h1 can effectively suppress the coupling of the vibration excited between the first extended electrode 15a and the second excitation electrode 14b and the vibration excited in the excitation region 19.

As one aspect of the present embodiment, the length Lh1 of the cavity h1 in the X axis direction intersecting the boundary B is three times or more the thickness Tq of the quartz crystal element 11 (3≤Lh1/Tq).

Accordingly, the cavity h1 can more effectively suppress the coupling of the vibration excited between the first extended electrode 15a and the second excitation electrode 14b and the vibration excited in the excitation region 19.

As one aspect of the present embodiment, a relationship of 0.05≤Ws/We≤0.15 is established for the difference Ws between the length Wc of the first extended electrode 15a and the length Wh1 of the cavity h1 in the Z′ axis direction along the boundary B and the length We of the first excitation electrode 14a in the Z′ axis direction along the boundary B.

Accordingly, by setting 0.05≤Ws/We, a decrease in the Q factor due to an increase in the resonance resistance caused by an increase in the wiring resistance is suppressed. Moreover, by setting Ws/We≤0.15, suppress the coupling of the vibration excited between the first extended electrode 15a and the second excitation electrode 14b and the vibration excited in the excitation region 19 is also suppressed.

As one aspect of the present embodiment, a relationship of Ls≤Ws/Rs is established for the difference Ws between the length Wc of the first extended electrode 15a and the length Wh1 of the cavity h1 in the Z′ axis direction along the boundary B, the length Lh1 of the cavity h1 in the X axis direction intersecting the boundary B, and the sheet resistance Rs of the first extended electrode 15a.

Accordingly, a decrease in the Q factor due to an increase in the resonance resistance caused by an increase in the wiring resistance is suppressed.

Hereinafter, other embodiments will be described. The same or similar configurations as the configurations described in the first embodiment are defined as the same or similar reference numerals, and descriptions thereof are appropriately omitted. In addition, the same operational effects according to the same configuration will not be sequentially described.

### Second Exemplary Embodiment

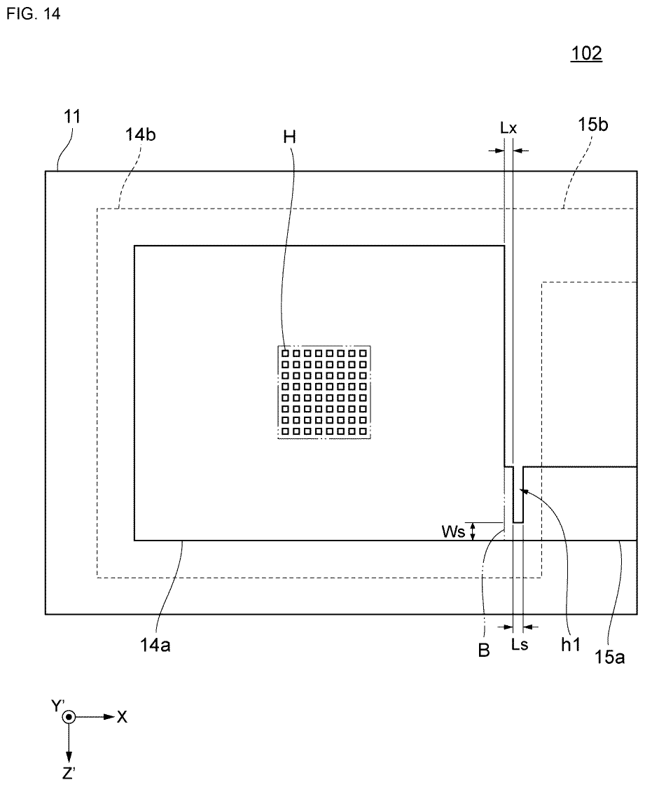

Next, a configuration of a quartz crystal resonator 102 according to a second embodiment will be described with reference to FIG. 14. FIG. 14 is a plan view of the quartz crystal resonator according to the second embodiment.

The cavity h1 is separated from the boundary B. A dimension from the boundary B to an end portion of the cavity h1 on the negative X axis direction side in the X axis direction is defined as a length Lx. The length Lx is a distance from the boundary B to the cavity h1 in a direction intersecting the boundary B, and is, for example, a distance in a direction orthogonal to the boundary B. The length Lx is a distance along the X axis direction between the boundary B at a predetermined position and an end portion of the cavity h1 on the negative X axis direction side, and is specified, for example, as a distance between the boundary B and the end portion of the cavity h1 on the negative X axis direction side in the X axis direction. The predetermined position is, for example, on a straight line that passes through the center of the cavity h1 in plan view and extends in the X axis direction. The length Lx may be specified as an average value or a minimum value of distance between the boundary B and an end portion of the cavity h1 on the negative X axis direction side in the X axis direction.

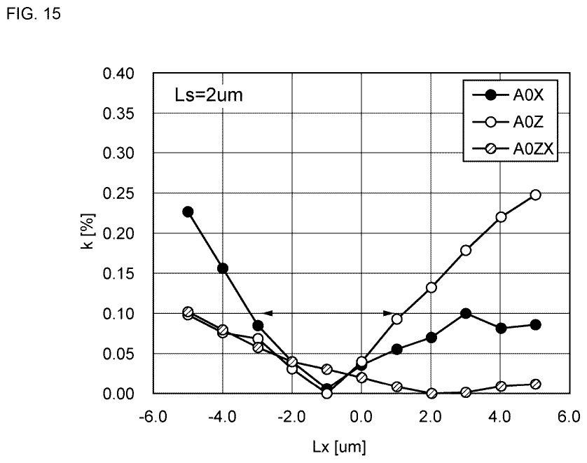

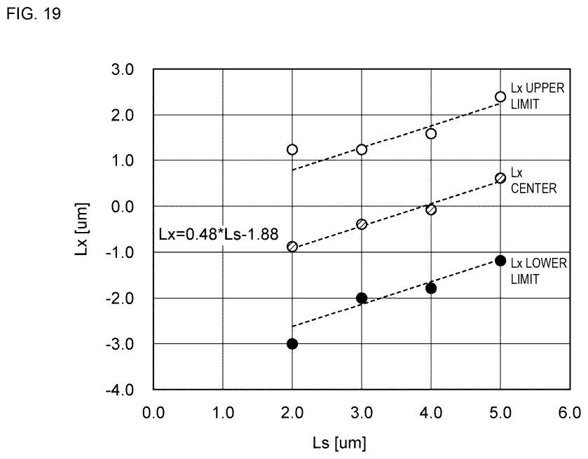

Simulation results based on the second embodiment will be described with reference to FIGS. 15 to 19. In the graphs shown in FIGS. 15 to 18, the horizontal axis indicates the length Lx [μm] from the boundary B to the cavity h1, and the vertical axis indicates the electromechanical coupling coefficient k [%]. In the graph shown in FIG. 19, the horizontal axis indicates the length Ls [μm] of the narrow passage portion along the X axis direction, and the vertical axis indicates the length Lx [μm] from the boundary B to the cavity h1. The simulation conditions based on the second embodiment are the same as the simulation conditions of the vibration distribution based on the first embodiment, except that Ls and Lx are variables.

FIG. 15 is a graph showing a relationship between the length Lx and the electromechanical coupling coefficient k in a case where Ls=2 μm. In a case where a relationship of −5.0 μm≤Lx≤1.0 μm is established, k_{A0Z} becomes sufficiently small. In a case where a relationship of −3.0 μm≤Lx≤5.0 μm is established, k_{A0X} becomes sufficiently small. Therefore, in a case where the relationship of −3.0 μm≤Lx≤1.0 μm is established, both k_{A0X} and k_{A0Z} become sufficiently small. Both k_{A0X} and k_{A0Z} are minimized in a case where Lx=−1.0 μm.

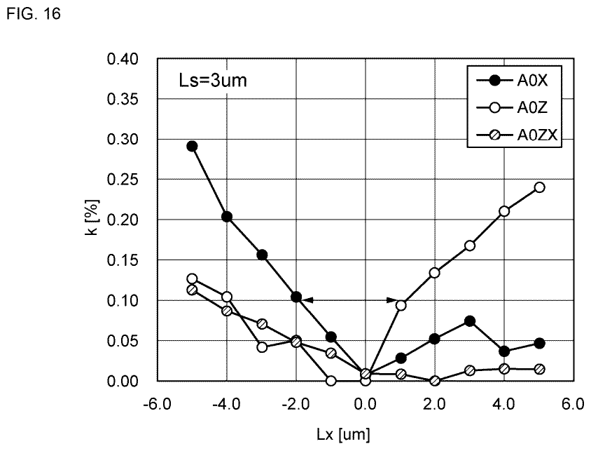

FIG. 16 is a graph showing a relationship between the length Lx and the electromechanical coupling coefficient k in a case where Ls=3 μm. In a case where a relationship of −4.0 μm≤Lx≤1.0 μm is established, k_{A0Z} becomes sufficiently small. In a case where a relationship of −2.0 μm≤Lx≤5.0 μm is established, k_{A0X} becomes sufficiently small. Therefore, in a case where a relationship of −2.0 μm≤Lx≤1.0 μm is established, both k_{A0X} and k_{A0Z} become sufficiently small. Both k_{A0X} and k_{A0Z} are minimized in a case where Lx=0 μm.

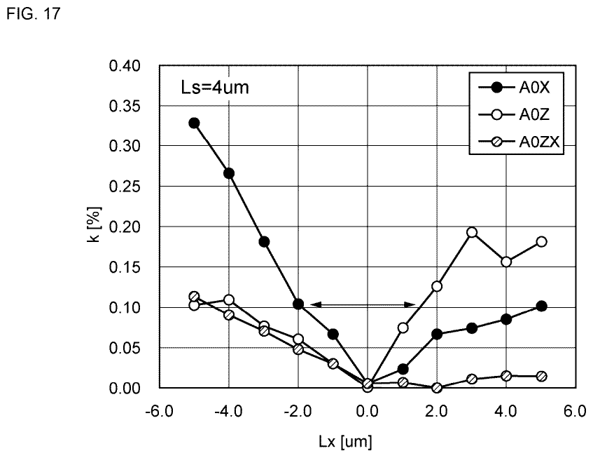

FIG. 17 is a graph showing a relationship between the length Lx and the electromechanical coupling coefficient k in a case where Ls=4 μm. In a case where a relationship of −3.5 μm≤Lx≤1.5 μm is established, k_{A0Z} becomes sufficiently small. In a case where a relationship of −2.0 μm≤Lx≤5.0 μm is established, k_{A0X} becomes sufficiently small. Therefore, in a case where a relationship of −2.0 μm≤Lx≤1.5 μm is established, both k_{A0X} and k_{A0Z} become sufficiently small. Both k_{A0X} and k_{A0Z} are minimized in a case where Lx=0 μm.

FIG. 17 is a graph showing a relationship between the length Lx and the electromechanical coupling coefficient k in a case where Ls=5 μm. In a case where a relationship of −4.0 μm≤Lx≤2.5 μm is established, k_{A0Z} becomes sufficiently small. In a case where a relationship of −1.0 μm≤Lx≤5.0 μm is established, k_{A0X} becomes sufficiently small. Therefore, in a case where a relationship of −1.0 μm≤Lx≤2.5 μm is established, both k_{A0X} and k_{A0Z} become sufficiently small. Both k_{A0X} and k_{A0Z} are minimized in a case where Lx=0 μm.

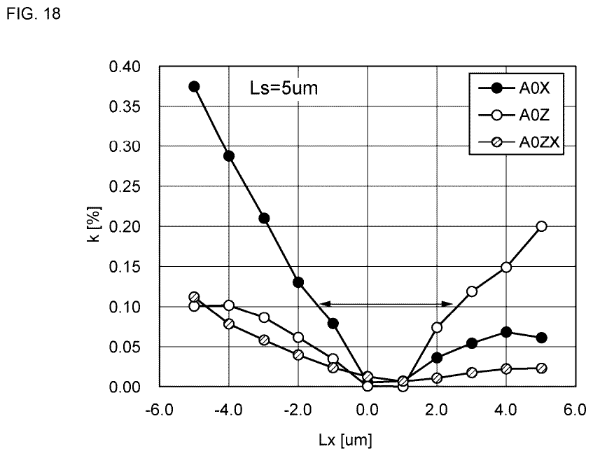

FIG. 18 is a graph in which an upper limit value, a lower limit value, and a center value of Lx are plotted in a case where both k_{A0X} and k_{A0Z} are sufficiently small. By fitting these plots, a conditional expression in which both k_{A0X} and k_{A0Z} are sufficiently small is obtained as the following expression.

$$Lx = 0.48 \times Ls - 1.88 \pm 1.7$$

### Third Exemplary Embodiment

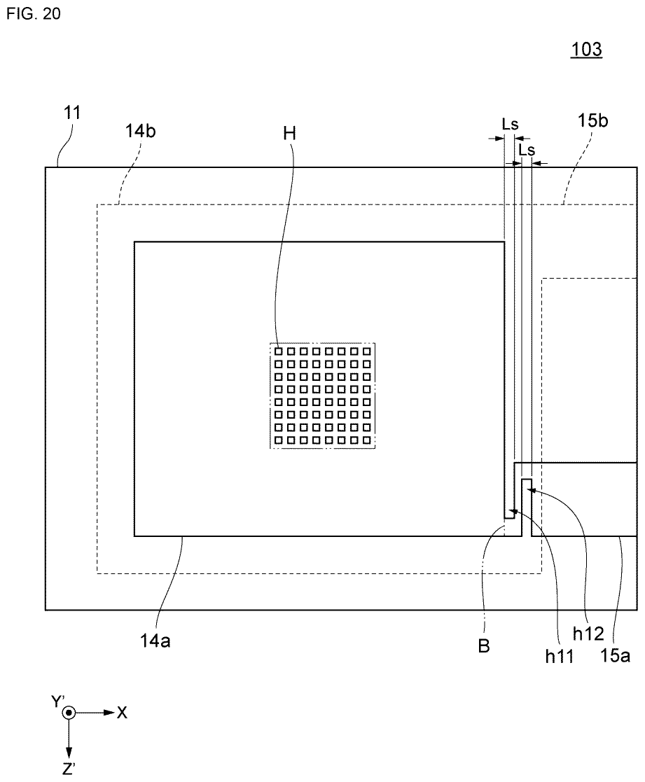

Next, a configuration of a quartz crystal resonator 103 according to a third embodiment will be described with reference to FIG. 20. FIG. 20 is a plan view of the quartz crystal resonator according to the third embodiment.

The quartz crystal resonator 103 is provided with two cavities h11 and h12. The planar shape of the cavities h11 and h12 is a rectangular slit shape. The cavity h11 is provided along the boundary B. The cavity h12 is provided on the positive X axis direction side of the cavity h11. The longitudinal direction of the cavity h11 and the longitudinal direction of the cavity h12 extend in parallel with each other. The length Ls of the cavity h11 along the X axis direction is the same as the length Ls of the cavity h12 along the X axis direction. The cavity h11 has a notch shape that is open on the negative Z′ axis direction side of the first extended electrode 15a. The cavity h12 has a notch shape that is open on the positive Z′ axis direction side of the first extended electrode 15a. A part of each of the cavities h11 and h12 is arranged in the X axis direction.

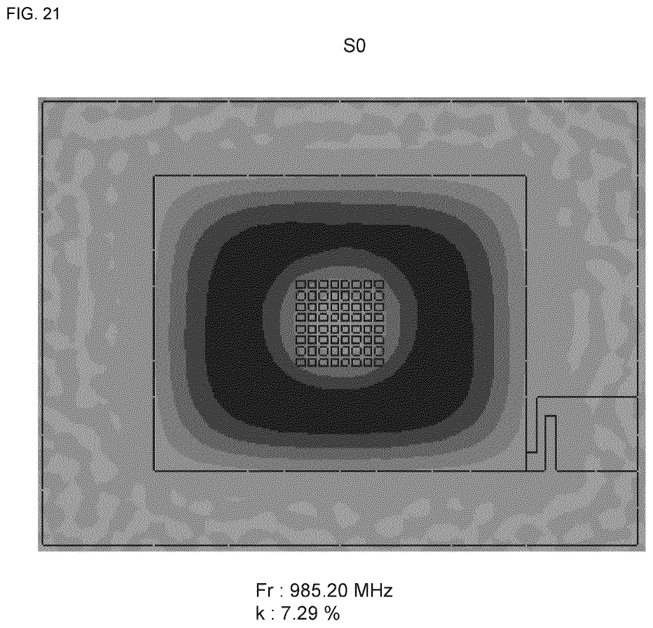

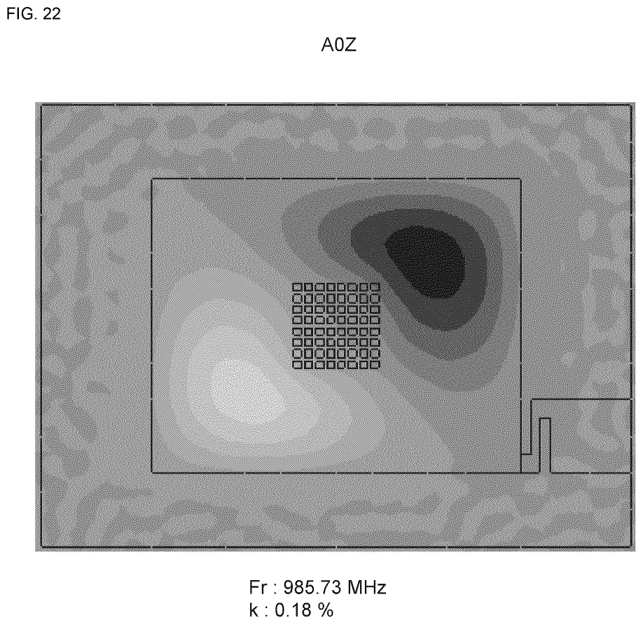

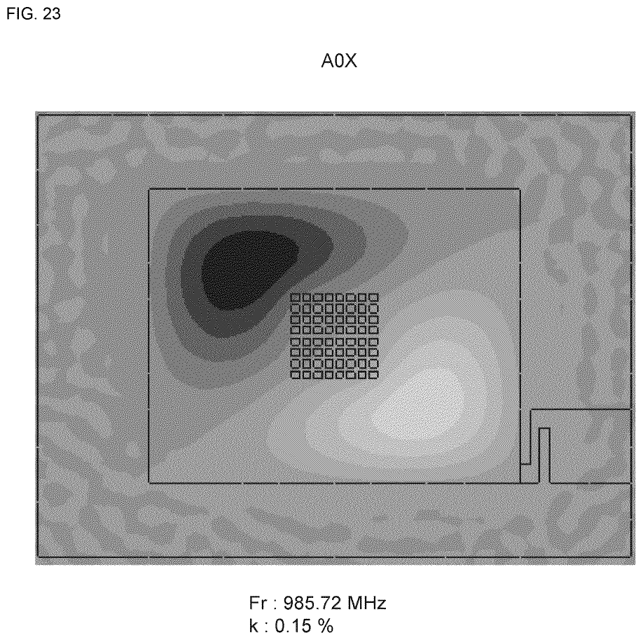

FIGS. 21 to 23 are diagrams showing the vibration distributions of the quartz crystal resonator according to the third embodiment. FIG. 21 shows a vibration distribution in the S0 mode, which is a main mode, as a simulation result based on the third embodiment. FIG. 22 shows a vibration distribution in the A0Z mode as a simulation result based on the third embodiment. FIG. 23 shows a vibration distribution in the A0X mode as a simulation result based on the third embodiment. In FIGS. 21 to 23, the first excitation electrode 14a and the first extended electrode 15a are shown, and the second excitation electrode 14b and the second extended electrode 15b are not shown.

As shown in FIG. 21, k_{S0} is 7.29% and Fr_{S0} is 985.20 MHz in an example of the third embodiment. As shown in FIG. 22, k_{A0Z} is 0.18% and Fr_{A0Z} is 985.73 MHz in an example of the third embodiment. As shown in FIG. 23, k_{A0X} is 0.15% and Fr_{A0X} is 985.72 MHz in an example of the third embodiment.

In comparison with the quartz crystal resonator 100 according to a comparative example not having the cavity, k_{S0} increases, k_{A0Z} decreases, and k_{A0X} hardly changes in the example of the third embodiment. Therefore, in the quartz crystal resonator 103 according to the third embodiment, the electromechanical coupling coefficient k is improved, although not as much as the quartz crystal resonator 10 according to the first embodiment.

### Fourth Exemplary Embodiment

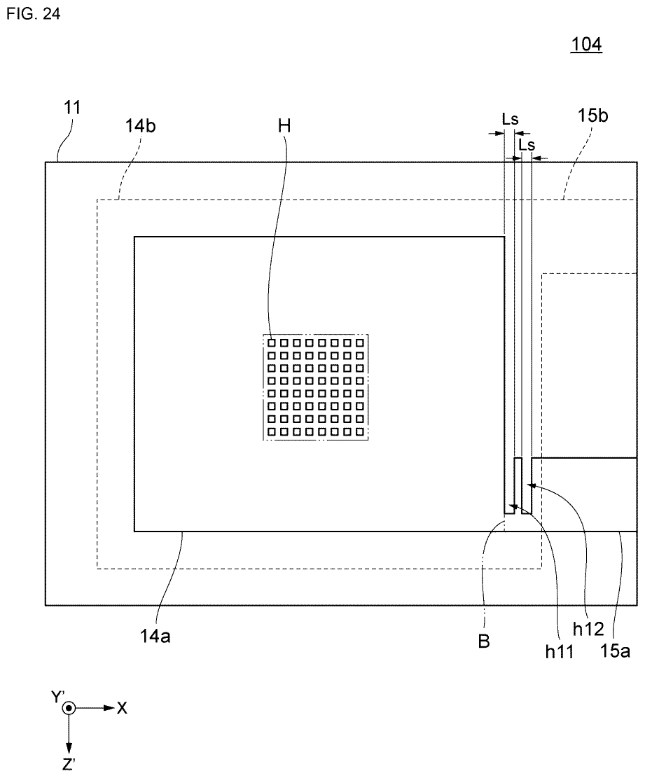

Next, a configuration of a quartz crystal resonator 104 according to a fourth embodiment will be described with reference to FIG. 24. FIG. 24 is a plan view of the quartz crystal resonator according to the fourth embodiment.

The quartz crystal resonator 104 is provided with two cavities h11 and h12. The planar shapes of the cavities h11 and h12 are the same rectangular slit shape and the dimensions are also the same. The cavity h11 is provided along the boundary B. The cavity h12 is provided on the positive X axis direction side of the cavity h11. The longitudinal direction of the cavity h11 and the longitudinal direction of the cavity h12 extend in parallel with each other. Both of the cavities h11 and h12 have a notch shape that is open on the negative Z′ axis direction side of the first extended electrode 15a.

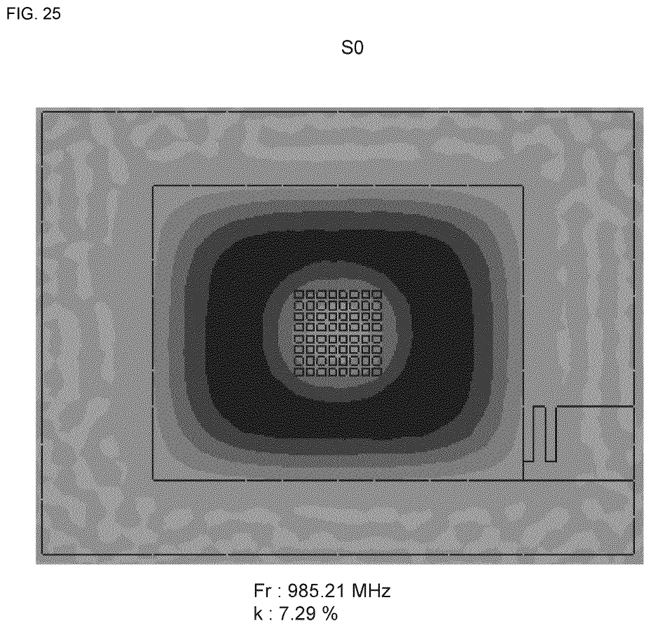

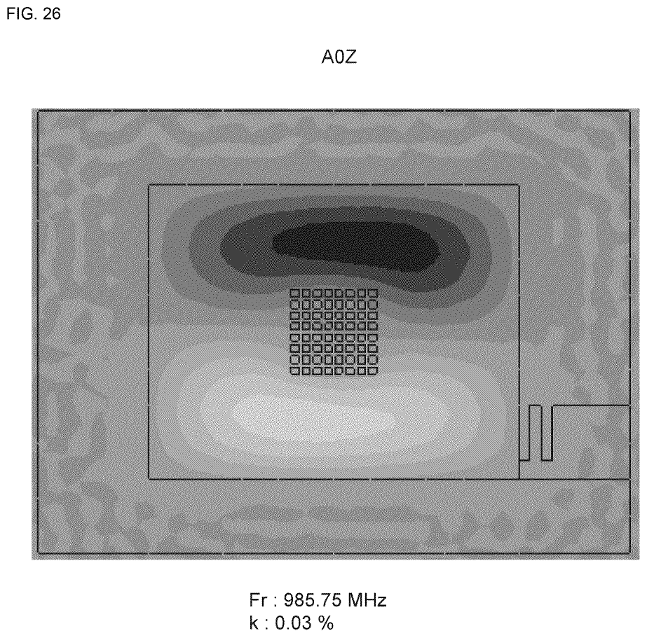

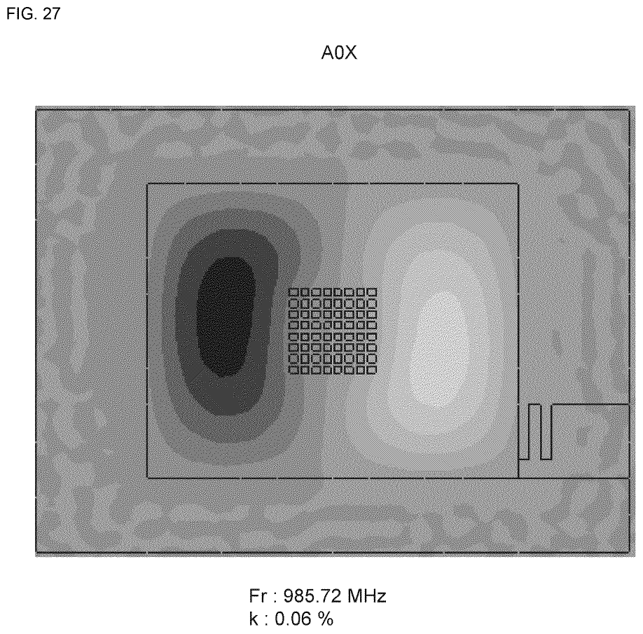

FIGS. 25 to 27 are diagrams showing the vibration distributions of the quartz crystal resonator according to the fourth embodiment. FIG. 25 shows a vibration distribution in the S0 mode, which is a main mode, as a simulation result based on the fourth embodiment. FIG. 26 shows a vibration distribution in the A0Z mode as a simulation result based on the fourth embodiment. FIG. 27 shows a vibration distribution in the A0X mode as a simulation result based on the fourth embodiment. In FIGS. 25 to 27, the first excitation electrode 14a and the first extended electrode 15a are shown, and the second excitation electrode 14b and the second extended electrode 15b are not shown.

As shown in FIG. 25, k_{S0} is 7.29% and Fr_{S0} is 985.21 MHz in an example of the fourth embodiment. As shown in FIG. 26, k_{A0Z} is 0.03% and Fr_{A0Z} is 985.75 MHz in an example of the fourth embodiment. As shown in FIG. 27, k_{A0X} is 0.06% and Fr_{A0X} is 985.72 MHz in an example of the fourth embodiment.

In comparison with the quartz crystal resonator 100 according to the comparative example not having the cavity, k_{S0} increases and k_{A0Z} and k_{A0X} decrease in the example of the fourth embodiment. Therefore, in the quartz crystal resonator 104 according to the fourth embodiment, the electromechanical coupling coefficient k is improved as compared with the quartz crystal resonator 103 according to the third embodiment. In an exemplary aspect where two cavities are provided, the electromechanical coupling coefficient k is effectively improved by providing the two cavities on the same side of the positive Z′ axis direction side or the negative Z′ axis direction side, rather than alternately providing the two cavities from both sides of the positive Z′ axis direction side and the negative Z′ axis direction side.

### Fifth Exemplary Embodiment

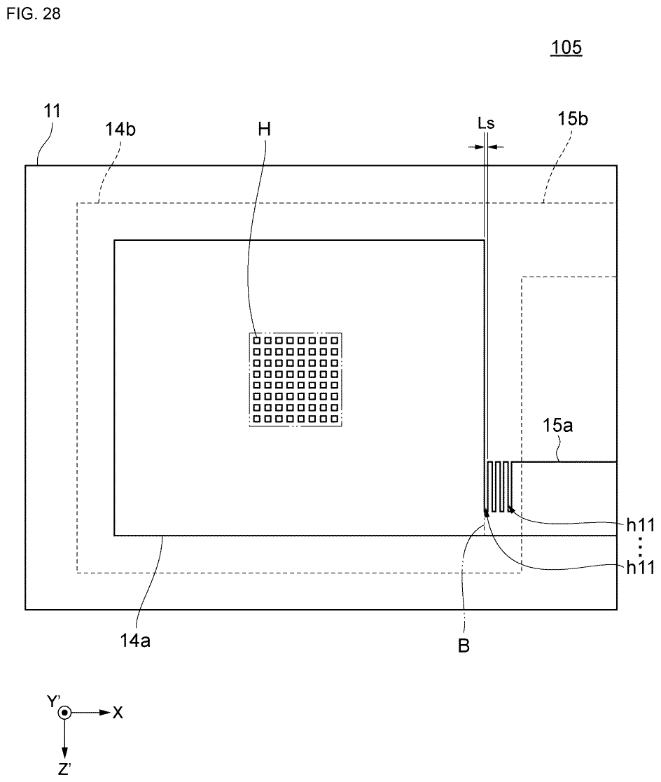

Next, a configuration of a quartz crystal resonator 105 according to a fifth embodiment will be described with reference to FIG. 28. FIG. 28 is a plan view of the quartz crystal resonator according to the fifth embodiment.

The quartz crystal resonator 105 is provided with the plurality of cavities h11. The planar shape of each of the plurality of cavities h11 is the same rectangular slit shape, and the dimensions are also the same. All of the plurality of cavities h11 have a notch shape that is open on the negative Z′ axis direction side of the first extended electrode 15a. The plurality of cavities h11 have a longitudinal shape in the Z′ axis direction along the boundary B and are arranged in the X axis direction intersecting the boundary B.

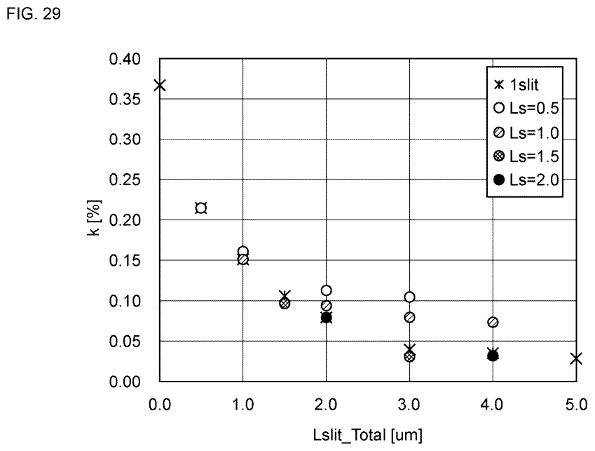

A simulation result based on the fifth embodiment will be described with reference to FIG. 29. FIG. 29 is a graph showing a simulation result based on the fifth embodiment. In the graph shown in FIG. 29, the horizontal axis indicates a total value Ls_total of lengths Ls of the plurality of cavities h11, and the vertical axis indicates an electromechanical coupling coefficient k (k_{A0Z}) [%] in the A0Z mode. The simulation conditions based on the fifth embodiment are the same as the simulation conditions based on the first embodiment except that Ws=8 μm and the number of Ls and the number of the cavities h11 are variables.

In an exemplary aspect where Ls=0.5 μm to 2.0 μm, in a range where the total value of the lengths Ls is 0 μm to 5.0 μm, the greater the total value of the lengths Ls, the smaller the electromechanical coupling coefficient k. From the viewpoint of reducing k_{A0Z}, desirably, 1.5 μm≤Ls_total, more desirably, 3.0 μm≤Ls_total, and desirably, 4.5 μm≤Ls_total. That is, desirably, the total value Ls_total of the lengths Ls is equal to or greater than the thickness Tq of the quartz crystal element 11, more desirably, equal to or greater than twice the thickness Tq, and even more desirably, equal to or greater than three times the thickness Tq. In an exemplary aspect where the total value Ls_total of the lengths Ls is equal to or greater than twice the thickness Tq of the quartz crystal element 11, k_{A0Z} becomes sufficiently small. In a case where Ls=1.5 μm and 2.0 μm, k_{A0Z} shows the same tendency in a case where there are a plurality of cavities h11 and a case where there is one cavity h11. However, in a case where Ls=0.5 μm and 1.0 μm, k_{A0Z} in a case where there are a plurality of cavities h11 is greater than k_{A0Z} in a case where there is one cavity h11. That is, in a case where there are a plurality of cavities h11, the suppression effect of the A0 mode is reduced in a case where Ls<1.5 μm. Therefore, in a case where there are a plurality of cavities h11, desirably, the relationship of 1.5 μm≤Ls is established.

### Sixth Exemplary Embodiment

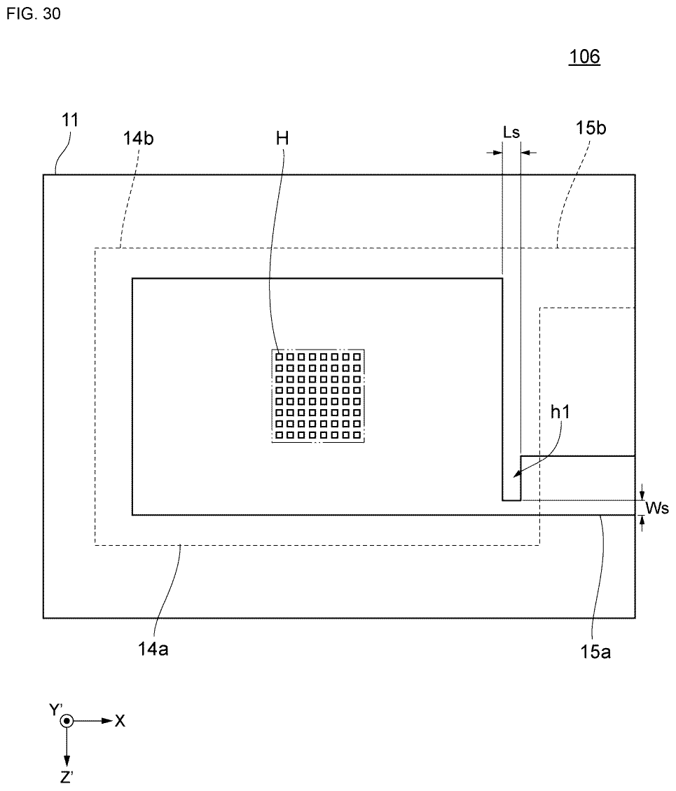

Next, a configuration of a quartz crystal resonator 106 according to a sixth embodiment will be described with reference to FIG. 30. FIG. 30 is a plan view of the quartz crystal resonator according to the sixth embodiment.

The lengths of the first excitation electrode 14a and the second excitation electrode 14b of the quartz crystal resonator 106 according to the sixth embodiment along the Z′ axis direction are smaller than the lengths of the first excitation electrode 14a and the second excitation electrode 14b of the quartz crystal resonator 101 according to the first embodiment along the Z′ axis direction. That is, the aspect ratio of the first excitation electrode 14a and the second excitation electrode 14b of the quartz crystal resonator 106 according to the sixth embodiment is greater than the aspect ratio of the first excitation electrode 14a and the second excitation electrode 14b of the quartz crystal resonator 101 according to the first embodiment.

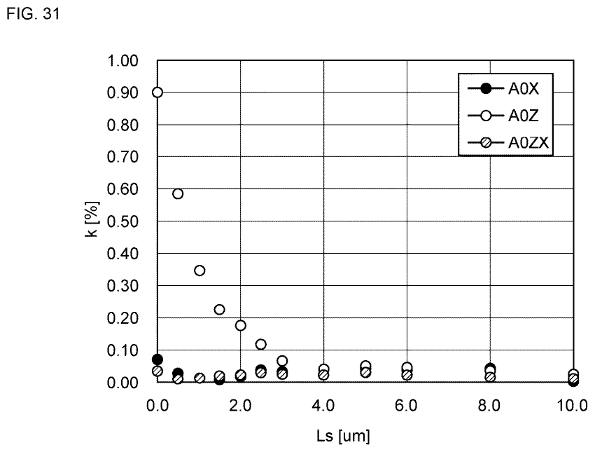

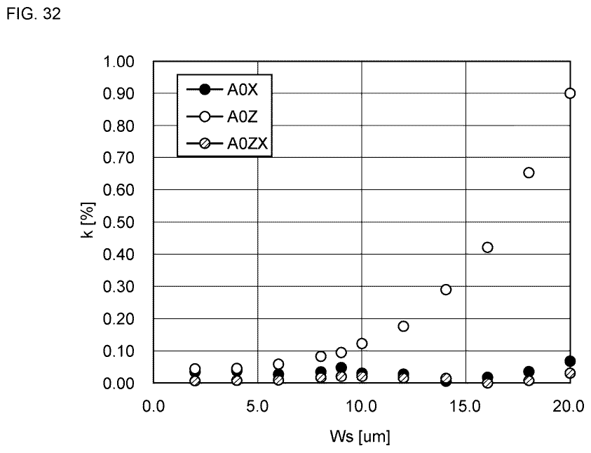

Simulation results based on the sixth embodiment will be described with reference to FIGS. 31 and 32. FIGS. 31 and 32 are graphs showing simulation results based on the sixth embodiment. In the graph shown in FIG. 31, the horizontal axis indicates the length Ls [μm] of the narrow passage portion along the X axis direction, and the vertical axis indicates the electromechanical coupling coefficient k [%]. In the graph shown in FIG. 32, the horizontal axis indicates the length Ws [μm] of the narrow passage portion along the Z′ axis direction, and the vertical axis indicates the electromechanical coupling coefficient k [%].

The simulation conditions of the graph shown in FIG. 31 are the same as the simulation conditions of the vibration distribution based on the first embodiment, except that We=60 μm, Ws=6 μm, and Ls is a variable. The simulation conditions of the graph shown in FIG. 32 are the same as the simulation conditions of the vibration distribution based on the first embodiment, except that We=60 μm and Ws is a variable.

As shown in FIG. 31, in a case where the length Ls is 3 μm or more, that is, in a case where Tq×2≤Ls, both k_{A0X} and k_{A0Z} become sufficiently small. As shown in FIG. 32, in a case where the length Ws is 9 μm or less, that is, in a case where Ws/We≤0.15, both k_{A0X} and k_{A0Z} become sufficiently small. That is, even in a case where the length We of the first excitation electrode 14a is different and the aspect ratio of the first excitation electrode 14a is different as in the first embodiment and the sixth embodiment, the conditions of the lengths Ls and Ws in which the electromechanical coupling coefficient k is favorable are the same.

### Seventh Exemplary Embodiment

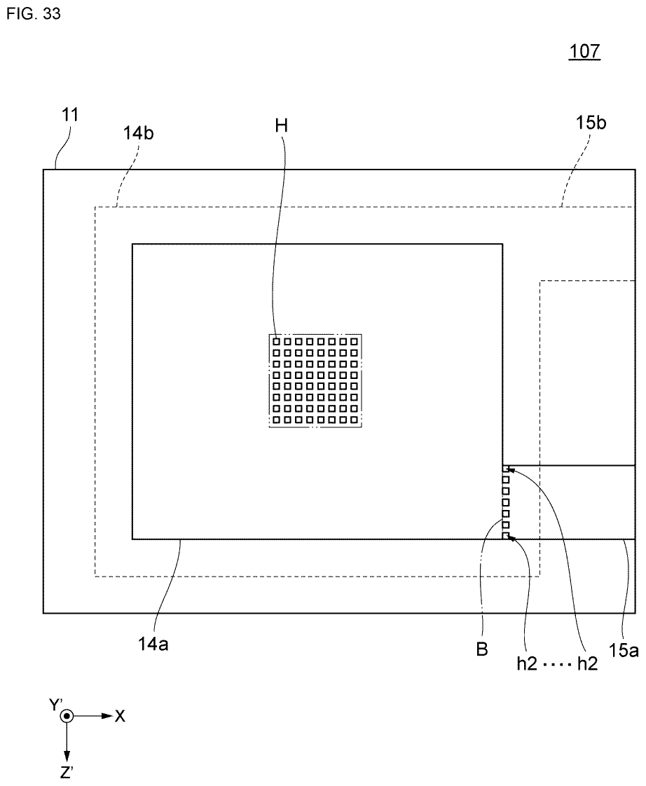

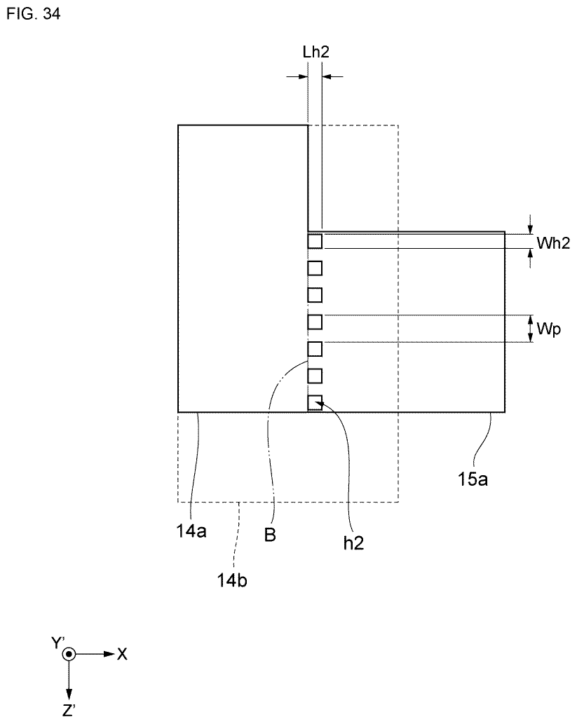

Next, a configuration of the quartz crystal resonator 107 according to a seventh embodiment will be described with reference to FIG. 33 and FIG. 34. FIG. 33 is a plan view of the quartz crystal resonator according to the seventh embodiment. FIG. 34 is an enlarged plan view of a coupling portion in the seventh embodiment.

Cavities h2 arranged in a row in the direction along the boundary B are provided on the first extended electrode 15a side of the boundary B between the first excitation electrode 14a and the first extended electrode 15a. The plurality of cavities h2 are disposed at equal intervals from the end portion of the first extended electrode 15a on the positive Z′ axis direction side to the end portion on the negative Z′ axis direction side. The planar shape of the cavity h2 is a rectangular shape having a pair of sides extending along the Z′ axis direction and a pair of sides extending along the X axis direction. One side of the cavity h2 overlaps the boundary B.

A dimension of the cavity h2 along the X axis direction is defined as a length Lh2. The length Lh2 is a length of the cavities h2 along the direction in which the cavities h2 are arranged, and is specified as, for example, a length of the cavities h2 in a direction parallel to the direction in which the cavities h2 are arranged. A dimension of the cavity h2 along the Z′ axis direction is referred to as a length Wh2. The length Wh2 is a length of the cavities h2 along the direction intersecting the direction in which the cavities h2 are arranged, and is specified as, for example, a length of the cavities h2 in the direction orthogonal to the direction in which the cavities h2 are arranged. An array period of the cavities h2 in the Z′ axis direction, that is, a distance between end portions of two cavities h2 adjacent to each other in the Z′ axis direction on the negative Z′ axis direction side is defined as Wp. The array period Wp is an array period of the cavities h2 along the direction in which the cavities h2 are arranged, and is specified as, for example, an array period of the cavities h2 in the direction in which the cavities h2 are arranged.

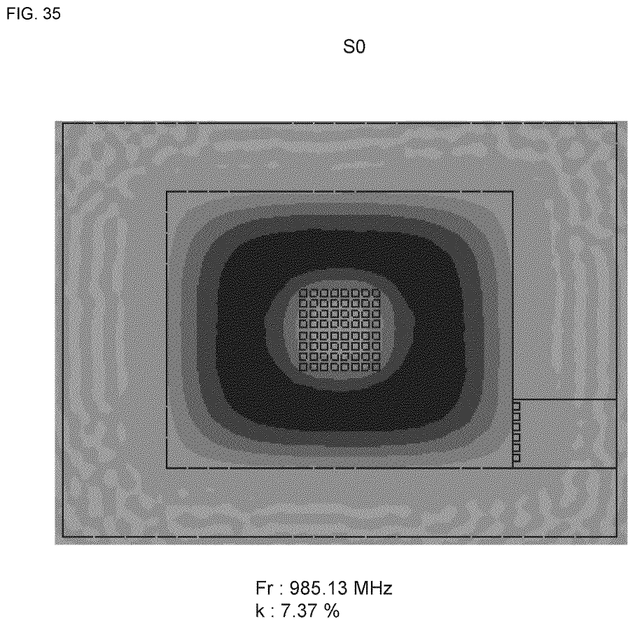

Next, simulation results based on the seventh embodiment will be described with reference to FIGS. 35 to 39.

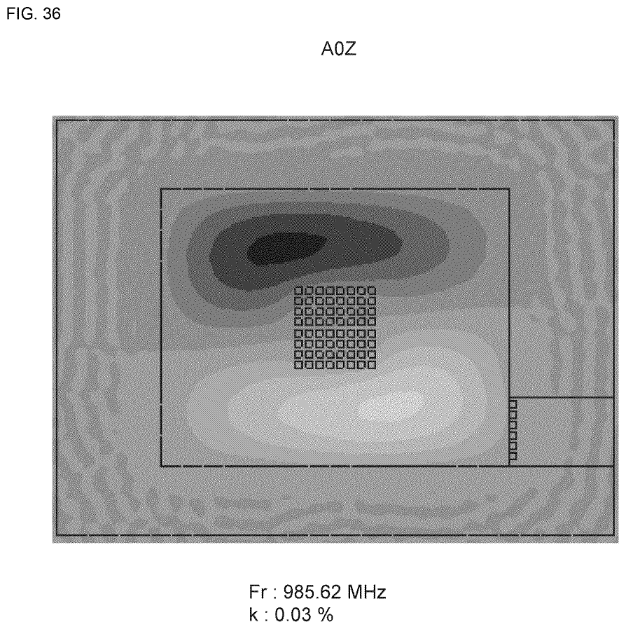

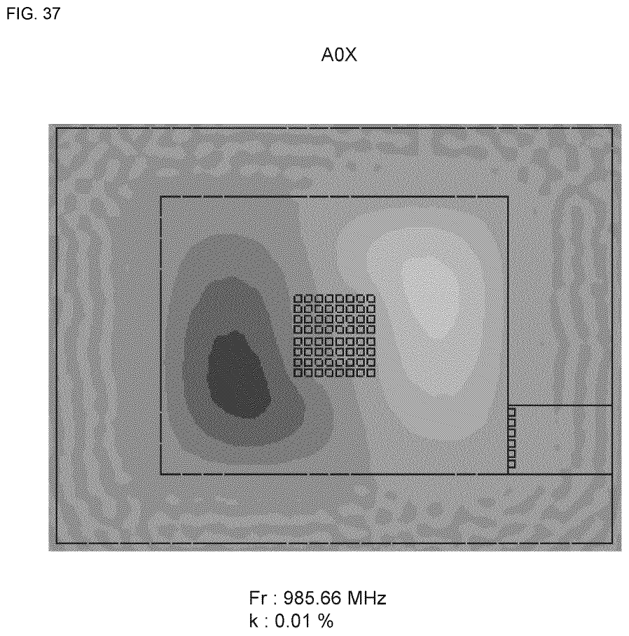

FIGS. 35 to 37 are diagrams showing the vibration distributions of the quartz crystal resonator according to the seventh embodiment. FIG. 35 shows a vibration distribution in the S0 mode as a simulation result based on the seventh embodiment. FIG. 36 shows a vibration distribution in the A0Z mode as a simulation result based on the seventh embodiment. FIG. 37 shows a vibration distribution in the A0X mode as a simulation result based on the seventh embodiment. In FIGS. 35 to 37, the first excitation electrode 14a and the first extended electrode 15a are shown, and the second excitation electrode 14b and the second extended electrode 15b are not shown.

As shown in FIG. 35, k_{S0} is 7.37% and Fr_{S0} is 985.13 MHz in an example of the seventh embodiment. As shown in FIG. 36, k_{A0Z} is 0.03% and Fr_{A0Z} is 985.62 MHz in an example of the seventh embodiment. As shown in FIG. 37, k_{A0X} is 0.01% and Fr_{A0X} is 985.66 MHz in an example of the seventh embodiment.

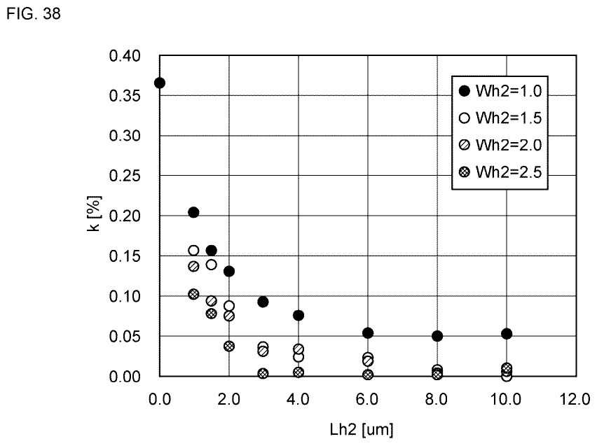

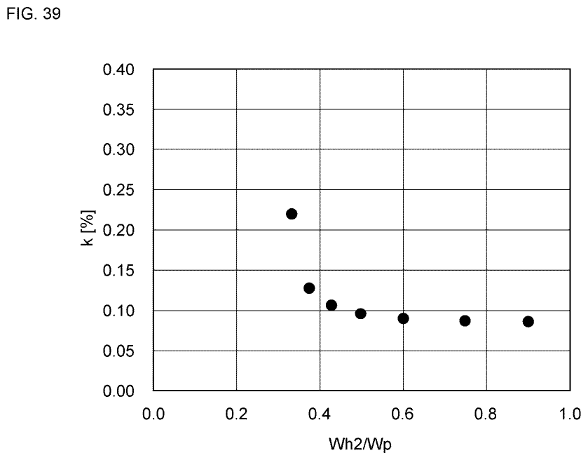

FIGS. 38 and 39 are graphs showing simulation results based on the seventh embodiment. In the graph shown in FIG. 38, the horizontal axis indicates a length Lh2 [μm] of the cavity h2 along the X axis direction, and the vertical axis indicates k_{A0Z} [%]. In the graph shown in FIG. 39, the horizontal axis indicates a ratio (hereinafter referred to as an opening ratio) Wh2/Wp of a length Lh2 of the cavity h2 along the Z′ axis direction with respect to the array period Wp of the cavity h2, and the vertical axis indicates k_{A0Z} [%].

The simulation conditions of the graph shown in FIG. 38 are the same as the simulation conditions of the vibration distribution based on the first embodiment, except that the cavity h2 is provided instead of the cavity h1, Wp=3 μm, and Lh2 and Wh2 are variables. The simulation conditions of the graph shown in FIG. 39 are the same as the simulation conditions of the vibration distribution based on the first embodiment, except that the cavity h2 is provided instead of the cavity h1, the number of cavities h2 and Wp are variables, and Lh2=Wh2=1.5 μm.

As shown in FIG. 38, k_{A0Z} decreases as the length Lh2 decreases. In a case where the length Lh2 is 3 μm or more, that is, in a case where Tq×2≤Lh2, k_{A0Z} becomes sufficiently small. As shown in FIG. 39, k_{A0Z} decreases as the opening ratio Wh2/Wp increases. In a case where the opening ratio Wh2/Wp is 50% or more and 90% or less (0.50≤Wh2/Wp≤0.90), k_{A0Z} becomes sufficiently small. Specifically, in a case where 0.50≤Wh2/Wp≤0.90, k_{A0Z}<0.10 is established. In order to further reduce k_{A0Z}, more desirably, 0.60≤Wh2/Wp is established. From the viewpoint of suppressing an increase in wiring resistance, desirably, Wh2/Wp≤0.90, and more desirably, Wh2/Wp≤0.80.

### Eighth Exemplary Embodiment

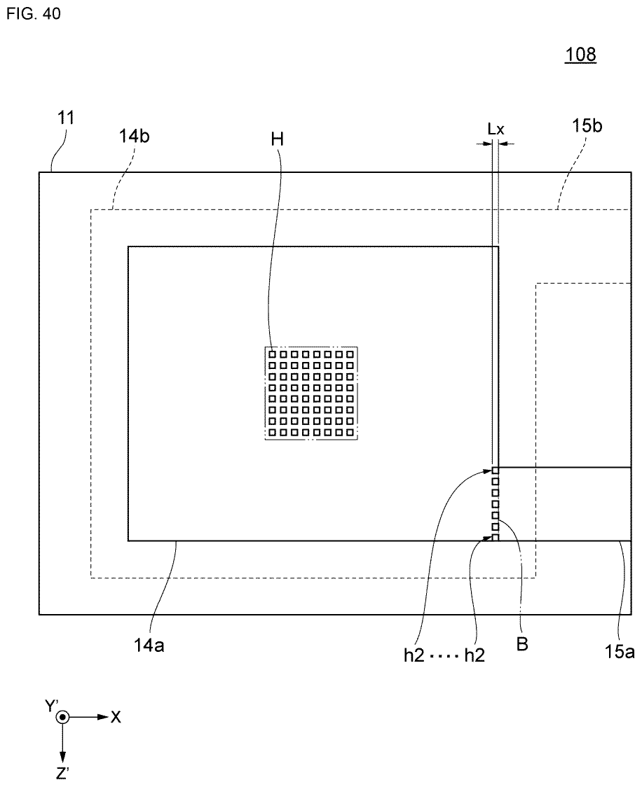

Next, a configuration of a quartz crystal resonator 108 according to an eighth embodiment will be described with reference to FIG. 40. FIG. 40 is a plan view of the quartz crystal resonator according to the eighth embodiment.

In the quartz crystal resonator 108, the cavities h2 arranged in a row are provided on the first excitation electrode 14a side of the boundary B. In the X axis direction, a dimension from the boundary B to the end portion of the cavity h2 on the negative X axis direction side is defined as a distance Lx.

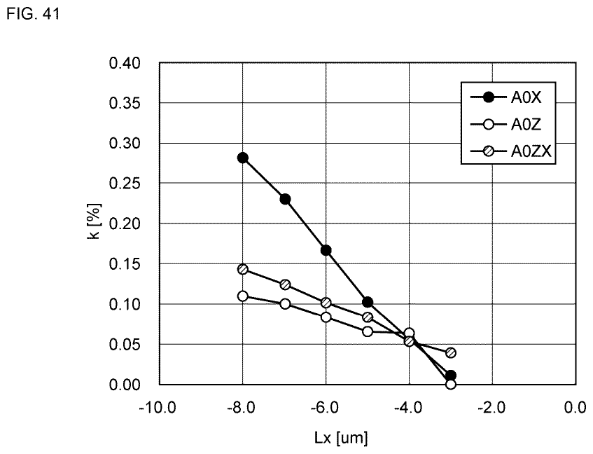

Next, a simulation result based on the eighth embodiment will be described with reference to FIGS. 41 to 44.

FIG. 41 is a graph showing a simulation result based on the eighth embodiment. In the graph shown in FIG. 41, the horizontal axis indicates a distance Lx [μm] from the boundary B to the end portion of the cavity h2 on the negative X axis direction side, and the vertical axis indicates an electromechanical coupling coefficient k [%]. The simulation conditions of the graph shown in FIG. 41 are the same as the simulation conditions of the vibration distribution based on the first embodiment, except that the cavity h2 is provided instead of the cavity h1, Lh2=Wh2=2 μm, and Lx is a variable.

As Lx decreases, the electromechanical coupling coefficient in the A0 mode increases. That is, as the cavity h2 approaches the high acoustic velocity region 17, the suppression effect of the A0 mode by the cavity h2 decreases. In a case where the cavity h2 is provided on the first excitation electrode 14a side, desirably, −5 μm≤Lx≤0 μm is established in order to sufficiently suppress the A0 mode.

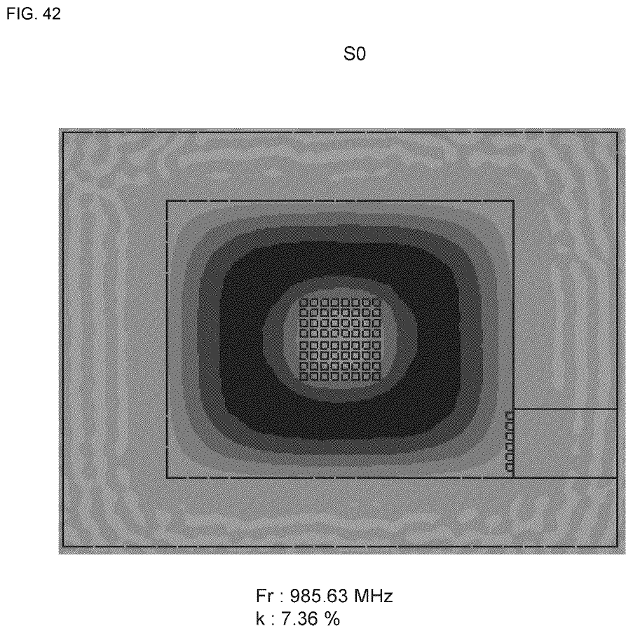

Next, a simulation result based on the eighth embodiment will be described with reference to FIGS. 42 to 44.

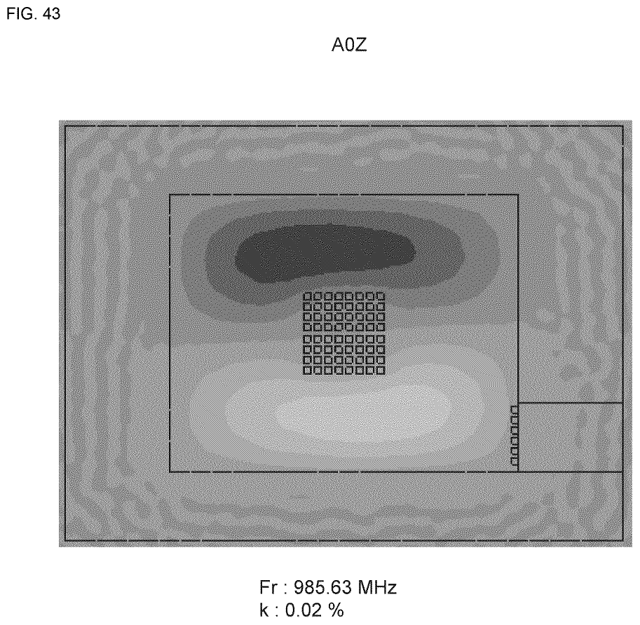

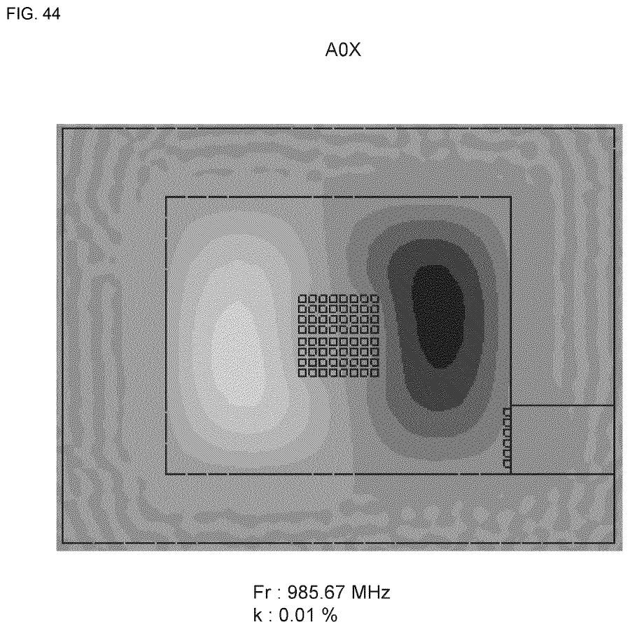

FIGS. 42 to 44 are diagrams showing the vibration distributions of the quartz crystal resonator according to the eighth embodiment. FIG. 42 shows a vibration distribution in the S0 mode as a simulation result based on the eighth embodiment. FIG. 43 shows a vibration distribution in the A0Z mode as a simulation result based on the eighth embodiment. FIG. 44 shows a vibration distribution in the A0X mode as a simulation result based on the eighth embodiment. In FIGS. 42 to 44, the first excitation electrode 14a and the first extended electrode 15a are shown, and the second excitation electrode 14b and the second extended electrode 15b are not shown.

As shown in FIG. 42, k_{S0} is 7.36% and Fr_{S0} is 985.63 MHz in an example of the eighth embodiment. As shown in FIG. 43, k_{A0Z} is 0.02% and Fr_{A0Z} is 985.63 MHz in an example of the eighth embodiment. As shown in FIG. 44, k_{A0X} is 0.01% and Fr_{A0X} is 985.67 MHz in an example of the eighth embodiment.

k_{S0} in the example of the eighth embodiment is not substantially changed from k_{S0} of the comparative example. k_{A0Z} and Fr_{A0X} in the example of the eighth embodiment are smaller than k_{A0Z} and Fr_{A0X} in the comparative example.

### Ninth Exemplary Embodiment

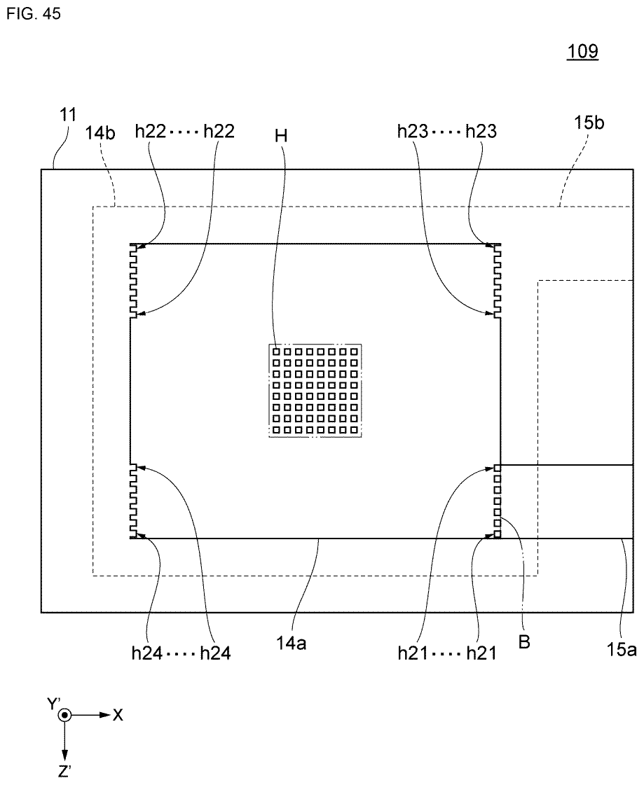

Next, a configuration of a quartz crystal resonator 109 according to a ninth embodiment will be described with reference to FIG. 45. FIG. 45 is a plan view of the quartz crystal resonator according to the ninth embodiment.

In the quartz crystal resonator 109, in addition to the cavities h21 arranged in a row, which are provided on the first excitation electrode 14a side of the boundary B, cavities h22, h23, and h24 arranged in a row are further provided. The cavity h21 in the quartz crystal resonator 109 according to the ninth embodiment has the same configuration as the cavity h2 provided in the quartz crystal resonator 108 according to the eighth embodiment. The cavities h21 arranged in a row are provided at corners of the first excitation electrode 14a on the positive X axis direction side and the positive Z′ axis direction side. The cavities h22 arranged in a row are provided at corners of the first excitation electrode 14a on the negative X axis direction side and the negative Z′ axis direction side. The cavities h23 arranged in a row are provided at corners of the first excitation electrode 14a on the positive X axis direction side and the negative Z′ axis direction side. The cavities h24 arranged in a row are provided at corners of the first excitation electrode 14a on the negative X axis direction side and the positive Z′ axis direction side. The cavities h22, h23, and h34 are arranged in rows in the Z′ axis direction. The cavities h21 and h23 are substantially provided within the range of the distance of four times the thickness Tq of the quartz crystal element 11 from the outer peripheral portion 71. The cavities h22 and h24 are substantially provided within the range of the distance of four times the thickness Tq of the quartz crystal element 11 from the outer peripheral portion 72.

The cavity h21 is provided in a region on the first extended electrode 15a side with respect to the high acoustic velocity region 17 in the low acoustic velocity region 18. The cavity h22 is provided in a region of the low acoustic velocity region 18 on a side opposite to the first extended electrode 15a with the high acoustic velocity region 17 interposed therebetween. The cavity h23 and the cavity h24 are provided diagonally opposite to each other in the low acoustic velocity region 18 with the high acoustic velocity region 17 interposed therebetween. The cavity h21 corresponds to an example of a first cavity, the cavity h22 corresponds to an example of a second cavity, the cavity h23 corresponds to an example of a third cavity, and the cavity h24 corresponds to an example of a fourth cavity.

The cavity h21 and the cavity h22 are provided at positions that are point-symmetric with respect to the center of the first excitation electrode 14a. The cavity h21 and the cavity h22 are provided in a shape that is point-symmetric with respect to the center of the first excitation electrode 14a. The cavity h23 and the cavity h24 are provided at positions that are point-symmetric with respect to the center of the first excitation electrode 14a. The cavity h23 and the cavity h24 are provided in a shape that is point-symmetric with respect to the center of the first excitation electrode 14a.

All of the cavities h21, h22, h23, and h24 arranged in rows are provided in the first excitation electrode 14a, but the present disclosure is not limited thereto. At least one of the cavities h21, h22, h23, and h24 arranged in rows may be provided in the second excitation electrode 14b.

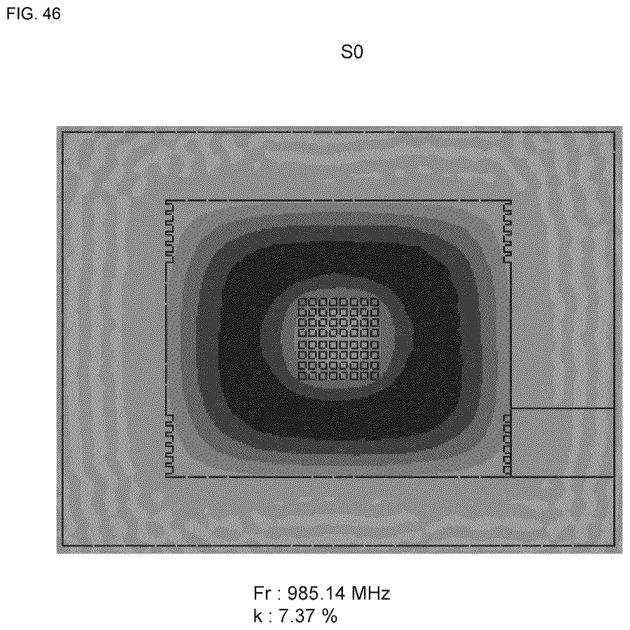

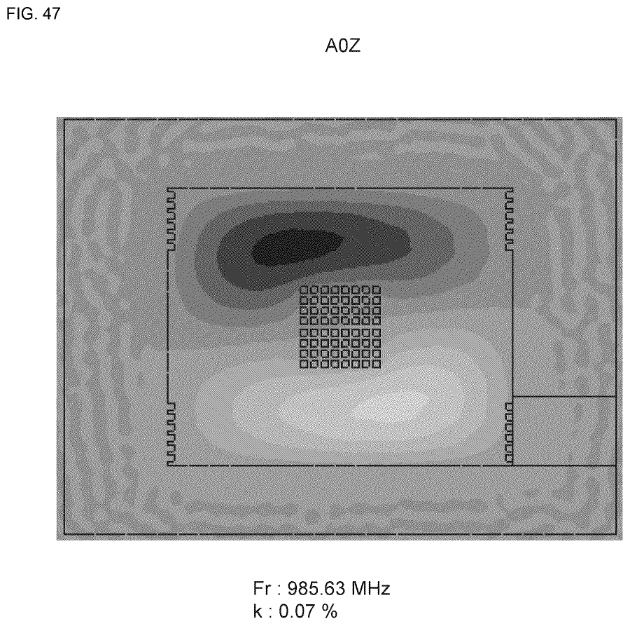

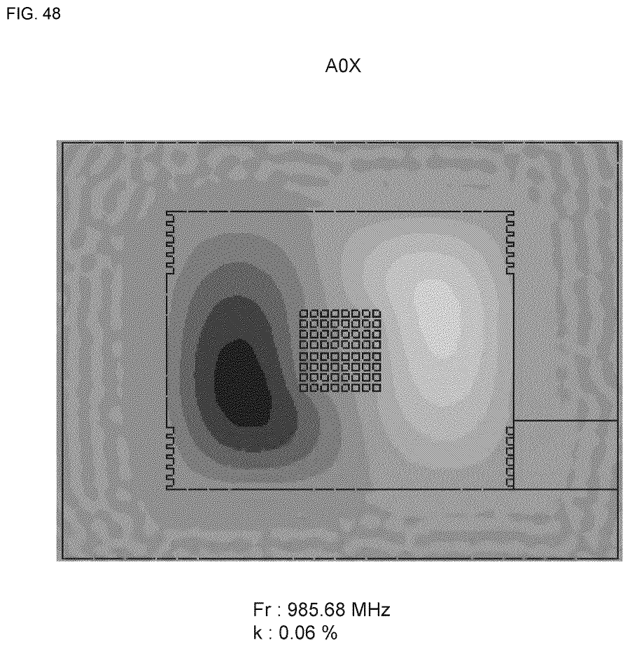

Next, a simulation result based on the ninth embodiment will be described with reference to FIGS. 46 to 48. FIGS. 46 to 48 are diagrams showing the vibration distributions of the quartz crystal resonator according to the ninth embodiment. FIG. 46 shows a vibration distribution in the S0 mode as a simulation result based on the ninth embodiment. FIG. 47 shows a vibration distribution in the A0Z mode as a simulation result based on the ninth embodiment. FIG. 48 shows a vibration distribution in the A0X mode as a simulation result based on the ninth embodiment. In FIGS. 46 to 48, the first excitation electrode 14a and the first extended electrode 15a are shown, and the second excitation electrode 14b and the second extended electrode 15b are not shown.

As shown in FIG. 46, k_{S0} is 7.37% and Fr_{S0} is 985.14 MHz in an example of the ninth embodiment. As shown in FIG. 47, k_{A0Z} is 0.07% and Fr_{A0Z} is 985.64 MHz in an example of the ninth embodiment. As shown in FIG. 48, k_{A0X} is 0.06% and Fr_{A0X} is 985.68 MHz in an example of the ninth embodiment.

k_{S0} in the example of the ninth embodiment is not substantially changed from k_{S0} of the comparative example. k_{A0Z} and k_{A0X} in the example of the ninth embodiment are smaller than k_{A0Z} and k_{A0X} in the comparative example.

### Tenth Exemplary Embodiment

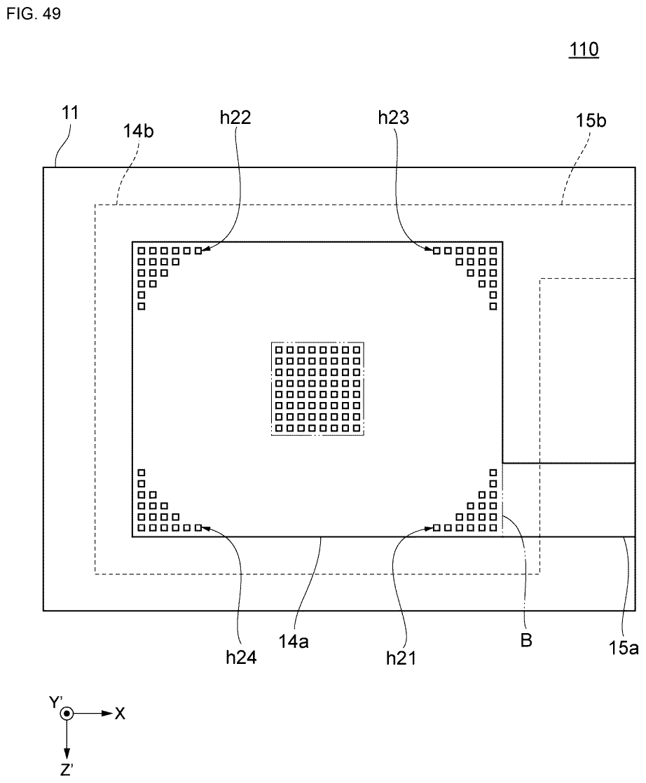

Next, a configuration of a quartz crystal resonator 110 according to a tenth embodiment will be described with reference to FIG. 49. FIG. 49 is a plan view of the quartz crystal resonator according to the tenth embodiment.

Each of the plurality of cavities h21, h22, h23, and h24 is arranged in a matrix in the X axis direction and the Z′ axis direction. The cavity h21 is provided in a region on the first extended electrode 15a side with respect to the high acoustic velocity region 17 in the low acoustic velocity region 18. The cavity h22 is provided in a region of the low acoustic velocity region 18 on a side opposite to the first extended electrode 15a with the high acoustic velocity region 17 interposed therebetween. The cavity h23 and the cavity h24 are provided diagonally opposite to each other in the low acoustic velocity region 18 with the high acoustic velocity region 17 interposed therebetween.

The number of cavities h21 arranged in the Z′ axis direction increases toward the positive X axis direction side. The number of cavities h21 arranged in the X axis direction increases toward the positive Z′ axis direction side. The cavity h21 is provided in a region surrounded by the end portion of the first excitation electrode 14a on the positive X axis direction side, the end portion of the first excitation electrode 14a on the positive Z′ axis direction side, and the arc centered on the high acoustic velocity region 17.

The number of cavities h22 arranged in the Z′ axis direction increases toward the negative X axis direction side. The number of cavities h22 arranged in the X axis direction increases toward the negative Z′ axis direction side. The cavity h22 is provided in a region surrounded by the end portion of the first excitation electrode 14a on the negative X axis direction side, the end portion of the first excitation electrode 14a on the negative Z′ axis direction side, and the arc centered on the high acoustic velocity region 17.

The number of cavities h23 arranged in the Z′ axis direction increases toward the positive X axis direction side. The number of cavities h23 arranged in the X axis direction increases toward the negative Z′ axis direction side. The cavity h23 is provided in a region surrounded by the end portion of the first excitation electrode 14a on the positive X axis direction side, the end portion of the first excitation electrode 14a on the negative Z′ axis direction side, and the arc centered on the high acoustic velocity region 17.

The number of cavities h24 arranged in the Z′ axis direction increases toward the negative X axis direction side. The number of cavities h24 arranged in the X axis direction increases toward the positive Z′ axis direction side. The cavity h24 is provided in a region surrounded by the end portion of the first excitation electrode 14a on the negative X axis direction side, the end portion of the first excitation electrode 14a on the positive Z′ axis direction side, and the arc centered on the high acoustic velocity region 17.

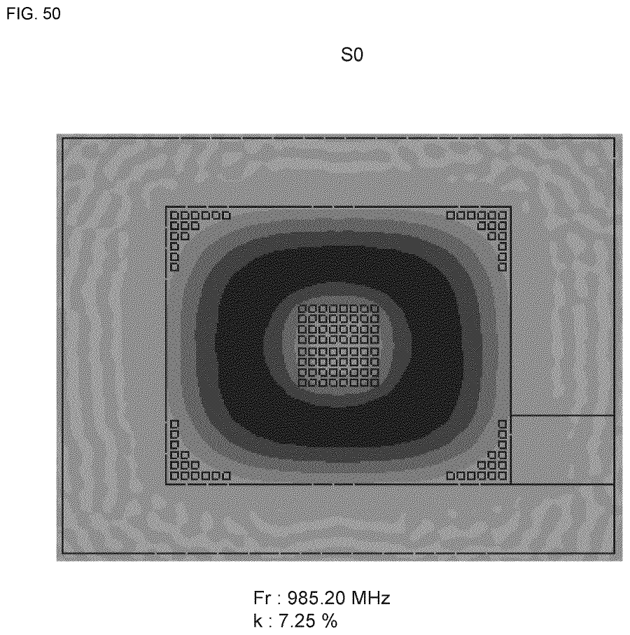

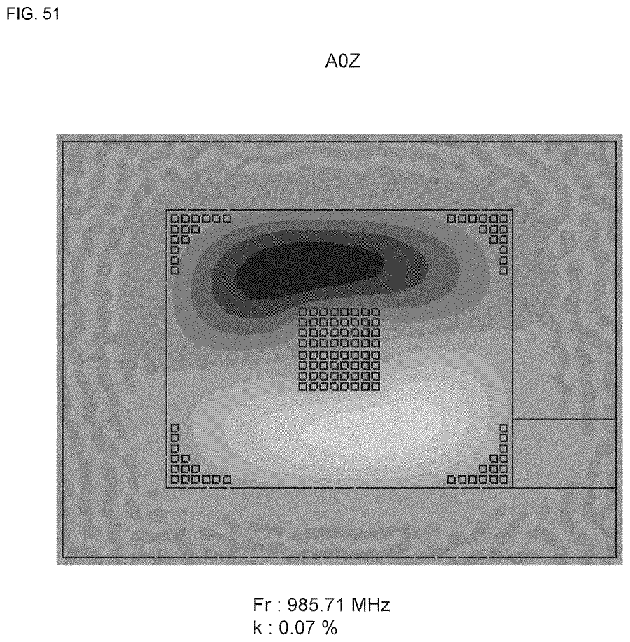

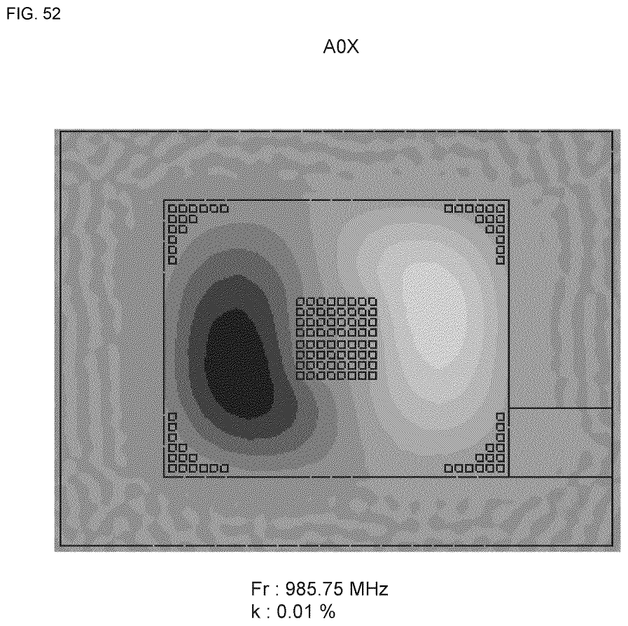

Next, a simulation result based on the tenth embodiment will be described with reference to FIGS. 50 to 52. FIGS. 50 to 52 are diagrams showing the vibration distributions of the quartz crystal resonator according to the tenth embodiment. FIG. 50 shows a vibration distribution in the S0 mode as a simulation result based on the tenth embodiment. FIG. 51 shows a vibration distribution in the A0Z mode as a simulation result based on the tenth embodiment. FIG. 52 shows a vibration distribution in the A0X mode as a simulation result based on the tenth embodiment. In FIGS. 50 to 52, the first excitation electrode 14a and the first extended electrode 15a are shown, and the second excitation electrode 14b and the second extended electrode 15b are not shown.

As shown in FIG. 50, k_{S0} is 7.25% and Fr_{S0} is 985.20 MHz in an example of the tenth embodiment. As shown in FIG. 51, k_{A0Z} is 0.07% and Fr_{A0Z} is 985.71 MHz in an example of the tenth embodiment. As shown in FIG. 52, k_{A0X} is 0.01% and Fr_{A0X} is 985.75 MHz in an example of the tenth embodiment.

k_{S0} in the example of the tenth embodiment is not substantially changed from k_{S0} of the comparative example. k_{A0Z} and k_{A0X} in the example of the tenth embodiment are smaller than k_{A0Z} and k_{A0X} in the comparative example.

### Eleventh Exemplary Embodiment

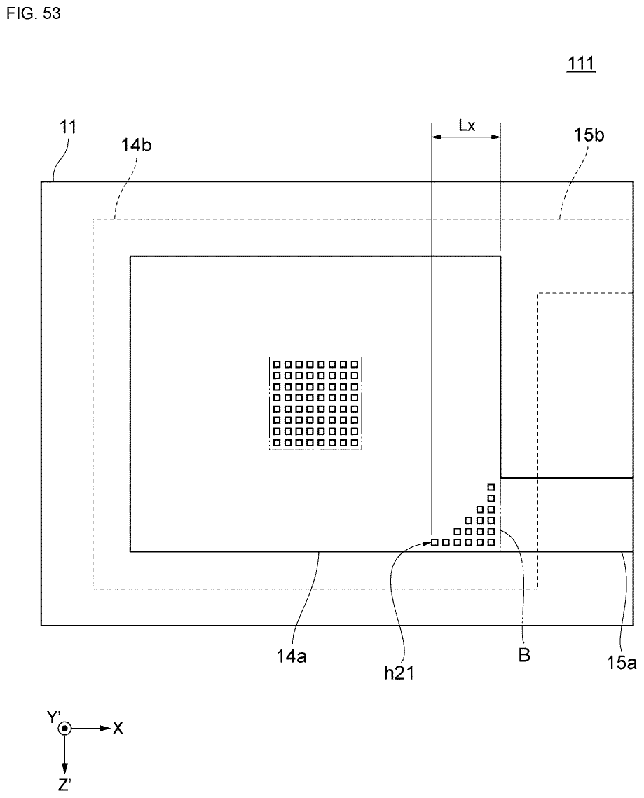

Next, a configuration of a quartz crystal resonator 111 according to an eleventh embodiment will be described with reference to FIG. 53. FIG. 53 is a plan view of the quartz crystal resonator according to the eleventh embodiment.

In the quartz crystal resonator 111, the matrix-shaped cavity h21 are provided in a region surrounded by the end portion of the first excitation electrode 14a on the positive X axis direction side, the end portion of the first excitation electrode 14a on the positive Z′ axis direction side, and the arc centered on the high acoustic velocity region 17. In the X axis direction, a dimension from the boundary B to the end portion of the cavity provided farthest from the boundary B on the negative X axis direction side among the plurality of cavities h21 is defined as a distance Lx.

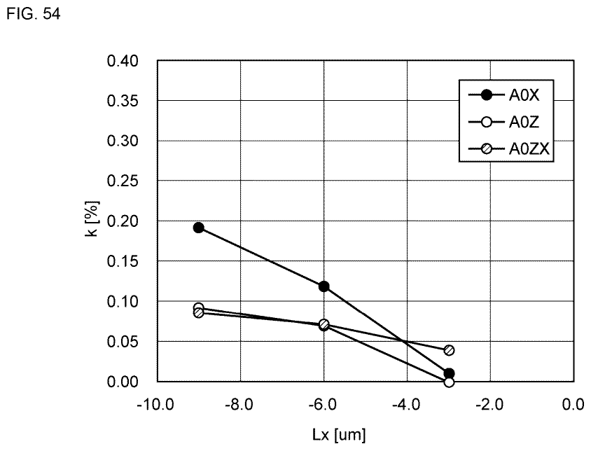

Next, a simulation result based on the eleventh embodiment will be described with reference to FIGS. 54 to 57.

FIG. 54 is a graph showing a simulation result based on the eleventh embodiment. In the graph shown in FIG. 54, the horizontal axis indicates a distance Lx [μm] from the boundary B to the end portion of the cavity provided farthest from the boundary B on the negative X axis direction side, and the vertical axis indicates an electromechanical coupling coefficient k [%]. The simulation conditions of the graph shown in FIG. 54 are the same as the simulation conditions of the vibration distribution based on the first embodiment, except that the cavity h21 is provided instead of the cavity h1, Lh2=Wh2=2 μm, and Lx is a variable.

As Lx decreases, the electromechanical coupling coefficient in the A0 mode increases. That is, as the cavity h21 approaches the high acoustic velocity region 17, the suppression effect of the A0 mode by the cavity h2 decreases. In order to suppress the A0 mode as compared with the comparative example, desirably, −5 μm≤Lx≤0 μm is established.

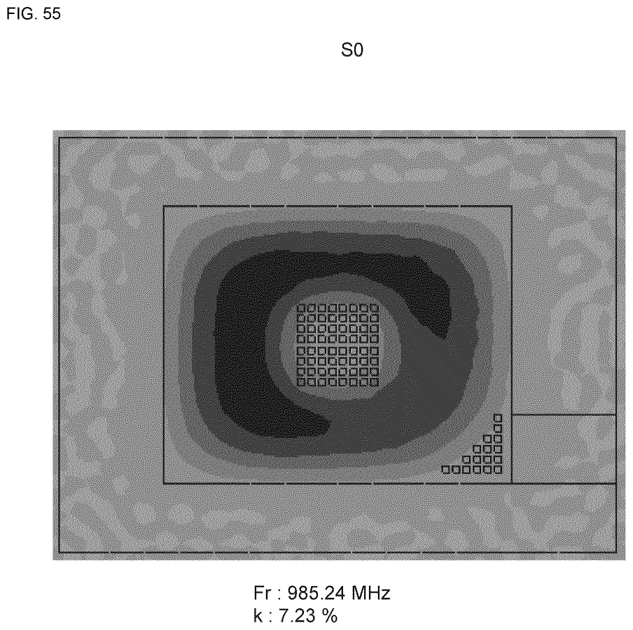

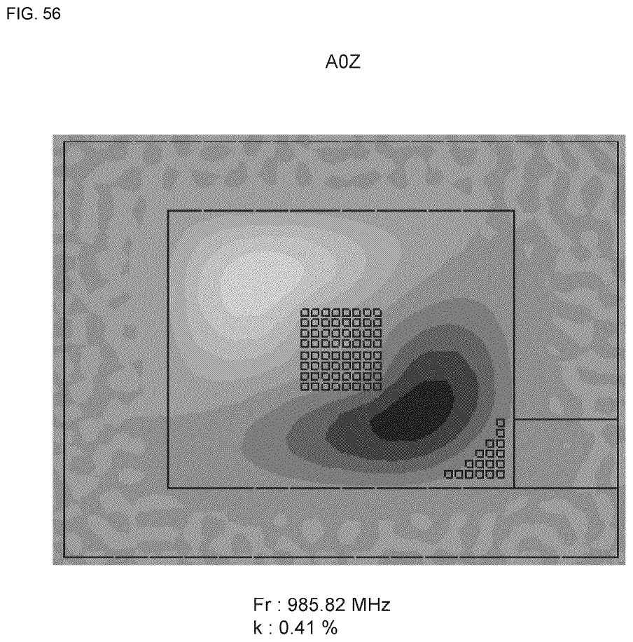

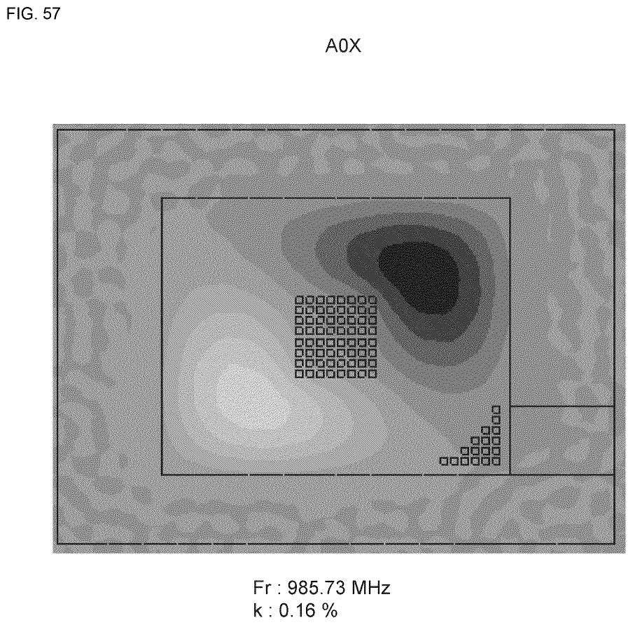

FIGS. 55 to 57 are diagrams showing vibration distributions of quartz crystal resonator according to a comparative example with respect to the eleventh embodiment. FIG. 55 shows a vibration distribution in the S0 mode as a simulation result based on a comparative example with respect to the eleventh embodiment. FIG. 56 shows a vibration distribution in the A0Z mode as a simulation result based on a comparative example with respect to the eleventh embodiment. FIG. 57 shows a vibration distribution in the A0X mode as a simulation result based on a comparative example with respect to the eleventh embodiment. In FIGS. 55 to 57, the first excitation electrode 14a and the first extended electrode 15a are shown, and the second excitation electrode 14b and the second extended electrode 15b are not shown.

As shown in FIG. 55, k_{S0} is 7.23% and Fr_{S0} is 985.24 MHz in a comparative example with respect to the eleventh embodiment. As shown in FIG. 56, k_{A0Z} is 0.41% and Fr_{A0Z} is 985.41 MHz in a comparative example with respect to the eleventh embodiment. As shown in FIG. 57, k_{A0X} is 0.16% and Fr_{A0X} is 985.73 MHz in a comparative example with respect to the eleventh embodiment.

k_{S0} in the comparative example with respect to the eleventh embodiment is smaller than k_{S0} in a case where the cavity is not provided. k_{A0Z} and k_{A0X} in the comparative example with respect to the eleventh embodiment are greater than k_{A0Z} and k_{A0X} in a case where the cavity is not provided. The reason why the A0 mode in the comparative example with respect to the eleventh embodiment is not suppressed as compared with a case where the cavity is not provided is that the cavity h21 is arranged in a maximum of six in the X axis direction in the comparative example with respect to the eleventh embodiment, and Lx<<−5 μm is established. In a case where the length Wh2 of the cavity h21 along the X axis direction is set to 2 μm and the distance Wp between the end portions of the two adjacent cavities h2 on the negative X axis direction side is set to 3 μm, Lx=−18 μm is established in the comparative example with respect to the eleventh embodiment, which is significantly out of the range of −5 μm≤Lx≤0 μm. As described in FIG. 54, in a case where the relationship of −5 μm≤Lx≤0 μm is established, the A0 mode is suppressed in the present embodiment as compared with a case where there is no cavity.

### Twelfth Exemplary Embodiment

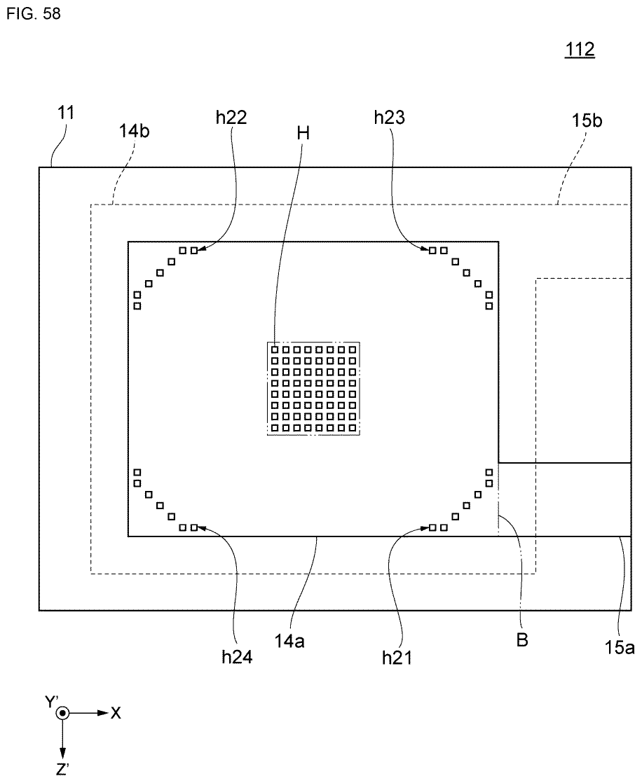

Next, a configuration of a quartz crystal resonator 112 according to a twelfth embodiment will be described with reference to FIG. 58. FIG. 58 is a plan view of the quartz crystal resonator according to the twelfth embodiment.

Each of the plurality of cavities h21, h22, h23, and h24 is arranged in an arc shape centered on the high acoustic velocity region 17. Each of the plurality of cavities h21 are provided at corners of the first excitation electrode 14a on the positive X axis direction side and the positive Z′ axis direction side. The plurality of cavities h22 are provided at corners of the first excitation electrode 14a on the negative X axis direction side and the negative Z′ axis direction side. The plurality of cavities h23 are provided at corners of the first excitation electrode 14a on the positive X axis direction side and the negative Z′ axis direction side. The plurality of cavities h24 are provided at corners of the first excitation electrode 14a on the negative X axis direction side and the positive Z′ axis direction side.

The cavity h21 is provided in a region on the first extended electrode 15a side with respect to the high acoustic velocity region 17 in the low acoustic velocity region 18. The cavity h22 is provided in a region of the low acoustic velocity region 18 on a side opposite to the first extended electrode 15a with the high acoustic velocity region 17 interposed therebetween. The cavity h23 and the cavity h24 are provided diagonally opposite to each other in the low acoustic velocity region 18 with the high acoustic velocity region 17 interposed therebetween.

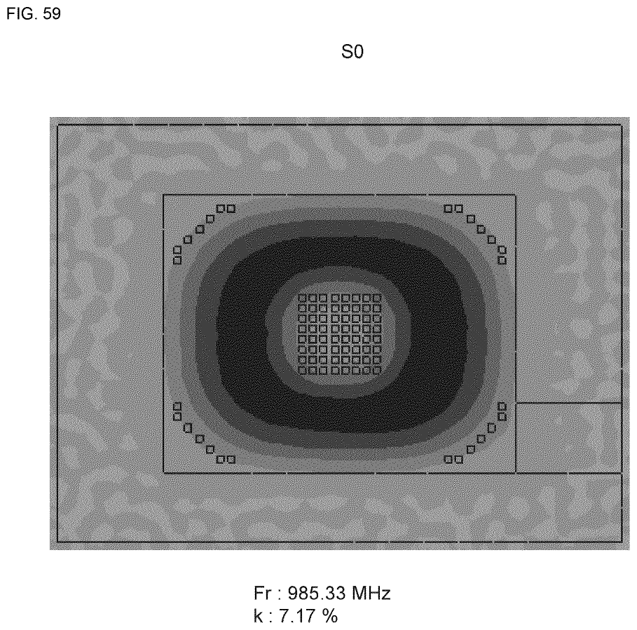

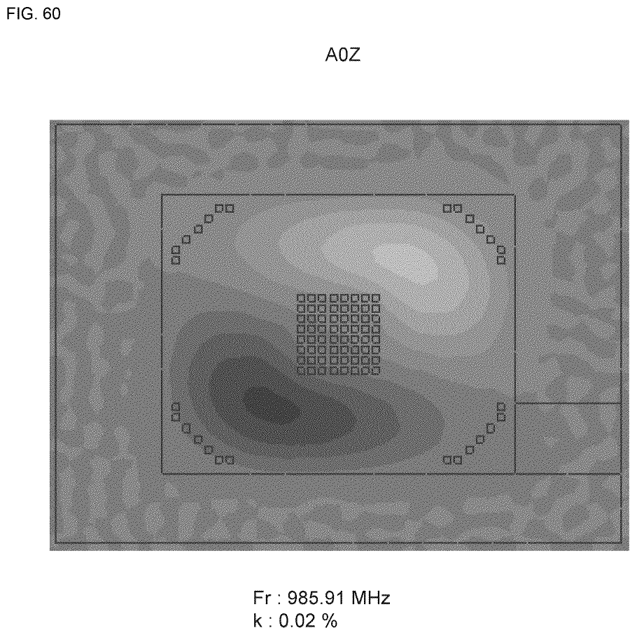

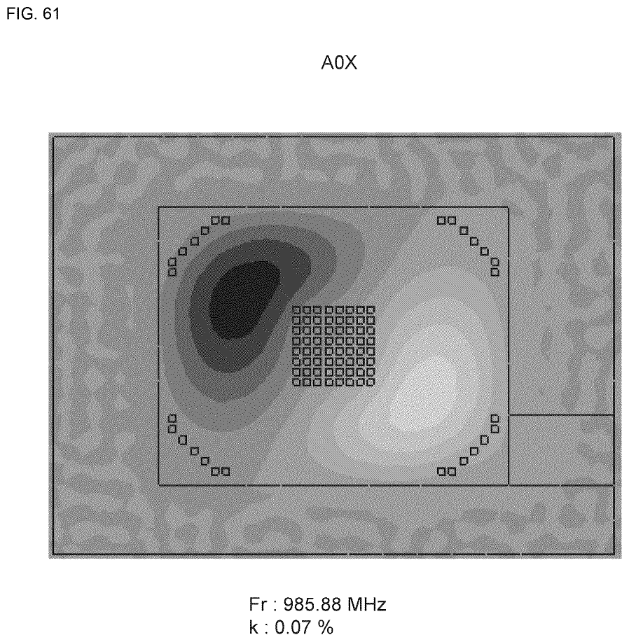

Next, a simulation result based on the twelfth embodiment will be described with reference to FIGS. 59 to 61. FIGS. 59 to 61 are diagrams showing the vibration distributions of the quartz crystal resonator according to the twelfth embodiment. FIG. 59 shows a vibration distribution in the S0 mode as a simulation result based on the twelfth embodiment. FIG. 60 shows a vibration distribution in the A0Z mode as a simulation result based on the twelfth embodiment. FIG. 61 shows a vibration distribution in the A0X mode as a simulation result based on the twelfth embodiment. In FIGS. 59 to 61, the first excitation electrode 14a and the first extended electrode 15a are shown, and the second excitation electrode 14b and the second extended electrode 15b are not shown.

As shown in FIG. 59, k_{S0} is 7.17% and Fr_{S0} is 985.33 MHz in an example of the twelfth embodiment. As shown in FIG. 60, k_{A0Z} is 0.02% and Fr_{A0Z} is 985.91 MHz in an example of the twelfth embodiment. As shown in FIG. 61, k_{A0X} is 0.07% and Fr_{A0X} is 985.88 MHz in an example of the twelfth embodiment.

k_{S0} in the example of the twelfth embodiment is slightly smaller than k_{S0} in the comparative example. k_{A0Z} and k_{A0X} in the example of the twelfth embodiment are smaller than k_{A0Z} and k_{A0X} in the comparative example. The reason why k_{S0} is small is that, as shown in FIG. 59, the vibration distribution does not spread over the entire surface of the first excitation electrode 14a, and only the region surrounded by the plurality of cavities h21, h22, h23, and h24 vibrates strongly. On the other hand, the reason why k_{A0Z} and k_{A0X} become small and the A0 mode is suppressed is that, within a region surrounded by the plurality of cavities h21, h22, h23, and h24, the vibrations of opposite phases are distributed symmetrically with the high acoustic velocity region 17 interposed therebetween, and the vibrations of opposite phases cancel each other out.

### Thirteenth Exemplary Embodiment

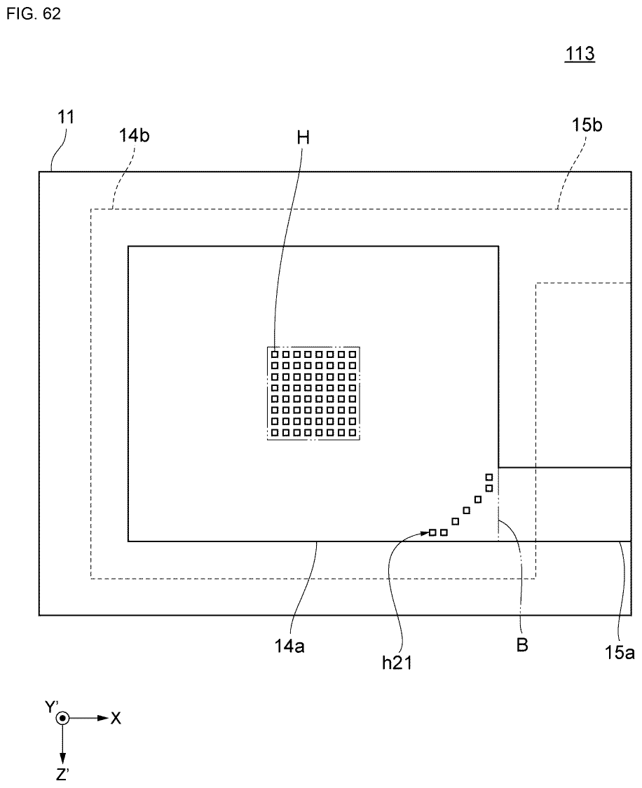

Next, a configuration of a quartz crystal resonator 113 according to a thirteenth embodiment will be described with reference to FIG. 62. FIG. 62 is a plan view of the quartz crystal resonator according to the thirteenth embodiment.

The quartz crystal resonator 113 according to the thirteenth embodiment is different from the quartz crystal resonator 112 according to the twelfth embodiment in that the plurality of cavities h22, h23, and h24 are omitted.

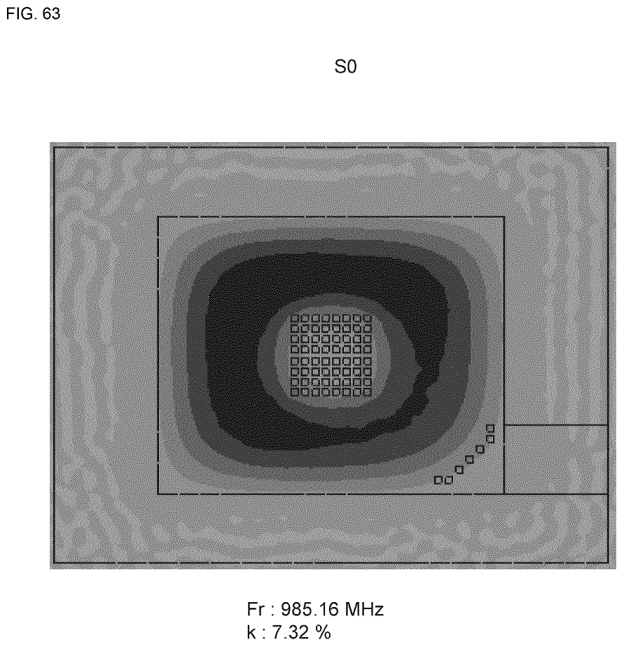

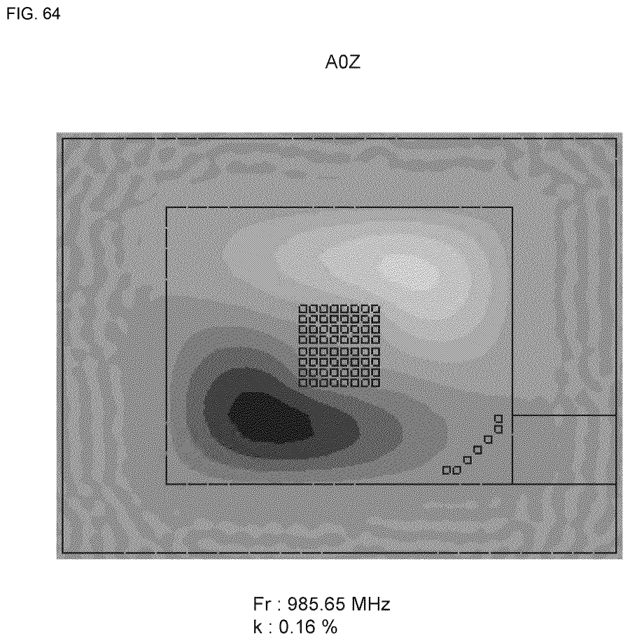

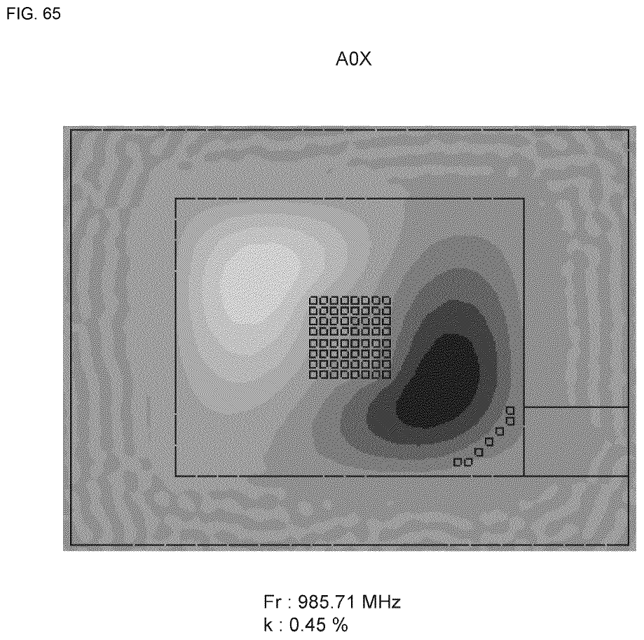

Next, a simulation result based on the thirteenth embodiment will be described with reference to FIGS. 63 to 65. FIGS. 63 to 65 are diagrams showing the vibration distributions of the quartz crystal resonator according to the thirteenth embodiment. FIG. 63 shows a vibration distribution in the S0 mode as a simulation result based on the thirteenth embodiment. FIG. 64 shows a vibration distribution in the A0Z mode as a simulation result based on the thirteenth embodiment. FIG. 65 shows a vibration distribution in the A0X mode as a simulation result based on the thirteenth embodiment. In FIGS. 63 to 65, the first excitation electrode 14a and the first extended electrode 15a are shown, and the second excitation electrode 14b and the second extended electrode 15b are not shown.

As shown in FIG. 63, k_{S0} is 7.32% and Fr_{S0} is 985.16 MHz in an example of the thirteenth embodiment. As shown in FIG. 64, k_{A0Z} is 0.16% and Fr_{A0Z} is 985.65 MHz in an example of the thirteenth embodiment. As shown in FIG. 65, k_{A0X} is 0.45% and Fr_{A0X} is 985.71 MHz in an example of the thirteenth embodiment.

k_{S0} in the example of the thirteenth embodiment has substantially the same size as k_{S0} in the comparative example. k_{A0Z} in the example of the thirteenth embodiment is smaller than k_{A0Z} in the comparative example. k_{A0X} in the example of the thirteenth embodiment is greater than k_{A0X} in the comparative example. The reason why k_{A0Z} is small is that, as shown in FIG. 64, the positions of the plurality of cavities h21 are far from the positions of the vibration peaks in the A0Z mode and do not significantly affect the balance of vibrations of opposite phases. The reason why k_{A0X} is large is that, as shown in FIG. 65, the positions of the plurality of cavities h21 are close to the positions of the vibration peaks in the A0Z mode, and the plurality of cavities h21 disrupt the balance of vibrations of the opposite phases.

### Fourteenth Exemplary Embodiment

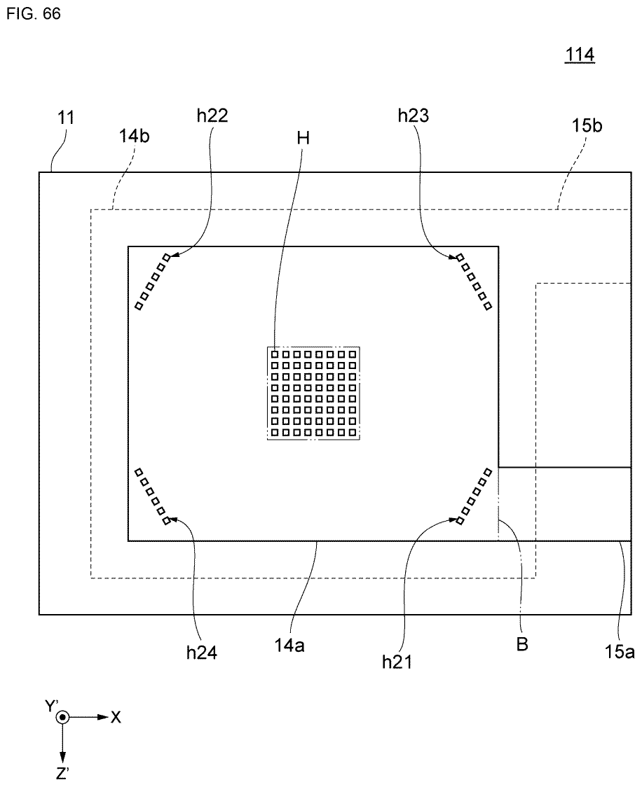

Next, a configuration of a quartz crystal resonator 114 according to a fourteenth embodiment will be described with reference to FIG. 66. FIG. 66 is a plan view of the quartz crystal resonator according to the fourteenth embodiment.

Each of the plurality of cavities h21, h22, h23, and h24 is cavities arranged in a row in a straight line, and is arranged in a direction intersecting the Z′ axis direction. The cavities h21 arranged in a row are separated from the end portion of the first excitation electrode 14a on the positive X axis direction side as the cavities h21 face the positive Z′ axis direction side. The cavities h21 arranged in a row are separated from the end portion of the first excitation electrode 14a on the negative X axis direction side toward the negative Z′ axis direction side. The cavities h23 arranged in a row are separated from the end portion of the first excitation electrode 14a on the positive X axis direction side as the cavities h23 face the negative Z′ axis direction side. The cavities h24 arranged in a row are separated from the end portion of the first excitation electrode 14a on the negative X axis direction side toward the positive Z′ axis direction side. The angle formed with the direction, in which the plurality of cavities h21, h22, h23, and h24 are arranged, and the Z′ axis direction is, for example, 30°.

### Fifteenth Exemplary Embodiment

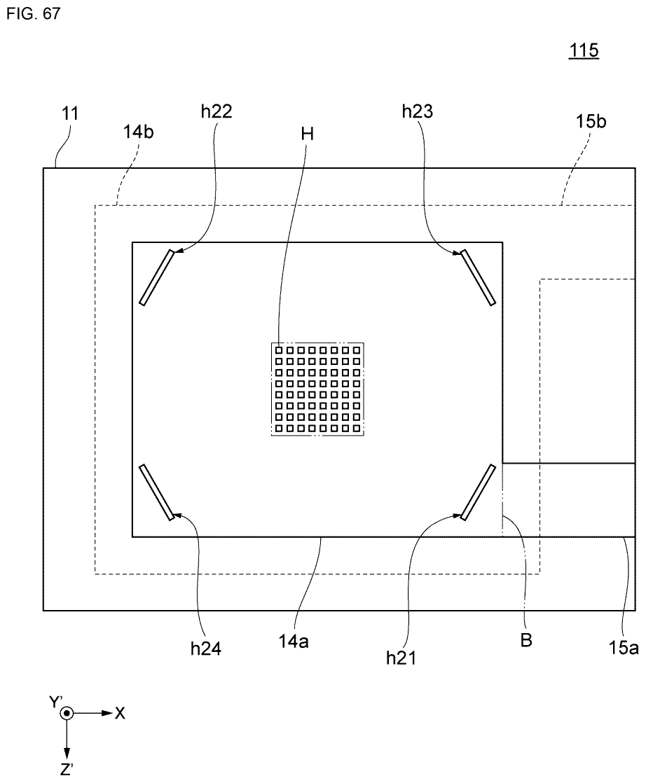

Next, a configuration of a quartz crystal resonator 115 according to a fifteenth embodiment will be described with reference to FIG. 67. FIG. 67 is a plan view of the quartz crystal resonator according to the fifteenth embodiment.

Each of the cavities h21, h22, h23, and h24 is a slit-shaped cavity that extends in a straight line and has a longitudinal shape in a direction intersecting the Z′ axis direction. The slit-shaped cavities h21 are separated from the end portion of the first excitation electrode 14a on the positive X axis direction side as the cavities h21 face the positive Z′ axis direction side. The slit-shaped cavities h21 are separated from the end portion of the first excitation electrode 14a on the negative X axis direction side as the cavities h21 face the negative Z′ axis direction side. The slit-shaped cavities h23 are separated from the end portion of the first excitation electrode 14a on the positive X axis direction side as the cavities h23 face the negative Z′ axis direction side. The slit-shaped cavities h24 are separated from the end portion of the first excitation electrode 14a on the negative X axis direction side as the cavities h24 face the positive Z′ axis direction side. An angle formed with the longitudinal direction of each of the slit-shaped cavities h21, h22, h23, and h24 and the Z′ axis direction is, for example, 30°.

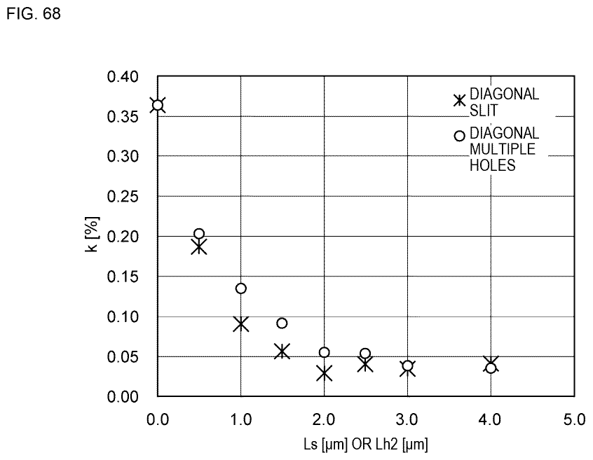

Next, the influence of the length Ls in the fourteenth embodiment and the fifteenth embodiment will be described with reference to FIG. 68. FIG. 68 is a graph showing a simulation result based on the fourteenth embodiment and the fifteenth embodiment. In FIG. 68, the horizontal axis indicates the length Ls or the length Lh2, and the vertical axis indicates k_{A0Z}. The length Ls is a dimension of the slit-shaped cavity in the lateral direction of the cavity, and the length Lh2 is a dimension of each of the cavities arranged in a row along the direction intersecting the direction in which the cavities are arranged.

The simulation conditions of the graph shown in FIG. 68 are the same as the simulation conditions of the vibration distribution based on the first embodiment, except for the conditions related to the cavity. The direction in which the cavities are arranged in a row is tilted by 30° from the Z′ axis direction. A longitudinal direction of the slit-shaped cavity is tilted by 30° from the Z′ axis direction. In a case of the cavities arranged in a row, the array period Wp of the cavities is 3 μm, the length Wh2 of the cavities in the direction in which the cavities are arranged is 2 μm, and the number of cavities arranged in one row is 7. In a case of the slit-shaped cavity, the length Wh1 of the cavity in the longitudinal direction is 20 μm.

k_{A0Z} shows the same tendency with respect to the length Ls of the slit-shaped cavity and the length Lh2 of each of the cavities arranged in a row. In the fourteenth embodiment, the greater the length Ls, the smaller k_{A0Z}, and in the fifteenth embodiment, the greater the length Lh2, the smaller k_{A0Z}. In a case where the length Ls or the length Lh2 is 3 μm or more, that is, in a case where Tq×2≤Ls or Tq×2≤Lh2, k_{A0Z} becomes sufficiently small.

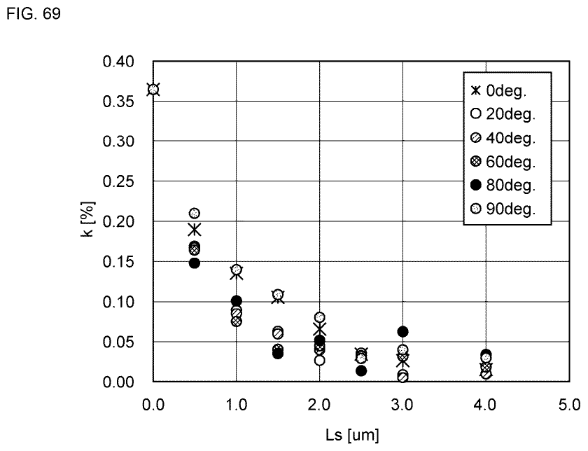

Next, the influence of the angle of the cavity in the fifteenth embodiment will be described with reference to FIG. 69. FIG. 69 is a graph showing a simulation result based on the fifteenth embodiment. In FIG. 69, the horizontal axis indicates the length Ls, and the vertical axis indicates k_{A0Z}. The length Ls is a dimension along the lateral direction of the cavity. k_{A0Z} with respect to the length Ls is plotted in a case where the angle formed with the longitudinal direction of the cavity and the Z′ axis direction is 0°, 20°, 40°, 60°, 80°, and 90°. The angle is an angle obtained by rotating the longitudinal direction of the cavity h21 clockwise, that is, to the negative X axis direction side, with the end portion of the cavity h21 on the negative Z′ axis direction side as a rotation center. The angle is an angle obtained by rotating the longitudinal direction of the cavity h22 clockwise, that is, to the positive X axis direction side, with the end portion of the cavity h22 on the positive Z′ axis direction side as a rotation center. The angle is an angle obtained by rotating the longitudinal direction of the cavity h23 counterclockwise, that is, to the negative X axis direction side, with the end portion of the cavity h23 on the positive Z′ axis direction side as a rotation center. The angle is an angle obtained by rotating the longitudinal direction of the cavity h24 counterclockwise, that is, to the positive X axis direction side, with the end portion of the cavity h24 on the negative Z′ axis direction side as a rotation center.

The simulation conditions of the graph shown in FIG. 69 are the same as the simulation conditions of the graph shown in FIG. 68 except that the angle formed with the longitudinal direction of the cavity and the Z′ axis direction is a variable.

In a range in which the angle formed with the longitudinal direction of the cavity and the Z′ axis direction is 0° or more and 90° or less, k_{A0Z} decreases as Ls increases, regardless of the angle. In a case where the length Ls is 3 μm or more, that is, in a case where Tq×2≤Ls, k_{A0Z} becomes sufficiently small. Even in a case where the angle formed with the longitudinal direction of the cavity and the Z′ axis direction is 90°, k_{A0Z} becomes small in a case where Tq×2≤Ls. Therefore, even in a case where the slit-shaped cavity has a longitudinal shape in a direction intersecting the boundary B, the A0 mode is sufficiently suppressed.

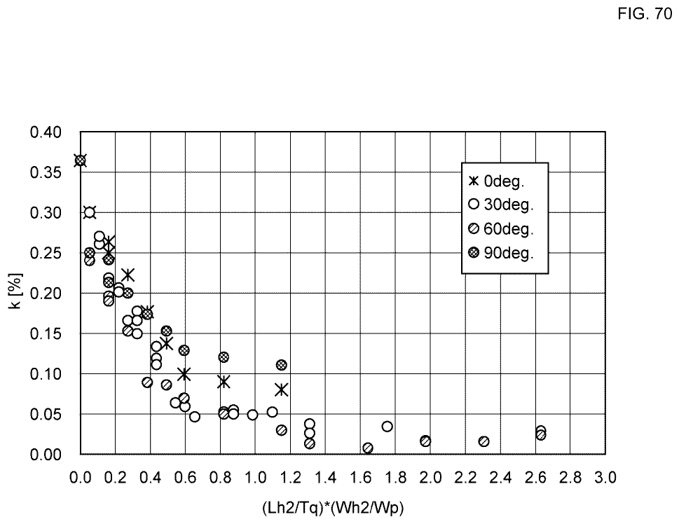

Next, the influence of the angle of the cavity in the fourteenth embodiment will be described with reference to FIG. 70. FIG. 70 is a graph showing a simulation result based on the fourteenth embodiment. In FIG. 70, the horizontal axis indicates (Lh2/Tq)×(Wh2/Wp), and the vertical axis indicates k_{A0Z}. k_{A0Z} is plotted in a case where the angle formed with the direction in which the cavities are arranged and the Z′ axis direction is 0°, 30°, 60°, and 90°. The angle is an angle obtained by rotating the direction in which the plurality of cavities h21 are arranged clockwise, that is, to the negative X axis direction side, with the cavity on the most negative Z′ axis direction side among the plurality of cavities h21 as a rotation center. The angle is an angle obtained by rotating the direction in which the plurality of cavities h22 are arranged clockwise, that is, to the positive X axis direction side, with the cavity on the most positive Z′ axis direction side among the plurality of cavities h22 as a rotation center. The angle is an angle obtained by rotating the direction in which the plurality of cavities h23 are arranged counterclockwise, that is, to the negative X axis direction side, with the cavity on the most positive Z′ axis direction side among the plurality of cavities h23 as a rotation center. The angle is an angle obtained by rotating the direction in which the plurality of cavities h24 are arranged counterclockwise, that is, to the positive X axis direction side, with the cavity on the most negative Z′ axis direction side among the plurality of cavities h24 as a rotation center.

The simulation conditions of the graph shown in FIG. 70 are the same as the simulation conditions of the graph shown in FIG. 68 except that the length Wh2 and the length Lh2 are variables and the angle formed with the direction in which the cavities are arranged and the Z′ axis direction is a variable.

In a range in which the angle formed with the direction in which the cavities are arranged and the Z′ axis direction is 0° or more and 90° or less, k_{A0Z} decreases as (Lh2/Tq)×(Wh2/Wp) increases regardless of the angle. In a case where 0.6≤(Lh2/Tq)×(Wh2/Wp) is established, k_{A0Z} becomes sufficiently small. Even in a case where the angle formed with the direction in which the cavities are arranged and the Z′ axis direction is 90°, k_{A0Z} becomes small in a case where 0.6≤(Lh2/Tq)×(Wh2/Wp). Therefore, even in a case where the cavities are arranged in a row in the direction intersecting the boundary B, as long as the relationship of 0.6≤(Lh2/Tq)×(Wh2/Wp) is established, the A0 mode is sufficiently suppressed.

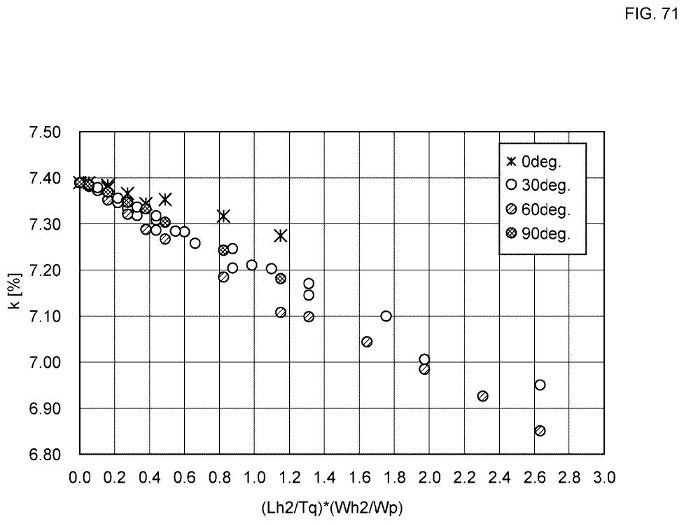

Next, the influence of the angle of the cavity in the fourteenth embodiment will be described with reference to FIG. 71. FIG. 71 is a graph showing a simulation result based on the fourteenth embodiment. In FIG. 71, the horizontal axis indicates (Lh2/Tq)×(Wh2/Wp), and the vertical axis indicates k_{S0}. k_{S0} is plotted in a case where the angle formed with the direction in which the cavities are arranged and the Z′ axis direction is 0°, 30°, 60°, and 90°.

The simulation conditions of the graph shown in FIG. 71 are the same as the simulation conditions of the graph shown in FIG. 70.

In a range in which the angle formed with the direction in which the cavities are arranged and the Z′ axis direction is 0° or more and 90° or less, k_{S0} decreases as (Lh2/Tq)×(Wh2/Wp) increases regardless of the angle. In a case where (Lh2/Tq)×(Wh2/Wp)≤2.3, k_{S0} in the fourteenth embodiment is greater than k_{S0} in the comparative example. Even in a case where the angle formed with the direction in which the cavities are arranged and the Z′ axis direction is 90°, k_{S0} becomes large in a case where (Lh2/Tq)×(Wh2/Wp)≤2.3. Therefore, even in a case where the cavities are arranged in a row in the direction intersecting the boundary B, as long as the relationship of (Lh2/Tq)×(Wh2/Wp)≤2.3 is established, the A0 mode is sufficiently suppressed.

### Sixteenth Exemplary Embodiment

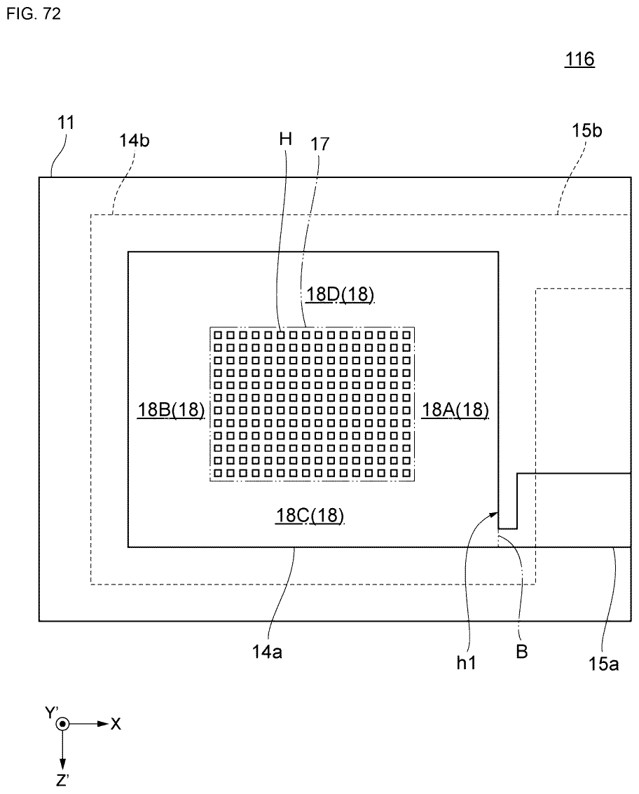

Next, a configuration of a quartz crystal resonator 116 according to a sixteenth embodiment will be described with reference to FIG. 72. FIG. 72 is a plan view of the quartz crystal resonator according to the sixteenth embodiment.

The area of the high acoustic velocity region 17 in the quartz crystal resonator 116 is greater than the area of the high acoustic velocity region 17 in the quartz crystal resonator 10. The quartz crystal resonator 116 is provided with 16×12 hole portions H.

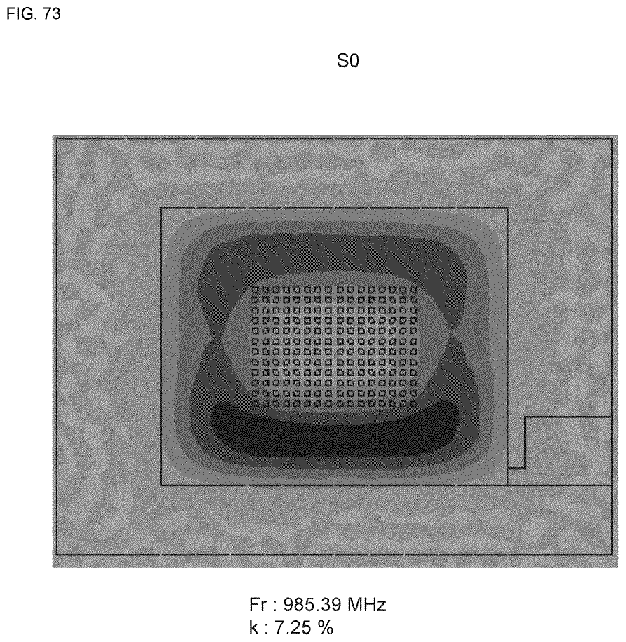

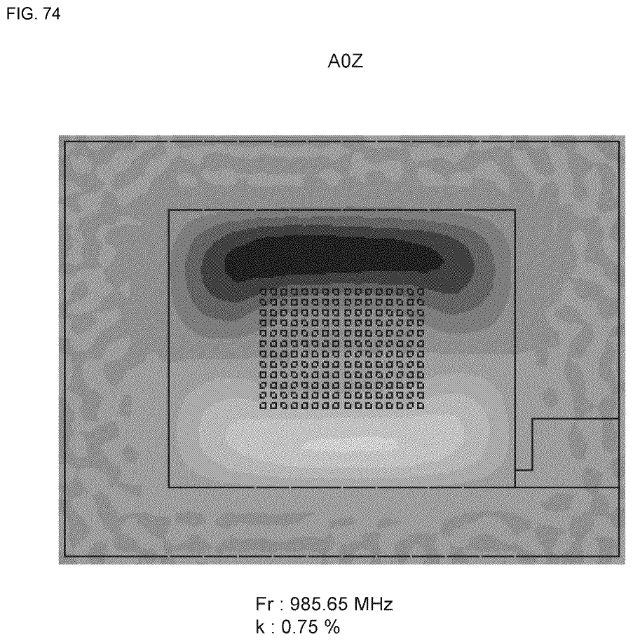

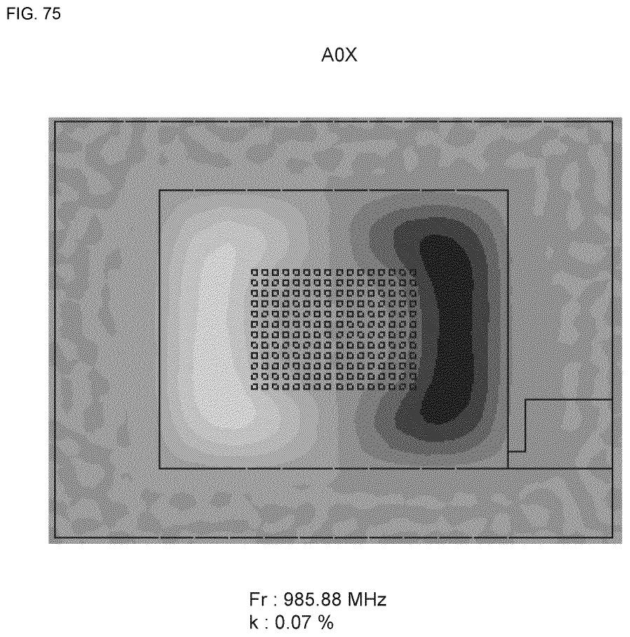

Next, a simulation result based on the sixteenth embodiment will be described with reference to FIGS. 73 to 75. FIGS. 73 to 75 are diagrams showing the vibration distributions of the quartz crystal resonator according to the sixteenth embodiment. FIG. 73 shows a vibration distribution in the S0 mode as a simulation result based on the sixteenth embodiment. FIG. 74 shows a vibration distribution in the A0Z mode as a simulation result based on the sixteenth embodiment. FIG. 75 shows a vibration distribution in the A0X mode as a simulation result based on the sixteenth embodiment. In FIGS. 73 to 75, the first excitation electrode 14a and the first extended electrode 15a are shown, and the second excitation electrode 14b and the second extended electrode 15b are not shown.

As shown in FIG. 73, k_{S0} is 7.25% and Fr_{S0} is 986.39 MHz in an example of the sixteenth embodiment. As shown in FIG. 74, k_{A0Z} is 0.75% and Fr_{A0Z} is 986.65 MHz in an example of the sixteenth embodiment. As shown in FIG. 75, k_{A0X} is 0.07% and Fr_{A0X} is 986.88 MHz in an example of the sixteenth embodiment.

Although not shown, in a comparative example in which the cavity h1 is omitted from the sixteenth embodiment, k_{S0} is 7.09%, Fr_{S0} is 986.348 MHz, k_{A0Z} is 1.75%, Fr_{A0Z} is 986.616 MHz, k_{A0X} is 0.63%, and Fr_{A0X} is 986.844 MHz.

k_{S0} in the example of the sixteenth embodiment is greater than k_{S0} in the comparative example. k_{A0Z} in the example of the sixteenth embodiment is smaller than k_{A0Z} in the comparative example. k_{A0X} in the example of the sixteenth embodiment is smaller than k_{A0X} in the comparative example. From the simulation results of the first embodiment and the sixteenth embodiment, even in a case where the area ratio between the high acoustic velocity region 17 and the low acoustic velocity region 18 is changed, the A0 mode is suppressed and the vibration characteristics of the S0 mode are improved by providing the cavity h1.

### Seventeenth Exemplary Embodiment

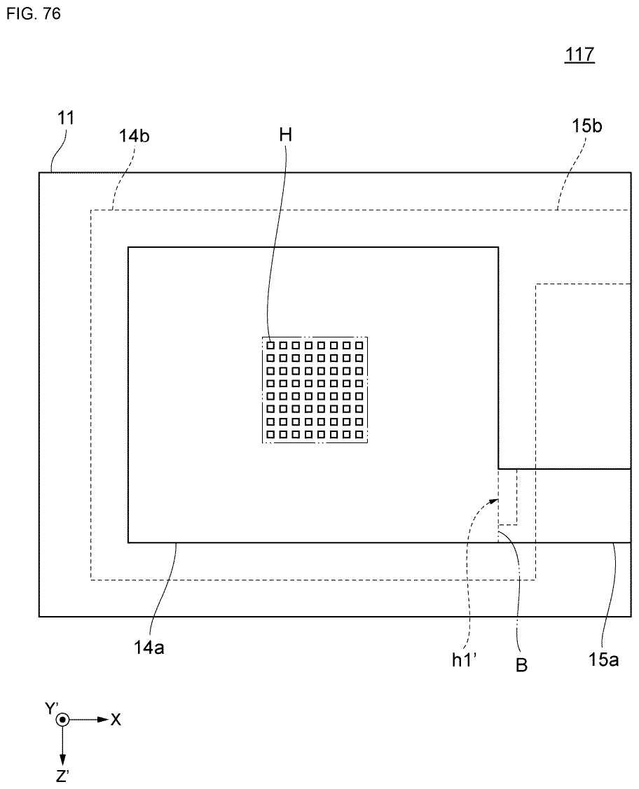

Next, a configuration of a quartz crystal resonator 117 according to a seventeenth embodiment will be described with reference to FIG. 76. FIG. 76 is a plan view of the quartz crystal resonator according to the seventeenth embodiment.

A cavity h1′ is provided in the second excitation electrode 14b in a region overlapping with the coupling portion between the first excitation electrode 14a and the first extended electrode 15a. The planar shape, position, and dimensions of the cavity h1′ are the same as the planar shape, position, and dimensions of the cavity h1 in the first embodiment. The cavity h1′ is provided in the second electrode provided on the side opposite to the first electrode, in which the plurality of hole portions H are disposed.

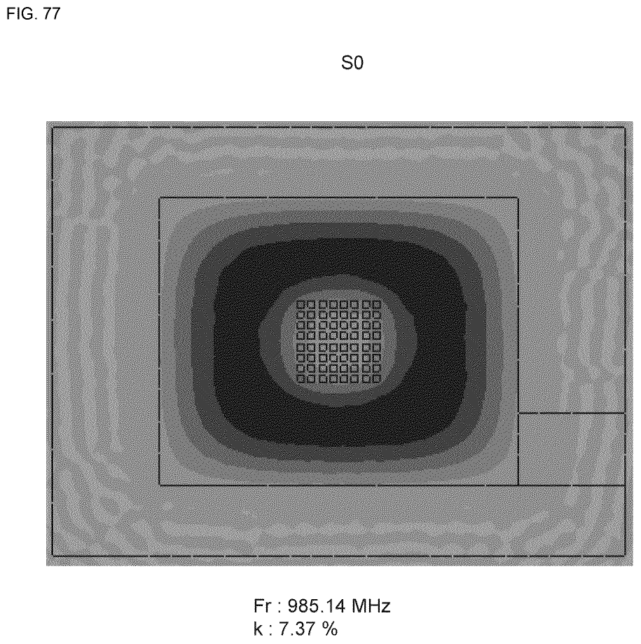

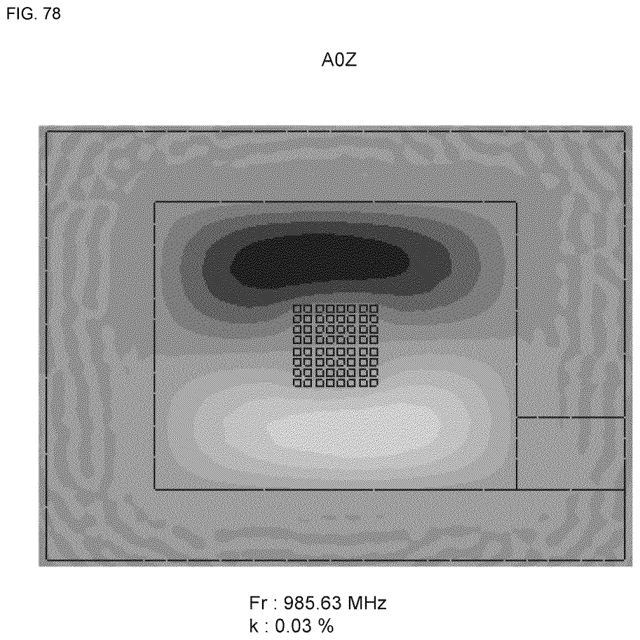

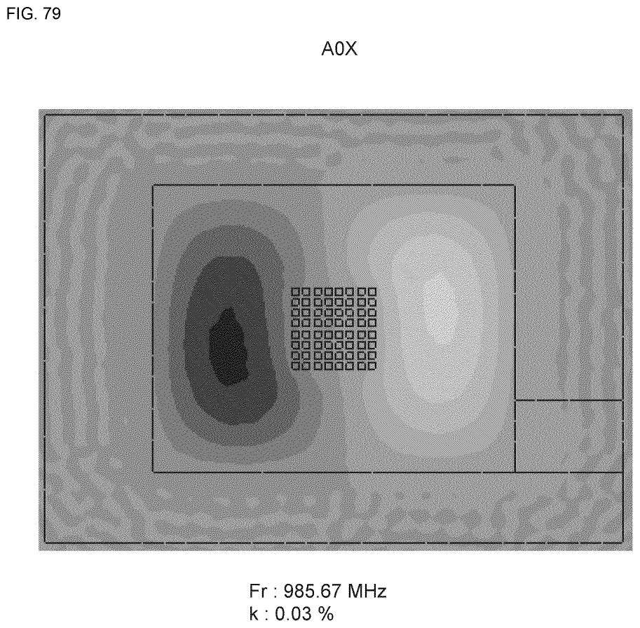

Next, a simulation result based on the seventeenth embodiment will be described with reference to FIGS. 77 to 79. FIGS. 77 to 79 are diagrams showing the vibration distributions of the quartz crystal resonator according to the seventeenth embodiment. FIG. 77 shows a vibration distribution in the S0 mode as a simulation result based on the seventeenth embodiment. FIG. 78 shows a vibration distribution in the A0Z mode as a simulation result based on the seventeenth embodiment. FIG. 79 shows a vibration distribution in the A0X mode as a simulation result based on the seventeenth embodiment. In FIGS. 77 to 79, the first excitation electrode 14a and the first extended electrode 15a are shown, and the second excitation electrode 14b and the second extended electrode 15b are not shown.

As shown in FIG. 77, k_{S0} is 7.37% and Fr_{S0} is 985.14 MHz in an example of the seventeenth embodiment. As shown in FIG. 78, k_{A0Z} is 0.03% and Fr_{A0Z} is 985.63 MHz in an example of the seventeenth embodiment. As shown in FIG. 79, k_{A0X} is 0.03% and Fr_{A0X} is 985.67 MHz in an example of the seventeenth embodiment.

k_{S0} in the example of the seventeenth embodiment is substantially the same as k_{S0} in the example of the first embodiment. k_{A0Z} in the example of the seventeenth embodiment is substantially the same as k_{A0Z} in the example of the first embodiment. k_{A0X} in the example of the seventeenth embodiment is substantially the same as k_{A0X} in the example of the first embodiment. That is, the same effect is obtained regardless of whether the cavity is in the first electrode or the second electrode.

### Eighteenth Exemplary Embodiment

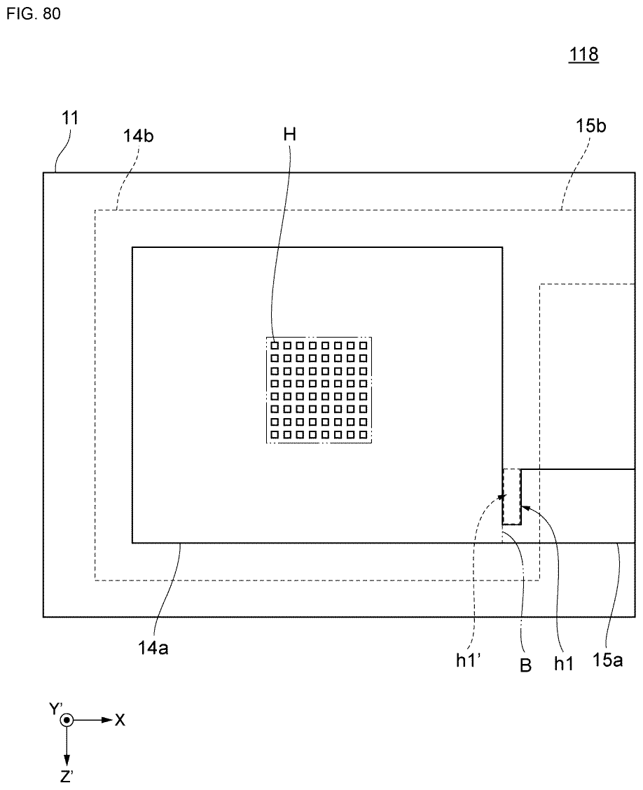

Next, a configuration of a quartz crystal resonator 118 according to an eighteenth embodiment will be described with reference to FIG. 80. FIG. 80 is a plan view of the quartz crystal resonator according to the eighteenth embodiment.

In a region overlapping with the coupling portion between the first excitation electrode 14a and the first extended electrode 15a, the cavity h1 is provided in the first excitation electrode 14a, and the cavity h1′ is provided in the second excitation electrode 14b. The planar shape, position, and dimensions of the cavity h1 are substantially the same as the planar shape, position, and dimensions of the cavity h1′.

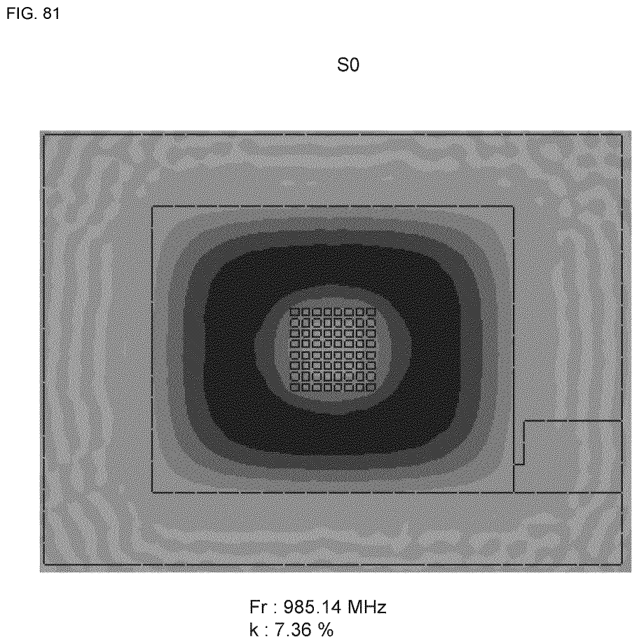

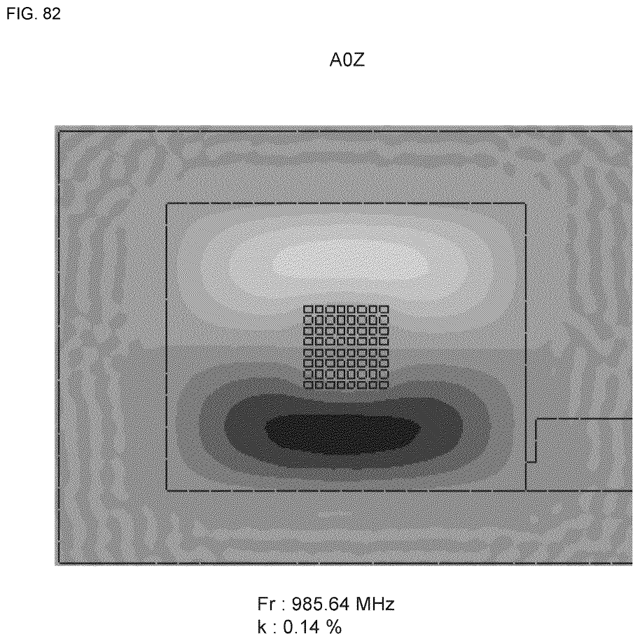

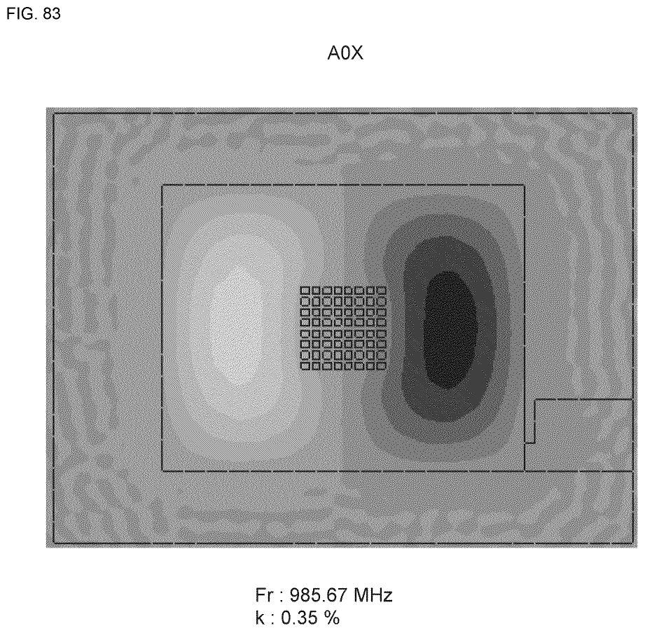

Next, a simulation result based on the eighteenth embodiment will be described with reference to FIGS. 81 to 83. FIGS. 81 to 83 are diagrams showing the vibration distributions of the quartz crystal resonator according to the eighteenth embodiment. FIG. 81 shows a vibration distribution in the S0 mode as a simulation result based on the eighteenth embodiment. FIG. 82 shows a vibration distribution in the A0Z mode as a simulation result based on the eighteenth embodiment. FIG. 83 shows a vibration distribution in the A0X mode as a simulation result based on the eighteenth embodiment. In FIGS. 81 to 83, the first excitation electrode 14a and the first extended electrode 15a are shown, and the second excitation electrode 14b and the second extended electrode 15b are not shown.

As shown in FIG. 81, k_{S0} is 7.36% and Fr_{S0} is 985.14 MHz in an example of the eighteenth embodiment. As shown in FIG. 82, k_{A0Z} is 0.14% and Fr_{A0Z} is 985.64 MHz in an example of the eighteenth embodiment. As shown in FIG. 83, k_{A0X} is 0.35% and Fr_{A0X} is 985.68 MHz in an example of the eighteenth embodiment.

k_{S0} in the example of the eighteenth embodiment is substantially the same as k_{S0} in the example of the first embodiment. k_{A0Z} in the example of the eighteenth embodiment is substantially the same as k_{A0Z} in the example of the first embodiment. k_{A0X} in the example of the eighteenth embodiment is substantially the same as k_{A0X} in the example of the first embodiment. That is, even in a case where the cavity is provided in both the first electrode and the second electrode, the same effect is obtained as when the cavity is in one of the first electrode and the second electrode.

### Nineteenth Exemplary Embodiment

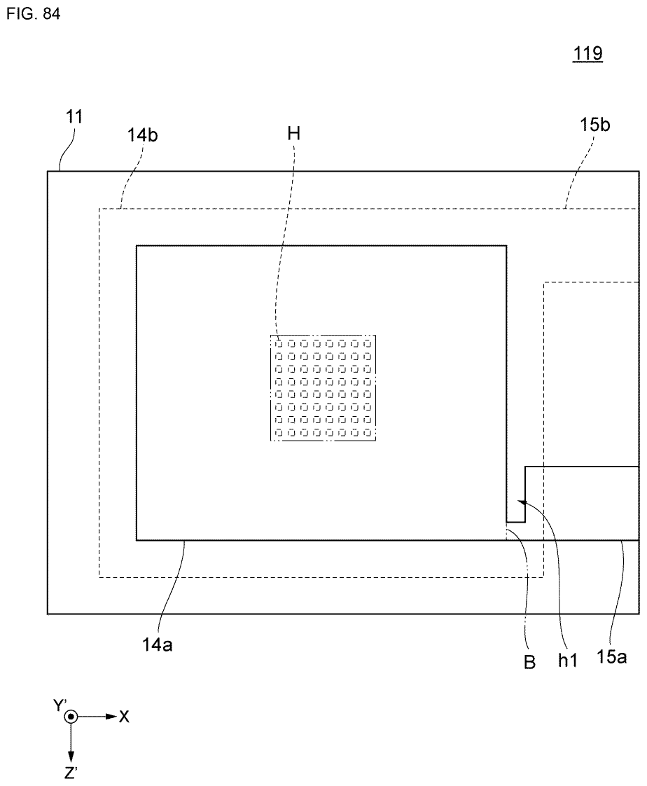

Next, a configuration of a quartz crystal resonator 119 according to a nineteenth embodiment will be described with reference to FIG. 84. FIG. 84 is a plan view of the quartz crystal resonator according to the nineteenth embodiment.

In the high acoustic velocity region 17, the plurality of hole portions H are provided in the second excitation electrode 14b. That is, out of the first excitation electrode 14a and the second excitation electrode 14b, a plurality of hole portions H are provided in the second excitation electrode 14b having a greater area than that of the first excitation electrode 14a. The cavity h1 is provided in the first electrode provided on the side opposite to the second electrode provided with the plurality of hole portions H.

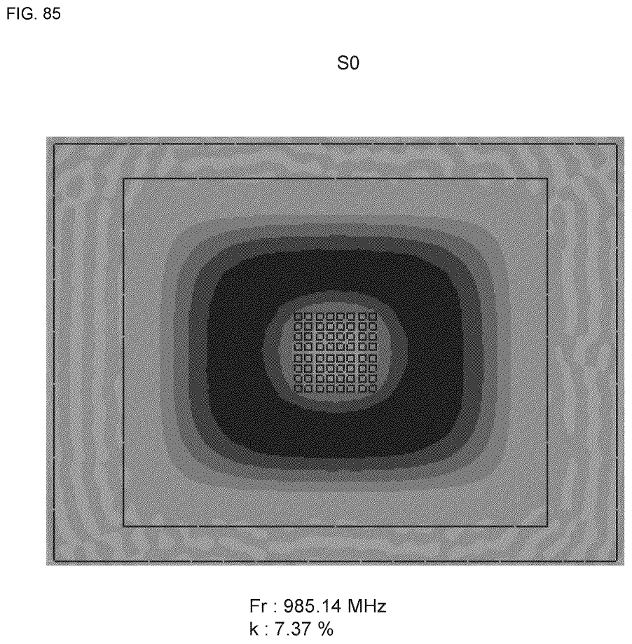

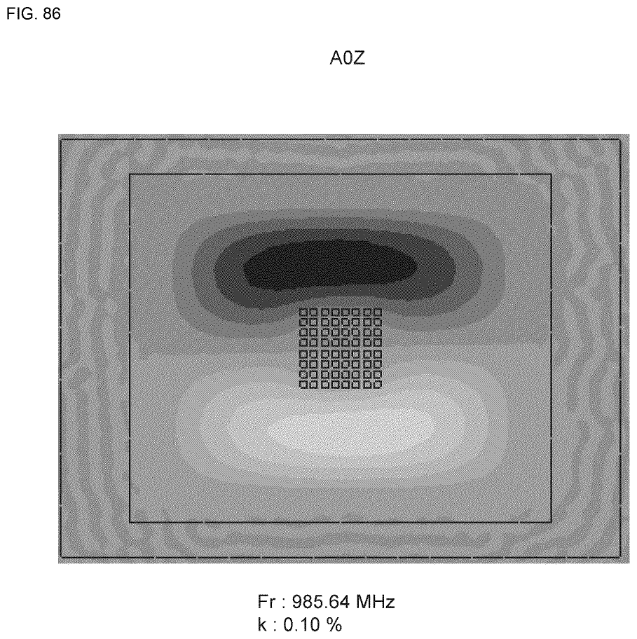

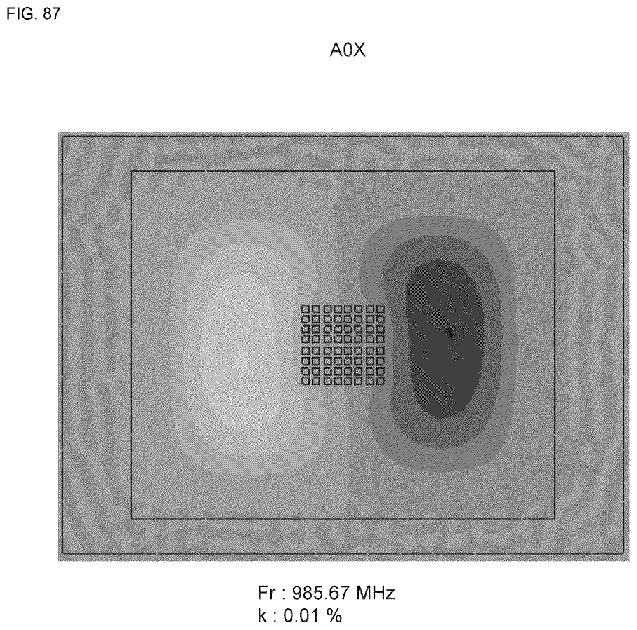

Next, a simulation result based on the nineteenth embodiment will be described with reference to FIGS. 85 to 87. FIGS. 85 to 87 are diagrams showing vibration distributions of the quartz crystal resonator according to the nineteenth embodiment. FIG. 85 shows a vibration distribution in the S0 mode as a simulation result based on the nineteenth embodiment. FIG. 86 shows a vibration distribution in the A0Z mode as a simulation result based on the nineteenth embodiment. FIG. 87 shows a vibration distribution in the A0X mode as a simulation result based on the nineteenth embodiment. In FIGS. 85 to 87, the second excitation electrode 14b is shown, and the first excitation electrode 14a, the first extended electrode 15a, and the second extended electrode 15b are not shown.

As shown in FIG. 85, k_{S0} is 7.37% and Fr_{S0} is 985.14 MHz in an example of the nineteenth embodiment. As shown in FIG. 86, k_{A0Z} is 0.10% and Fr_{A0Z} is 985.64 MHz in an example of the nineteenth embodiment. As shown in FIG. 87, k_{A0X} is 0.01% and Fr_{A0X} is 985.67 MHz in an example of the nineteenth embodiment.

k_{S0} in the example of the nineteenth embodiment has substantially the same size as k_{S0} in the comparative example. k_{A0Z} in the example of the nineteenth embodiment is smaller than k_{A0Z} in the comparative example. k_{A0X} in the example of the nineteenth embodiment is smaller than k_{A0X} in the comparative example. As described above, of the first excitation electrode 14a and the second excitation electrode 14b, in a case where the plurality of hole portions H are provided in the second excitation electrode 14b having a large area, and the cavity h1 is provided in the first electrode on the side opposite to the second electrode in which the plurality of hole portions H are provided, the A0 mode is suppressed, and the vibration characteristics of the S0 mode are improved.

### Twentieth Exemplary Embodiment

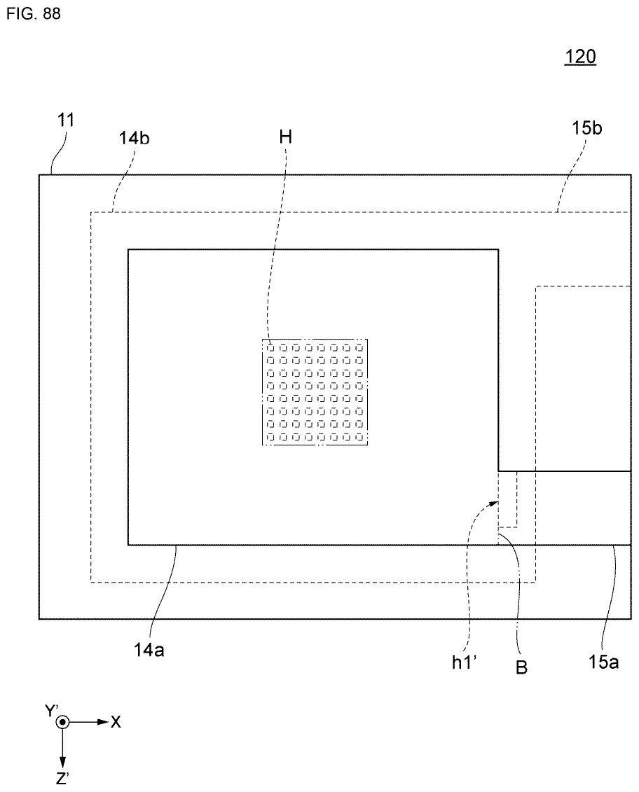

Next, a configuration of a quartz crystal resonator 120 according to a twentieth embodiment will be described with reference to FIG. 88. FIG. 88 is a plan view of the quartz crystal resonator according to the twentieth embodiment.

In the high acoustic velocity region 17, the plurality of hole portions H are provided in the second excitation electrode 14b. That is, out of the first excitation electrode 14a and the second excitation electrode 14b, a plurality of hole portions H are provided in the second excitation electrode 14b having a greater area than that of the first excitation electrode 14a. The cavity h1′is provided in the first electrode on the same side as the second electrode provided with the plurality of hole portions H.

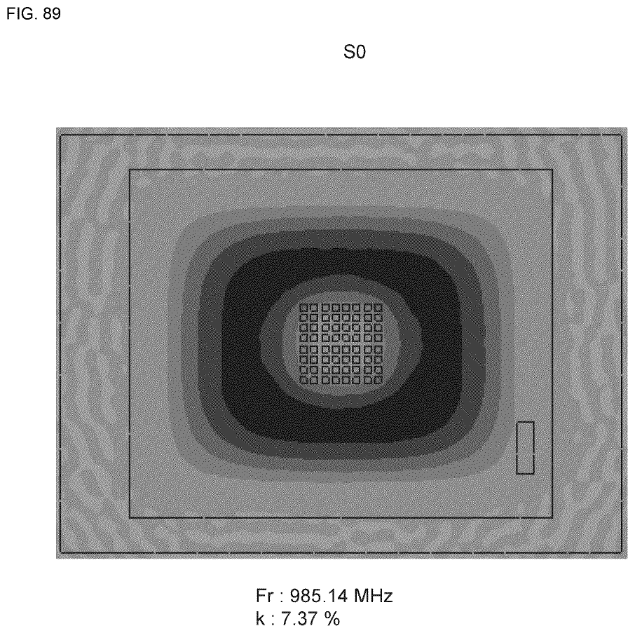

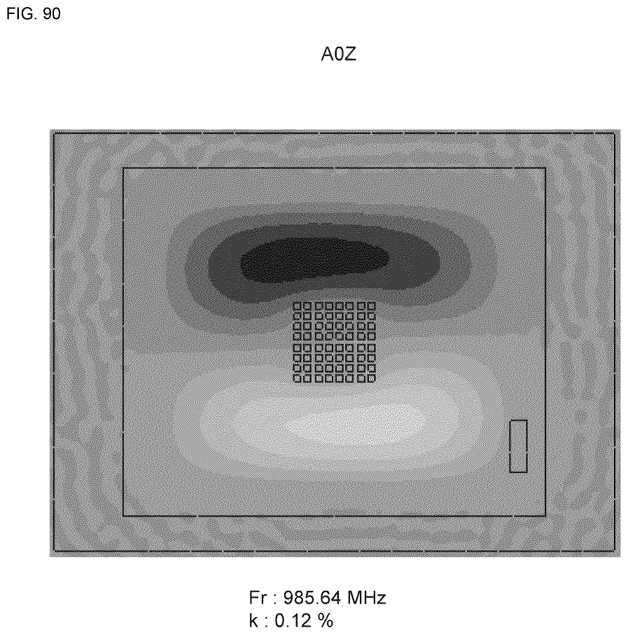

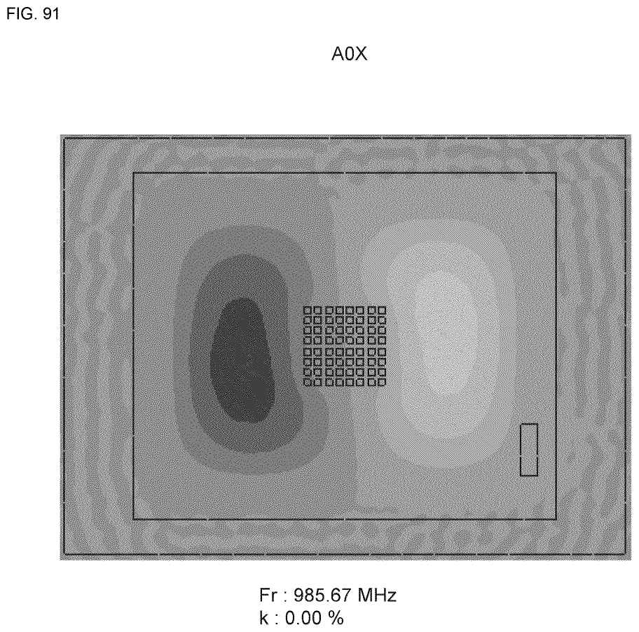

Next, a simulation result based on the twentieth embodiment will be described with reference to FIGS. 89 to 91. FIGS. 89 to 91 are diagrams showing vibration distributions of the quartz crystal resonator according to the twentieth embodiment. FIG. 89 shows a vibration distribution in the S0 mode as a simulation result based on the twentieth embodiment. FIG. 90 shows a vibration distribution in the A0Z mode as a simulation result based on the twentieth embodiment. FIG. 91 shows a vibration distribution in the A0X mode as a simulation result based on the twentieth embodiment. In FIGS. 89 to 91, the second excitation electrode 14b is shown, and the first excitation electrode 14a, the first extended electrode 15a, and the second extended electrode 15b are not shown.

As shown in FIG. 89, k_{S0} is 7.37% and Fr_{S0} is 985.14 MHz in an example of the twentieth embodiment. As shown in FIG. 90, k_{A0Z} is 0.12% and Fr_{A0Z} is 985.64 MHz in an example of the twentieth embodiment. As shown in FIG. 91, k_{A0X} is 0.00% and Fr_{A0X} is 985.67 MHz in an example of the twentieth embodiment.

k_{S0} in the example of the twentieth embodiment is substantially the same as k_{S0} in the example of the nineteenth embodiment. k_{A0Z} in the example of the twentieth embodiment is substantially the same as k_{A0Z} in the example of the nineteenth embodiment. k_{A0X} in the example of the twentieth embodiment is substantially the same as k_{A0X} in the example of the nineteenth embodiment. That is, the same effect is obtained regardless of whether the cavity is in the first electrode or the second electrode.

### Twenty-first Exemplary Embodiment

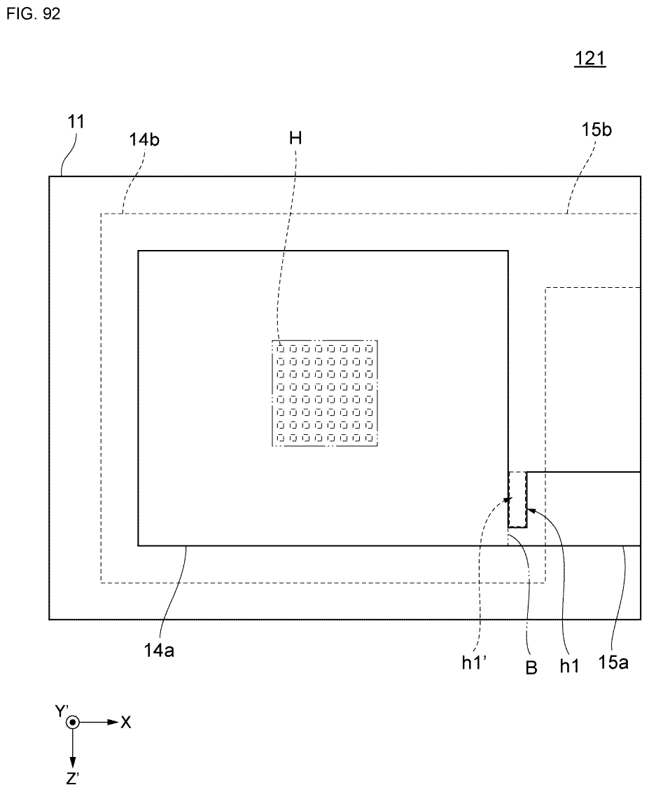

Next, a configuration of a quartz crystal resonator 121 according to a twenty-first embodiment will be described with reference to FIG. 92. FIG. 92 is a plan view of the quartz crystal resonator according to the twenty-first embodiment.

Of the first excitation electrode 14a and the second excitation electrode 14b, the plurality of hole portions H are provided in the second excitation electrode 14b having a greater area. In a region overlapping with the coupling portion between the first excitation electrode 14a and the first extended electrode 15a, the cavity h1 is provided in the first excitation electrode 14a, and the cavity h1′is provided in the second excitation electrode 14b. The planar shape, position, and dimensions of the cavity h1 are substantially the same as the planar shape, position, and dimensions of the cavity h1′.

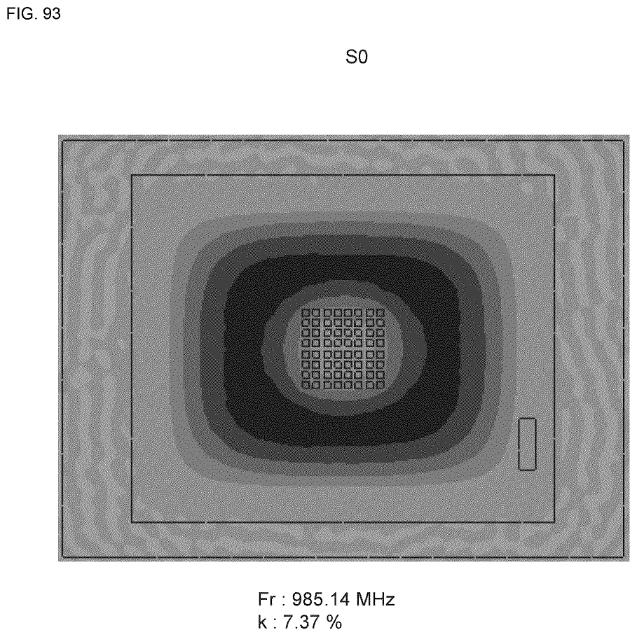

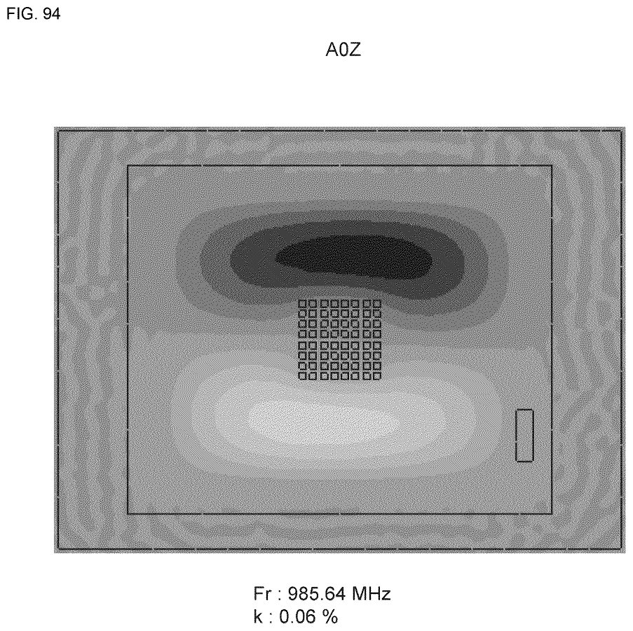

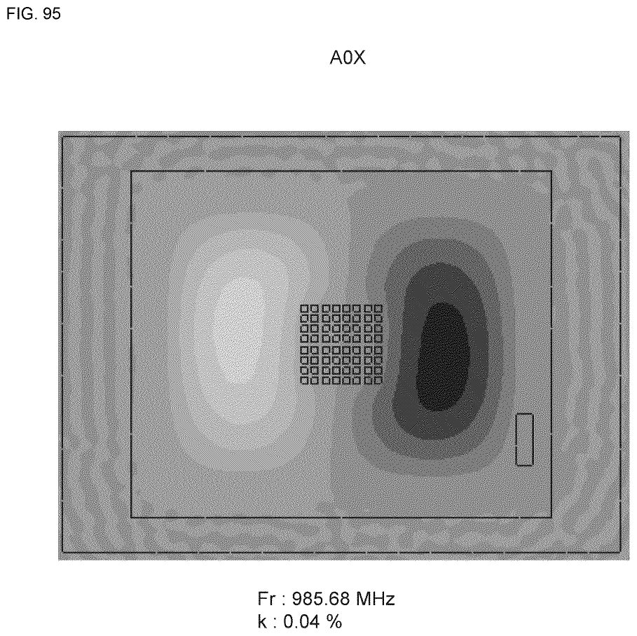

Next, a simulation result based on the twenty-first embodiment will be described with reference to FIGS. 93 to 95. FIGS. 93 to 95 are diagrams showing vibration distributions of the quartz crystal resonator according to the twenty-first embodiment. FIG. 93 shows a vibration distribution in the S0 mode as a simulation result based on the twenty-first embodiment. FIG. 94 shows a vibration distribution in the A0Z mode as a simulation result based on the twenty-first embodiment. FIG. 95 shows a vibration distribution in the A0X mode as a simulation result based on the twenty-first embodiment. In FIGS. 93 to 95, the second excitation electrode 14b is shown, and the first excitation electrode 14a, the first extended electrode 15a, and the second extended electrode 15b are not shown.

As shown in FIG. 93, k_{S0} is 7.36% and Fr_{S0} is 985.14 MHz in an example of the twenty-first embodiment. As shown in FIG. 94, k_{A0Z} is 0.06% and Fr_{A0Z} is 985.64 MHz in an example of the twenty-first embodiment. As shown in FIG. 95, k_{A0X} is 0.04% and Fr_{A0X} is 985.68 MHz in an example of the twenty-first embodiment.

k_{S0} in the example of the twenty-first embodiment is substantially the same as k_{S0} in the example of the nineteenth embodiment and the twentieth embodiment. k_{A0Z} in the example of the twenty-first embodiment is substantially the same as k_{A0Z} in the example of the nineteenth embodiment and the twentieth embodiment. k_{A0X} in the example of the twenty-first embodiment is substantially the same as k_{A0X} in the example of the nineteenth embodiment and the twentieth embodiment. That is, even in a case where the cavity is provided in both the first electrode and the second electrode, the same effect is obtained as when the cavity is in the first electrode or the second electrode.

### Twenty-second Exemplary Embodiment

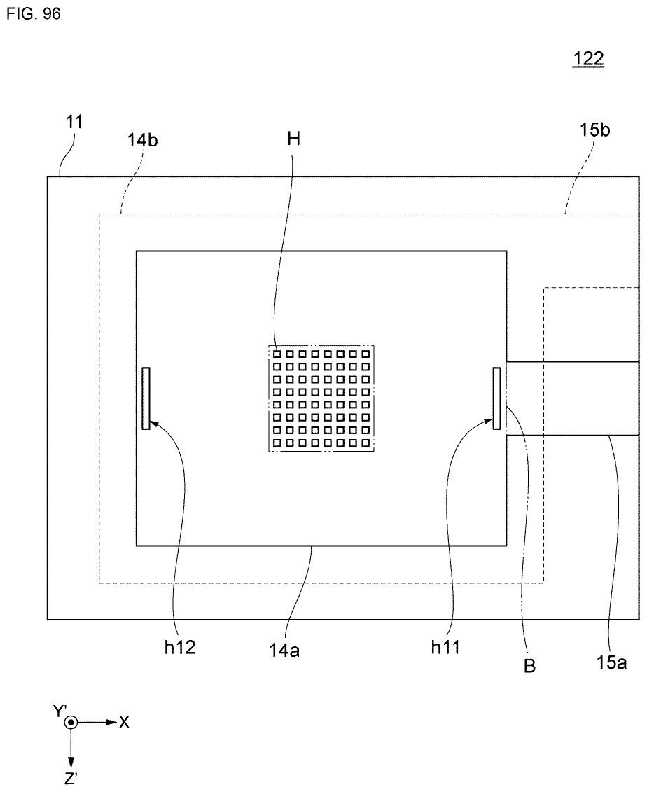

Next, a configuration of a quartz crystal resonator 122 according to a twenty-second embodiment will be described with reference to FIG. 96. FIG. 96 is a plan view of the quartz crystal resonator according to the twenty-second embodiment.

The first extended electrode 15a is coupled to a center portion in the Z′ axis direction of the end portion of the first excitation electrode 14a on the positive X axis direction side. The cavity h11 is provided on the first excitation electrode 14a side of the boundary B, and the cavity h12 is provided on a side opposite to the cavity h11 with the high acoustic velocity region 17 interposed therebetween. The cavities h11 and h12 are slit-shaped cavities having a longitudinal shape extending in the direction along the boundary B.

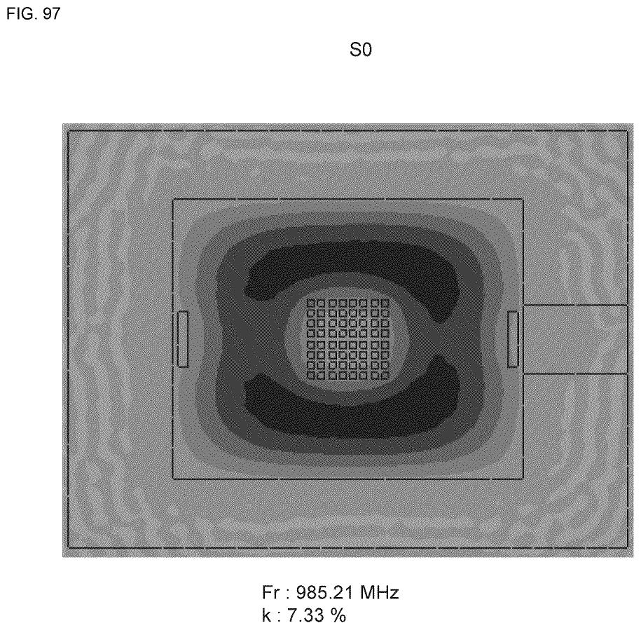

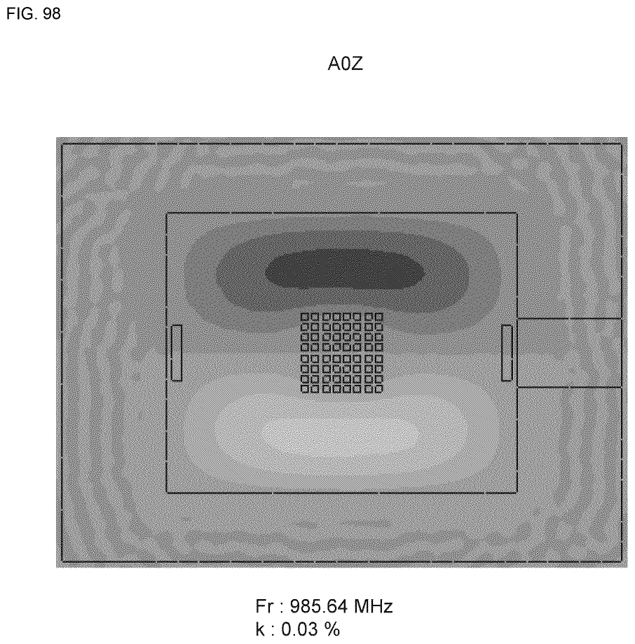

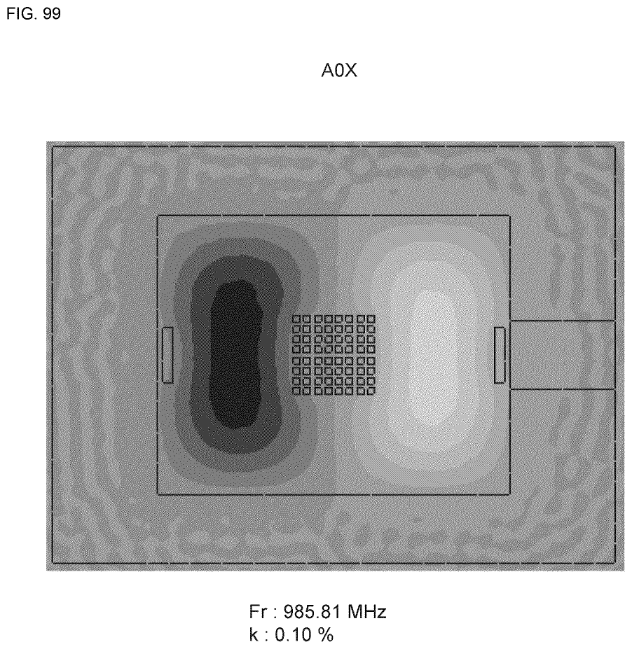

Next, a simulation result based on the twenty-second embodiment will be described with reference to FIGS. 97 to 99. FIGS. 97 to 99 are diagrams showing vibration distributions of the quartz crystal resonator according to the twenty-second embodiment. FIG. 97 shows a vibration distribution in the S0 mode as a simulation result based on the twenty-second embodiment. FIG. 98 shows a vibration distribution in the A0Z mode as a simulation result based on the twenty-second embodiment. FIG. 99 shows a vibration distribution in the A0X mode as a simulation result based on the twenty-second embodiment. In FIGS. 97 to 99, the first excitation electrode 14a and the first extended electrode 15a are shown, and the second excitation electrode 14b and the second extended electrode 15b are not shown.

As shown in FIG. 97, k_{S0} is 7.33% and Fr_{S0} is 985.21 MHz in an example of the twenty-second embodiment. As shown in FIG. 98, k_{A0Z} is 0.03% and Fr_{A0Z} is 985.64 MHz in an example of the twenty-second embodiment. As shown in FIG. 99, k_{A0X} is 0.10% and Fr_{A0X} is 985.81 MHz in an example of the twenty-second embodiment.

Although not shown, in a comparative example in which the cavities h11 and h12 are omitted from the twenty-second embodiment, k_{S0} is 7.34%, Fr_{S0} is 985.08 MHz, k_{A0Z} is 0.03%, Fr_{A0Z} is 985.63 MHz, k_{A0X} is 1.05%, and Fr_{A0X} is 985.58 MHz.

k_{S0} in the example of the twenty-second embodiment has substantially the same size as k_{S0} in the comparative example. k_{A0Z} in the example of the twenty-second embodiment has substantially the same size as k_{A0Z} in the comparative example. k_{A0X} in the example of the twenty-second embodiment is smaller than k_{A0X} in the comparative example. As described above, even in a case where the first extended electrode 15a is coupled to the center portion of the end portion of the first excitation electrode 14a instead of the corner thereof, the cavity h11 is provided in the region overlapping with the coupling portion between the first excitation electrode 14a and the first extended electrode 15a, and accordingly, the A0 mode is suppressed and the vibration characteristics of the S0 mode is improved.

In the present specification, although a quartz crystal resonator including a quartz crystal element as a piezoelectric element is described as an example, the piezoelectric resonator is not limited thereto. Examples of piezoelectric elements suitable for use in the piezoelectric resonator unit of the present embodiment include piezoelectric ceramics such as lead zirconate titanate (PZT) and aluminum nitride, and piezoelectric single crystals such as lithium niobate and lithium tantalate, but are not limited to these and can be selected as appropriate.

It is also noted that the exemplary embodiments according to the present disclosure are not particularly limited, and can be applied as appropriate to any device that converts electromechanical energy using a piezoelectric effect, such as a timing device, a sound generator, an oscillator, or a load sensor.

As described above, according to exemplary an aspect of the present disclosure, a piezoelectric resonator is provided with improved vibration characteristics.

The exemplary embodiments described above are for facilitating the understanding of the present disclosure, and are not intended to be construed as limiting. The exemplary embodiments may be modified/improved without departing from the concept of the present disclosure. That is, the scope of the present disclosure includes designs obtained by appropriately changing the embodiments and/or the modification examples by those skilled in the art as long as the designs have the characteristics of the present disclosure. For example, each component included in the embodiments and/or the modification examples, arrangement, a material, a condition, a shape, a size, and the like of the component are not limited to those shown, and can be changed as appropriate. In addition, the embodiments and the modification examples are merely examples, and it goes without saying that partial substitutions or combinations of the configurations shown in the different embodiments and/or modification examples can be made, and substitutions or combinations are also included within the scope of the present disclosure as long as the substitutions or combinations include the characteristics of the present disclosure.

### REFERENCE SIGNS LIST

1 QUARTZ CRYSTAL RESONATOR UNIT
10 QUARTZ CRYSTAL RESONATOR
30 BASE MEMBER
40 LID MEMBER
50 BONDING PORTION
11 QUARTZ CRYSTAL ELEMENT
11A UPPER SURFACE
11B LOWER SURFACE
14a FIRST EXCITATION ELECTRODE
14b SECOND EXCITATION ELECTRODE
15a FIRST EXTENDED ELECTRODE
15b SECOND EXTENDED ELECTRODE
16a FIRST COUPLING ELECTRODE
16b SECOND COUPLING ELECTRODE
17 HIGH ACOUSTIC VELOCITY REGION
18 LOW ACOUSTIC VELOCITY REGION
19 EXCITATION REGION
71, 72, 73, 74 OUTER PERIPHERAL PORTION
81, 82, 83, 84 OUTER PERIPHERAL PORTION
B BOUNDARY
h1 CAVITY
H HOLE PORTION

1. A piezoelectric resonator comprising:
a piezoelectric element having a first main surface and a second main surface;
a first electrode including a first excitation electrode on the first main surface and a first extended electrode coupled to the first excitation electrode; and
a second excitation electrode on the second main surface,
wherein:
in a plan view of at least one of the first and second main surfaces, a high acoustic velocity region is disposed at a center portion in a region where the first excitation electrode overlaps the second excitation electrode, and a low acoustic velocity region is disposed at a peripheral portion in the region where the first excitation electrode overlaps the second excitation electrode overlap, the low acoustic velocity region having an acoustic velocity less than an acoustic velocity in the high acoustic velocity region,
a first outer peripheral portion of the first excitation electrode is inside a second outer peripheral portion of the second excitation electrode,
an acoustic velocity in the region where the first extended electrode overlaps the second excitation electrode overlap is less than the acoustic velocity in the high acoustic velocity region and is equal to or greater than the acoustic velocity in the low acoustic velocity region,
at least one cavity is in at least one of the first electrode and the second excitation electrode in the region where the first electrode overlaps the second excitation electrode, and
the at least one cavity is disposed within a range of a distance of four times or less a thickness of the piezoelectric element from a boundary between the first excitation electrode and the first extended electrode.

2. The piezoelectric resonator according to claim 1, wherein a plurality of holes are in at least one of the first excitation electrode and the second excitation electrode in the high acoustic velocity region.

3. The piezoelectric resonator according to claim 1, wherein:
in the plan view, the first excitation electrode has a rectangular shape, and
the first extended electrode is coupled to a corner of the first excitation electrode.

4. The piezoelectric resonator according to claim 3, wherein the first extended electrode is coupled to only one side of the first excitation electrode.

5. The piezoelectric resonator according to claim 1, wherein the at least one cavity includes at least one of a slit-shaped cavity having a longitudinal shape extending in a direction along the boundary and a plurality of cavities arranged in a row in the direction along the boundary.

6. The piezoelectric resonator according to claim 1, wherein:
the at least one cavity includes at least one of a slit-shaped cavity having a longitudinal shape extending in a direction parallel to the boundary and a plurality of cavities arranged in a row in the direction parallel to the boundary, and
a total length of the at least one cavity in the direction parallel to the boundary is 50% or more and 90% or less of a length of the first extended electrode in the direction parallel to the boundary.

7. The piezoelectric resonator according to claim 1, wherein:
the at least one cavity includes a plurality of cavities arranged in a row in a direction parallel to the boundary, and
a length of one cavity of the plurality of cavities is defined as Wh2 and a period in which the cavities are disposed is defined as Wp, in a direction in which the plurality of cavities are arranged, and
$$0.5 \leq Wh 2 / Wp \leq 0.90 .$$

8. The piezoelectric resonator according to claim 1, wherein:
the thickness of the piezoelectric element is defined as Tq,
in the plan view, a length a cavity of the at least one cavity in a direction along the boundary is defined as Wh, and a length of a cavity of the at least one cavity in a direction orthogonal to the length Wh along the boundary is defined as Lh, and
$$2 < Lh / Tq .$$

9. The piezoelectric resonator according to claim 1, wherein the at least one cavity includes a plurality of cavities arranged in a direction that intersects the boundary.

10. The piezoelectric resonator according to claim 1, wherein a total length of the at least one cavity in a direction orthogonal to the boundary is equal to or greater than twice the thickness of the piezoelectric element.

11. The piezoelectric resonator according to claim 1, wherein the at least one cavity includes a plurality of slit-shaped cavities each having a longitudinal shape that extends in parallel with each other.

12. The piezoelectric resonator according to claim 1, wherein:
a difference between a length of the first extended electrode and a length of the at least one cavity in a direction parallel to the boundary is defined as Ws,
a length of the first excitation electrode in the direction parallel to the boundary is defined as We, and
$$Ws / We \leq 0.15 .$$

13. The piezoelectric resonator according to claim 1, wherein:
the at least one cavity is in the first extended electrode, and
a difference between a length of the first extended electrode and a length of the at least one cavity in a direction parallel to the boundary is defined as Ws,
a length of the at least one cavity in a direction orthogonal to the boundary is defined as Ls,
a sheet resistance of a part in the first extended electrode adjacent to the at least one cavity in the direction parallel to the boundary is defined as Rs, and
$$Ls \leq Ws / Rs .$$

14. The piezoelectric resonator according to claim 1, wherein:
a distance between the boundary and the at least one cavity in a direction orthogonal to the boundary is defined as Lx,
a difference between a length of the first extended electrode and a length of the at least one cavity in a direction parallel to the boundary is defined as Ws, and
$$Lx = 0.48 \times Ls - 1.88 \pm 1.7 .$$

15. The piezoelectric resonator according to claim 1, wherein:
the at least one cavity includes a plurality of cavities arranged in a row,
an array period of the plurality of cavities is defined as Wp,
a length of each of the plurality of cavities in a direction in which the plurality of cavities are arranged is defined as Wh2,
a length of each of the plurality of cavities in a direction orthogonal to the direction in which the plurality of cavities are arranged is defined as Lh2,
the thickness of the piezoelectric element is defined as Tq, and
$$0.6 \leq ( Lh 2 / Tq ) \times ( Wh 2 / Wp ) \leq 2.3 .$$

16. A piezoelectric resonator comprising:
a piezoelectric element having a first main surface and a second main surface;
a first electrode including a first excitation electrode on the first main surface and a first extended electrode coupled to the first excitation electrode; and
a second excitation electrode on the second main surface,
wherein, in a plan view of at least one of the first main surface and the second main surface:
a high acoustic velocity region is disposed at a center portion in a region where the first excitation electrode overlaps the second excitation electrode,
a low acoustic velocity region is disposed at a peripheral portion in the region where the first excitation electrode overlaps the second excitation electrode, the low acoustic velocity region having an acoustic velocity less than an acoustic velocity of the high acoustic velocity region, and
a first outer peripheral portion of the first excitation electrode is inside a second outer peripheral portion of the second excitation electrode,
wherein an acoustic velocity in the region where the first extended electrode overlaps the second excitation electrode is less than the acoustic velocity in the high acoustic velocity region and is equal to or greater than the acoustic velocity in the low acoustic velocity region,
wherein at least one first cavity is in at least one of the first excitation electrode and the second excitation electrode in a region in the low acoustic velocity region on the first extended electrode side with respect to the high acoustic velocity region, and
at least one second cavity is in at least one of the first excitation electrode and the second excitation electrode in a region in the low acoustic velocity region on a side opposite to the first extended electrode with the high acoustic velocity region interposed therebetween.

17. The piezoelectric resonator according to claim 16, wherein:
a plurality of holes are in at least one of the first excitation electrode and the second excitation electrode in the high acoustic velocity region, and
the at least one first cavity and the at least one second cavity are within a range of a distance of four times or less a thickness of the piezoelectric element from the first outer peripheral portion of the first excitation electrode.

18. The piezoelectric resonator according to claim 16, wherein, in the plan view:
the first excitation electrode has a rectangular shape,
the first excitation electrode has a first corner and a second corner which are positioned diagonally opposite to each other,
the first extended electrode is coupled to the first corner of the first excitation electrode,
the at least one first cavity is in a region overlapping with the first corner, and
the at least one second cavity is in a region overlapping with the second corner.

19. The piezoelectric resonator according to claim 16, wherein, in the plan view, the at least one first cavity and the at least one second cavity are at positions that are point-symmetric with respect to a center of the first excitation electrode.

20. The piezoelectric resonator according to claim 16, wherein:
a plurality of holes are in at least one of the first excitation electrode and the second excitation electrode in the high acoustic velocity region,
the plurality of holes pass through the first excitation electrode or the second excitation electrode in a thickness direction thereof,
a thickness of the piezoelectric element is defined as Tq,
in the plan view, when each of the plurality of holes has a square shape and a length of one side of the square shape is defined as Hr, and when each of the plurality of holes has a shape other than a square shape, the shape of each of the holes is converted into a square shape while keeping an area constant, and a length of one side of the square shape is defined as Hr, and
$$0 < Hr / Tq \leq 2.0 .$$
